(19) United States
(12) Patent Application Publication
(10) Pub. No.: US 2026/0319746 A1
(43) Pub. Date: Oct. 15, 2026

(54) OPERATION CIRCUIT, SEMICONDUCTOR DEVICE, AND ELECTRONIC DEVICE

(71) Applicant: SEMICONDUCTOR ENERGY LABORATORY CO., LTD., Atsugi-shi (JP)

(72) Inventors: Munehiro KOZUMA, Atsugi (JP); Yoshiyuki KUROKAWA, Sagamihara (JP); Takeshi AOKI, Ebina (JP); Takuro KANEMURA, Sapporo (JP)

(21) Appl. No.: 19/718,209

(22) Filed: Jun. 24, 2026

Related U.S. Application Data
(63) Continuation of application No. 17/769,845, filed on Oct. 15, 2020.

(30) Foreign Application Priority Data
Oct. 25, 2019 (JP) 2019-194274

(51) Int. Cl. G06F 7/544; G06N 3/045; G06N 3/048; H10B 12/00; H10D 30/67; H10D 86/40; H10D 86/60

(52) U.S. Cl. CPC G06F 7/5443; G06N 3/045; G06N 3/048; H10B 12/00; H10D 30/6734; H10D 30/6755; H10D 86/423; H10D 86/481; H10D 86/60

(57) ABSTRACT

A semiconductor device that inhibits signal delay and can perform parallel product-sum operations is provided. The semiconductor device includes first to fourth registers, an adder, a multiplier, a selector, and a first memory unit. An output terminal of the first register is electrically connected to an input terminal of the second register, and an output terminal of the second register is electrically connected to a first input terminal of the multiplier. An output terminal of the multiplier is electrically connected to a first input terminal of the adder, and an output terminal of the adder is electrically connected to an input terminal of the third register. An output terminal of the third register is electrically connected to a first input terminal of the selector, and an output terminal of the selector is electrically connected to an input terminal of the fourth register, and the first memory unit is electrically connected to a second input terminal of the multiplier. The first memory unit has a function reading out first data corresponding to a context signal input to the first memory unit and inputting the first data to the second input terminal of the multiplier.

### CROSS REFERENCE TO RELATED APPLICATIONS

This application is a continuation of U.S. application Ser. No. 17/769,845, filed Apr. 18, 2022, now pending, which is incorporated by reference, and claims priority U.S. National Phase Application under 35 U.S.C. § 371 of International Application PCT/IB2020/059669, filed on Oct. 15, 2020, which is incorporated by reference and claims the benefit of a foreign priority application filed in Japan on Oct. 25, 2019, as Application No. 2019-194274.

### TECHNICAL FIELD

One embodiment of the present invention relates to an operation circuit, a semiconductor device and an electronic device.

Note that one embodiment of the present invention is not limited to the above technical field. The technical field of the invention disclosed in this specification and the like relates to an object, a driving method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display device, a liquid crystal display device, a light-emitting device, a power storage device, an imaging device, a memory device, a signal processing device, a processor, an electronic device, a system, a driving method thereof, a manufacturing method thereof, and a testing method thereof.

### BACKGROUND ART

Integrated circuits that imitate the mechanism of the human brain are currently under active development. The integrated circuits incorporate electronic circuits as the brain mechanism and include circuits corresponding to “neurons” and “synapses” of the human brain. Such integrated circuits may therefore be called “neuromorphic”, “brain-morphic”, or “brain-inspired” circuits. The integrated circuits have a non-von Neumann architecture and are expected to be able to perform parallel processing with extremely low power consumption as compared with a von Neumann architecture, in which power consumption increases with increasing processing speed.

An information processing model that imitates a biological neural network including “neurons” and “synapses” is called an artificial neural network (ANN). By using an artificial neural network, inference with an accuracy as high as or higher than that of a human can be carried out. In a neural network, the main operation is the weighted sum operation of outputs from neurons, i.e., the product-sum operation.

Depending on a matter to be treated in an artificial neural network, optimal values for the depth of the hierarchy of the artificial neural network, the number of neuron elements, and the like are varied; therefore, the artificial network is preferably constructed so as to be suitable for the matter. For example, Patent Document 1 discloses a semiconductor device that includes a programmable logic element and in which the electrical continuity and discontinuity between circuits are switched with a plurality of contexts and a product-sum operation is performed on a circuit scale suitable for a desired artificial neural network.

### REFERENCE

### Patent Document

[Patent Document 1] Japanese Published Patent Application No. 2018-110386

### SUMMARY OF THE INVENTION

### Problems to be Solved by the Invention

In recent years, artificial intelligence has been actively developed, and “inference” (also referred to as recognition in some cases) performed by an artificial intelligence is derived from operation results of an artificial neural network. In order that the artificial intelligence can solve a complicated problem, the scale of the artificial neural network needs to be enlarged. In other words, it is necessary to make provisions such as making the hierarchy of the artificial neural network deeper or increasing the number of neuron elements included in the layer.

In the case where product-sum operation circuits are mounted for an operation in the artificial neural network, the product-sum operation circuit is preferably provided with high parallelism. On the other hand, in the case where the scale of the artificial neural network is large, the parallel number of product-sum operation circuits is increased. In this case, the length of a lead wiring in the circuit layout might become long owing to the layout relation among input and output terminals of parallel-arranged product-sum operation circuits, a buffer memory storing operation results, and the like. The large length of the lead wiring increases parasitic resistance of the wiring and the parasitic capacitance with a peripheral wiring, element, or the like, which results in delay of a signal to be transmitted to the wiring, thereby reducing the operating speed of the product-sum operation circuit in some cases.

An object of one embodiment of the present invention is to provide a novel operation circuit. Another object of one embodiment of the present invention is to provide a semiconductor device that inhibits signal delay and can perform parallel product-sum operations by including the operation circuit.

Another object of one embodiment of the present invention is to provide a novel semiconductor device and the like. Another object of one embodiment of the present invention is to provide an electronic device including the semiconductor device.

Note that the objects of one embodiment of the present invention are not limited to the objects listed above. The objects listed above do not preclude the existence of other objects. Note that the other objects are objects that are not described in this section and are described below. The objects that are not described in this section are derived from the description of the specification, the drawings, and the like and can be extracted as appropriate from the description by those skilled in the art. Note that one embodiment of the present invention is to achieve at least one of the objects listed above and the other objects. Note that one embodiment of the present invention does not necessarily achieve all the objects listed above and the other objects.

### Means for Solving the Problems

(1)

One embodiment of the present invention is an operation circuit including a first register, a second register, a third register, a fourth register, an adder, a multiplier, a selector, and a first memory unit. An output terminal of the first register is electrically connected to an input terminal of the second register, and an output terminal of the second register is electrically connected to a first input terminal of the multiplier. An output terminal of the multiplier is electrically connected to a first input terminal of the adder, an output terminal of the adder is electrically connected to an input terminal of the third register, an output terminal of the third register is electrically connected to a first input terminal of the selector, and an output terminal of the selector is electrically connected to an input terminal of the fourth register. The first memory unit is electrically connected to a second input terminal of the multiplier, and the first memory unit has a function reading out first data corresponding to a context signal input to the first memory unit and inputting the first data to the second input terminal of the multiplier.

(2)

Another embodiment of the present invention is a semiconductor device including a first operation circuit and a second operation circuit. The second operation circuit has the same circuit structure as the first operation circuit. The first operation circuit includes a first memory unit, a first register, a second register, a third register, a first terminal, a second terminal, a third terminal, and a fourth terminal. In the first operation circuit, an input terminal of the first register is electrically connected to the first terminal, an output terminal of the first register is electrically connected to an input terminal of the second register and the second terminal, and an output terminal of the third register is electrically connected to the fourth terminal. The first operation circuit has a function of reading out first data corresponding to a context signal from the first memory unit when the context signal is input to the first memory unit. The first operation circuit has a function of retaining second data input to the first terminal, in the first register or the second register. The first operation circuit has a function of generating third data by multiplying the first data and the second data retained in the second register, a function of generating addition data by adding the third data to fourth data input from the third terminal, and a function of retaining the addition data in the third register. The first operation circuit has a function of outputting the second data retained in the first register to the second terminal and inputting the second data to the first terminal of the second operation circuit, and a function of outputting the addition data retained in the third register to the fourth terminal and inputting the addition data as the fourth data to the third terminal of the second operation circuit.

(3)

In the above structure (2), one embodiment of the present invention may further include an input register and a second memory unit. The second memory unit is electrically connected to an input terminal of the input register. The second memory unit has a function of reading out the second data and inputting the second data from an output terminal of the input register to the first terminal of the first operation circuit via the input register.

(4)

In the above structure (3), one embodiment of the present invention may further include a third operation circuit having the same circuit structure as the first operation circuit, and each of the first operation circuit and the third operation circuit may include a selector, a fourth register, a fifth terminal, and a sixth terminal. In each of the first operation circuit and the third operation circuit, a first input terminal of the selector is electrically connected to the output terminal of the third register, a second input terminal of the selector is electrically connected to the fifth terminal, an output terminal of the selector is electrically connected to an input terminal of the fourth register, and an output terminal of the fourth register is electrically connected to the sixth terminal. The fifth terminal of the first operation circuit is electrically connected to the sixth terminal of the third operation circuit

(5)

In the above structure (4), one embodiment of the present invention may further include a circuit that performs an operation with an activation function. The circuit performs an operation with an activation function on data output from the sixth terminal of the first operation circuit or the third operation circuit and retains a result of the operation in the second memory unit.

(6)

In any of the above structures (2) to (5), one embodiment of the present invention may further include a plurality of first switches and a plurality of second switches. The second terminal of the first operation circuit is electrically connected to the first terminal of the second operation circuit via the plurality of first switches, and the third terminal of the first operation circuit is electrically connected to the fourth terminal of the second operation circuit via the plurality of second switches.

(7)

One embodiment of the present invention is an electronic device including the semiconductor device according to any one of the above (2) to (6) and a housing. The electronic device has a function of performing an operation in a neural network using the semiconductor device.

Note that in this specification and the like, a semiconductor device refers to a device that utilizes semiconductor characteristics, and means a circuit including a semiconductor element (a transistor, a diode, a photodiode, or the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display device, a light-emitting device, a lighting device, an electronic device, and the like themselves are semiconductor devices, or include semiconductor devices in some cases.

In the case where there is a description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, for example, a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow(s) electrical connection between X and Y (e.g., a switch, a transistor, a capacitor, an inductor, a resistor, a diode, a display device, a light-emitting device, and a load) can be connected between X and Y. Note that a switch has a function of being controlled to be turned on or off. That is, the switch has a function of being in a conduction state (on state) or a non-conduction state (off state) to control whether a current flows or not.

For example, in the case where X and Y are functionally connected, at least one circuit that enables functional connection between X and Y (e.g., a logic circuit (an inverter, a NAND circuit, a NOR circuit, or the like); a signal converter circuit (a digital-analog converter circuit, an analog-digital converter circuit, a gamma correction circuit, or the like); a potential level converter circuit (a power supply circuit (a step-up circuit, a step-down circuit, or the like), a level shifter circuit for changing the potential level of a signal, or the like); a voltage source; a current source; a switching circuit; an amplifier circuit (a circuit that can increase signal amplitude, the amount of current, or the like, an operational amplifier, a differential amplifier circuit, a source follower circuit, a buffer circuit, or the like); a signal generation circuit; a memory circuit; or a control circuit) can be connected between X and Y. For example, even when another circuit is interposed between X and Y, X and Y are functionally connected when a signal output from X is transmitted to Y.

Note that an explicit description, X and Y are electrically connected, includes the case where X and Y are electrically connected (i.e., the case where X and Y are connected with another element or another circuit interposed therebetween) and the case where X and Y are directly connected (i.e., the case where X and Y are connected without another element or another circuit interposed therebetween).

It can be expressed as, for example, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”. Alternatively, it can be expressed as “a source (or a first terminal or the like) of a transistor is electrically connected to X; a drain (or a second terminal or the like) of the transistor is electrically connected to Y; and X, the source (or the first terminal or the like) of the transistor, the drain (or the second terminal or the like) of the transistor, and Y are electrically connected to each other in this order”. Alternatively, it can be expressed as “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided in this connection order”. When the connection order in a circuit configuration is defined by an expression similar to the above examples, a source (or a first terminal or the like) and a drain (or a second terminal or the like) of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: a function of the wiring and a function of the electrode. Thus, “electrical connection” in this specification includes in its category such a case where one conductive film has functions of a plurality of components.

In this specification and the like, a “resistor” can be, for example, a circuit element or a wiring having a resistance value higher than 0Ω. Therefore, in this specification and the like, a “resistor” sometimes includes a wiring having a resistance value, a transistor in which current flows between its source and drain, a diode, and a coil. Thus, the term “resistor” can be replaced with the terms “resistance”, “load”, “region having a resistance value”, and the like; inversely, the terms “resistance”, “load”, and “region having a resistance value” can be replaced with the term “resistor” and the like. The resistance value can be, for example, preferably greater than or equal to 1 mΩ and less than or equal to 10Ω, further preferably greater than or equal to 5 mΩ and less than or equal to 5Ω, still further preferably greater than or equal to 10 mΩ and less than or equal to 1Ω. As another example, the resistance value may be greater than or equal to 1Ω and less than or equal to 1×10⁹Ω.

In this specification and the like, a “capacitor” can be, for example, a circuit element having an electrostatic capacitance value higher than 0 F, a region of a wiring having an electrostatic capacitance value, parasitic capacitance, or gate capacitance of a transistor. Therefore, in this specification and the like, a “capacitor” sometimes includes not only a circuit element that has a pair of electrodes and a dielectric between the electrodes, but also parasitic capacitance generated between wirings, gate capacitance generated between a gate and one of a source and a drain of a transistor, and the like. The terms “capacitor”, “parasitic capacitance”, “gate capacitance”, and the like can be replaced with the term “capacitance” and the like; inversely, the term “capacitance” can be replaced with the terms “capacitor”, “parasitic capacitance”, “gate capacitance”, and the like. The term “pair of electrodes” of “capacitor” can be replaced with “pair of conductors”, “pair of conductive regions”, “pair of regions”, and the like. Note that the electrostatic capacitance value can be greater than or equal to 0.05 fF and less than or equal to 10 pF, for example. Alternatively, the electrostatic capacitance value may be greater than or equal to 1 pF and less than or equal to 10 μF, for example.

In this specification and the like, a transistor includes three terminals called a gate, a source, and a drain. The gate functions as a control terminal for controlling the conduction state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source” and “drain” can be replaced with each other in this specification and the like. In this specification and the like, expressions “one of a source and a drain” (or a first electrode or a first terminal) and “the other of the source and the drain” (or a second electrode or a second terminal) are used in description of the connection relationship of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, and a third gate, for example, in this specification and the like.

In this specification and the like, a node can be referred to as a terminal, a wiring, an electrode, a conductive layer, a conductor, an impurity region, or the like depending on the circuit structure, the device structure, or the like. Furthermore, a terminal, a wiring, or the like can be referred to as a node.

In this specification and the like, “voltage” and “potential” can be replaced with each other as appropriate. The “voltage” refers to a potential difference from a reference potential, and when the reference potential is a ground potential, for example, the “voltage” can be replaced with the “potential”. Note that the ground potential does not necessarily mean 0 V. Moreover, potentials are relative values, and a potential supplied to a wiring, a potential applied to a circuit and the like, a potential output from a circuit and the like, for example, are changed with a change of the reference potential.

In this specification and the like, the term “high-level potential” or “low-level potential” does not mean a particular potential. For example, in the case where two wirings are both described as “functioning as a wiring for supplying a high-level potential”, the levels of the high-level potentials supplied by the wirings are not necessarily equal to each other. Similarly, in the case where two wirings are both described as “functioning as a wiring for supplying a low-level potential”, the levels of the low-level potentials supplied by the wirings are not necessarily equal to each other.

Note that “current” is a charge transfer (electrical conduction); for example, the description “electrical conduction of positively charged particles occurs” can be rephrased as “electrical conduction of negatively charged particles occurs in the opposite direction”. Therefore, unless otherwise specified, “current” in this specification and the like refers to a charge transfer (electrical conduction) accompanied by carrier movement. Examples of a carrier here include an electron, a hole, an anion, a cation, and a complex ion, and the type of carrier differs between current flow systems (e.g., a semiconductor, a metal, an electrolyte solution, and a vacuum). The direction of current in a wiring or the like refers to the direction in which a positive carrier moves, and the amount of current is expressed as a positive value. In other words, the direction in which a negative carrier moves is opposite to the direction of current, and the amount of current is expressed as a negative value. Thus, in the case where the polarity of a current (or the direction of a current) is not specified in this specification and the like, the description “current flows from element A to element B” can be rephrased as “current flows from element B to element A”, for example. The description “current is input to element A” can be rephrased as “current is output from element A”, for example.

Ordinal numbers such as “first”, “second”, and “third” in this specification and the like are used to avoid confusion among components. Thus, the terms do not limit the number of components. Furthermore, the ordinal numbers do not limit the order of components. In this specification and the like, for example, a “first” component in one embodiment can be referred to as a “second” component in other embodiments or the scope of claims. Furthermore, in this specification and the like, for example, a “first” component in one embodiment can be omitted in other embodiments or the scope of claims.

In this specification and the like, the terms for describing positioning, such as “over” or “above” and “under” or “below”, are sometimes used for convenience to describe the positional relationship between components with reference to drawings. The positional relation between components is changed as appropriate in accordance with a direction in which the components are described. Thus, the positional relationship is not limited to the terms described in the specification and the like, and can be described with another term as appropriate depending on the situation. For example, the expression “an insulator positioned over (on) a top surface of a conductor” can be replaced with the expression “an insulator positioned under (on) a bottom surface of a conductor” when the direction of a drawing showing these components is rotated by 180°.

Furthermore, the terms such as “over” or “above” and “under” or “below” do not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B.

In this specification and the like, the terms “film”, “layer”, and the like can be interchanged with each other depending on the situation. For example, the term “conductive layer” can be changed into the term “conductive film” in some cases. Moreover, the term “insulating film” can be changed into the term “insulating layer” in some cases. Alternatively, the term “film”, “layer”, or the like is not used and can be interchanged with another term depending on the case or according to circumstances. For example, the term “conductive layer” or “conductive film” can be changed into the term “conductor” in some cases. Furthermore, for example, the term “insulating layer” or “insulating film” can be changed into the term “insulator” in some cases.

In this specification and the like, the term “electrode”, “wiring”, “terminal”, or the like does not limit the function of a component. For example, an “electrode” is used as part of a “wiring” in some cases, and vice versa. Furthermore, the term “electrode” or “wiring” also includes the case where a plurality of “electrodes” or “wirings” are formed in an integrated manner, for example. For example, a “terminal” is used as part of a “wiring” or an “electrode” in some cases, and vice versa. Furthermore, the term “terminal” can also include the case where a plurality of “electrodes”, “wirings”, “terminals”, or the like are formed in an integrated manner. Therefore, for example, an “electrode” can be part of a “wiring” or a “terminal”, and a “terminal” can be part of a “wiring” or an “electrode”. Moreover, the term “electrode”, “wiring”, “terminal”, or the like is sometimes replaced with the term “region”, for example.

In this specification and the like, the terms “wiring”, “signal line”, “power supply line”, and the like can be interchanged with each other depending on the case or according to circumstances. For example, the term “wiring” can be changed into the term “signal line” in some cases. Also, for example, the term “wiring” can be changed into the term “power source line” in some cases. Inversely, the term “signal line”, “power supply line”, or the like can be changed into the term “wiring” in some cases. The term “power source line” or the like can be changed into the term “signal line” or the like in some cases. Inversely, the term “signal line” or the like can be changed into the term “power source line” or the like in some cases. The term “potential” that is applied to a wiring can be changed into the term “signal” or the like depending on the case or according to circumstances. Inversely, the term “signal” or the like can be changed into the term “potential” in some cases.

In this specification and the like, an impurity in a semiconductor refers to an element other than a main component of a semiconductor layer, for example. For example, an element with a concentration of lower than 0.1 atomic % is an impurity. When an impurity is contained, for example, the density of defect states in a semiconductor may be increased, the carrier mobility may be decreased, or the crystallinity may be decreased. In the case where the semiconductor is an oxide semiconductor, examples of an impurity that changes characteristics of the semiconductor include Group 1 elements, Group 2 elements, Group 13 elements, Group 14 elements, Group 15 elements, and transition metals other than the main components; specific examples are hydrogen (including water), lithium, sodium, silicon, boron, phosphorus, carbon, and nitrogen. Specifically, when the semiconductor is a silicon layer, examples of an impurity that changes characteristics of the semiconductor include Group 1 elements, Group 2 elements, Group 13 elements, and Group 15 elements (except oxygen and hydrogen).

In this specification and the like, a switch has a function of being in a conduction state (on state) or a non-conduction state (off state) to determine whether a current flows or not. Alternatively, a switch has a function of selecting and changing a current path. For example, an electrical switch or a mechanical switch can be used. That is, a switch can be any element capable of controlling current, and is not limited to a certain element.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, and a diode-connected transistor), and a logic circuit in which such elements are combined. Note that in the case of using a transistor as a switch, a “conduction state” of the transistor refers to a state where a source electrode and a drain electrode of the transistor can be regarded as being electrically short-circuited. Furthermore, a “non-conduction state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

An example of a mechanical switch is a switch formed using a MEMS (micro electro mechanical system) technology. Such a switch includes an electrode which can be moved mechanically, and operates by controlling conduction and non-conduction with movement of the electrode.

In this specification, “parallel” indicates a state where the angle formed between two straight lines is greater than or equal to −10° and less than or equal to 10°. Accordingly, the case where the angle is greater than or equal to −5° and less than or equal to 5° is also included. In addition, the term “approximately parallel” or “substantially parallel” indicates a state where two straight lines are placed at an angle greater than or equal to −30° and less than or equal to 30°. In addition, “perpendicular” indicates a state where the angle formed between two straight lines is greater than or equal to 80° and less than or equal to 100°. Accordingly, the case where the angle is greater than or equal to 85° and less than or equal to 950 is also included. Furthermore, “approximately perpendicular” or “substantially perpendicular” indicates a state where two straight lines are placed at an angle greater than or equal to 60° and less than or equal to 120°.

### Effect of the Invention

According to one embodiment of the present invention, a novel operation circuit can be provided. According to another embodiment of the present invention, a semiconductor device that inhibits signal delay and can perform parallel product-sum operations by including the operation circuit can be provided.

According to another embodiment of the present invention, a novel semiconductor device and the like can be provided. According to another embodiment of the present invention, an electronic device including the semiconductor device can be provided.

Note that the effects of one embodiment of the present invention are not limited to the effects listed above. The effects listed above do not preclude the existence of other effects. Note that the other effects are effects that are not described in this section and will be described below. The effects that are not described in this section are derived from the descriptions of the specification, the drawings, and the like and can be extracted from these descriptions by those skilled in the art. Note that one embodiment of the present invention has at least one of the effects listed above and the other effects. Accordingly, depending on the case, one embodiment of the present invention does not have the effects listed above in some cases.

### BRIEF DESCRIPTION OF THE DRAWINGS

FIG. 1 is a block diagram illustrating a structure example of a semiconductor device.

FIG. 2 is a block diagram illustrating a structure example of a semiconductor device.

FIG. 3 is a block diagram illustrating a structure example of a circuit included in a semiconductor device.

FIG. 4 is a block diagram illustrating a structure example of a circuit included in a semiconductor device.

FIG. 5 is a block diagram illustrating a structure example of a circuit included in a semiconductor device.

FIG. 6 is a diagram illustrating a CNN structure example.

FIG. 7 is a block diagram illustrating a structure example of a circuit included in a semiconductor device.

FIG. 8 is a timing chart showing an operation example of a semiconductor device.

FIG. 9A is a diagram illustrating filter values included in a filter, and FIG. 9B is a block diagram illustrating filter values read out to the inside of operation circuits.

FIG. 10A is a diagram illustrating pixel data included in image data, and FIG. 10B is a diagram illustrating pixel data input to operation circuits.

FIG. 11 is a diagram illustrating pixel data input to operation circuits.

FIG. 12A and FIG. 12B are diagrams illustrating pixel data input to operation circuits.

FIG. 13 is a diagram illustrating pixel data input to operation circuits.

FIG. 14 is a diagram illustrating pixel data input to the operation circuits.

FIG. 15 is a diagram illustrating pixel data input to the operation circuits.

FIG. 16 is a diagram illustrating pixel data input to the operation circuits.

FIG. 17 is a diagram illustrating operation results output from operation circuits.

FIG. 18 is a diagram showing image data (a feature map) with feature portions extracted with a filter.

FIG. 19A and FIG. 19B are block diagrams each illustrating a structure example of a circuit included in a semiconductor device.

FIG. 20 is a block diagram illustrating a structure example of a circuit included in a semiconductor device.

FIG. 21 is a timing chart showing an operation example of a semiconductor device.

FIG. 22A and FIG. 22B are diagrams illustrating pixel data input to operation circuits.

FIG. 23 is a diagram illustrating filter values read out to operation circuits.

FIG. 24A to FIG. 24C are diagrams illustrating operation results output from operation circuits.

FIG. 25 is a block diagram illustrating a structure example of a circuit included in a semiconductor device.

FIG. 26 is a diagram illustrating neuron signals input to operation circuits and weighting coefficients read out to the operation circuits.

FIG. 27A to FIG. 27C are circuit diagrams illustrating structure examples of a memory cell included in a memory circuit.

FIG. 28 is a schematic cross-sectional view illustrating a structure example of a semiconductor device.

FIG. 29 is a schematic cross-sectional view illustrating a structure example of a semiconductor device.

FIG. 30A to FIG. 30C are schematic cross-sectional views illustrating a structure example of a transistor.

FIG. 31A and FIG. 31B are schematic cross-sectional views illustrating a structure example of a transistor.

FIG. 32 is a schematic cross-sectional view illustrating a structure example of a semiconductor device.

FIG. 33A and FIG. 33B are schematic cross-sectional views illustrating a structure example of a transistor.

FIG. 34 is a schematic cross-sectional view illustrating a structure example of a semiconductor device.

FIG. 35A is a top view illustrating a structure example of a capacitor, and FIG. 35B and FIG. 35C are cross-sectional perspective views illustrating the structure example of the capacitor.

FIG. 36A is a top view illustrating a structure example of a capacitor, FIG. 36B is a cross-sectional view illustrating the structure example of the capacitor, and FIG. 36C is a cross-sectional perspective view illustrating the structure example of the capacitor.

FIG. 37A is a diagram showing classifications of crystal structures of IGZO, FIG. 37B is a diagram showing an XRD spectrum of crystalline IGZO, and FIG. 37C is a diagram showing a nanobeam electron diffraction pattern of the crystalline IGZO.

FIG. 38A is a perspective view illustrating an example of a semiconductor wafer, FIG. 38B is a perspective view illustrating an example of a chip, and FIG. 38C and FIG. 38D are perspective views illustrating examples of electronic components.

FIG. 39 is a perspective view illustrating examples of electronic devices.

FIG. 40A to FIG. 40C are perspective views each illustrating an example of an electronic device.

### MODE FOR CARRYING OUT THE INVENTION

In an artificial neural network (hereinafter, referred to as a neural network), the connection strength between synapses can be changed by providing the neural network with existing information. The processing for determining a connection strength by providing a neural network with existing data in such a manner is called “learning” in some cases.

Furthermore, when a neural network in which “learning” has been performed (the connection strength has been determined) is provided with some type of information, new information can be output on the basis of the connection strength. The processing for outputting new information on the basis of provided information and the connection strength in a neural network in such a manner is called “inference” or “recognition” in some cases.

Examples of the model of a neural network include a Hopfield neural network and a hierarchical neural network. In particular, a neural network with a multilayer structure is called a “deep neural network” (DNN), and machine learning using a deep neural network is called “deep learning” in some cases.

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS FET or an OS transistor is described, it can also be referred to as a transistor including a metal oxide or an oxide semiconductor.

Furthermore, in this specification and the like, a metal oxide containing nitrogen is also collectively referred to as a metal oxide in some cases. A metal oxide containing nitrogen may be referred to as a metal oxynitride.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined as appropriate.

Note that a content (or part of the content) described in one embodiment can be applied to, combined with, or replaced with at least one of another content (or part of the content) in the embodiment and a content (or part of the content) described in one or a plurality of different embodiments.

Note that in each embodiment (or the example), a content described in the embodiment is a content described with reference to a variety of diagrams or a content described with text disclosed in the specification.

Note that by combining a drawing (or part thereof) described in one embodiment with at least one of another part of the drawing, a different drawing (or part thereof) described in the embodiment, and a drawing (or part thereof) described in one or a plurality of different embodiments, much more drawings can be constituted.

Embodiments described in this specification are described with reference to the drawings. Note that the embodiments can be implemented in many different modes, and it will be readily appreciated by those skilled in the art that modes and details can be changed in various ways without departing from the spirit and scope thereof. Therefore, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, some components might not be illustrated for clarity of the drawings.

In this specification and the like, when a plurality of components are denoted with the same reference numerals, and in particular need to be distinguished from each other, an identification sign such as “_1”, “[n]”, or “[m,n]” is sometimes added to the reference numerals.

In the drawings in this specification, the size, the layer thickness, or the region is exaggerated for clarity in some cases. Therefore, they are not limited to the illustrated scale. The drawings are schematic views showing ideal examples, and embodiments of the present invention are not limited to shapes or values shown in the drawings. For example, variations in signal, voltage, or current due to noise, variations in signal, voltage, or current due to difference in timing, or the like can be included.

### Embodiment 1

In this embodiment, the structure of a digital operation circuit that is a semiconductor device of one embodiment of the present invention will be described.

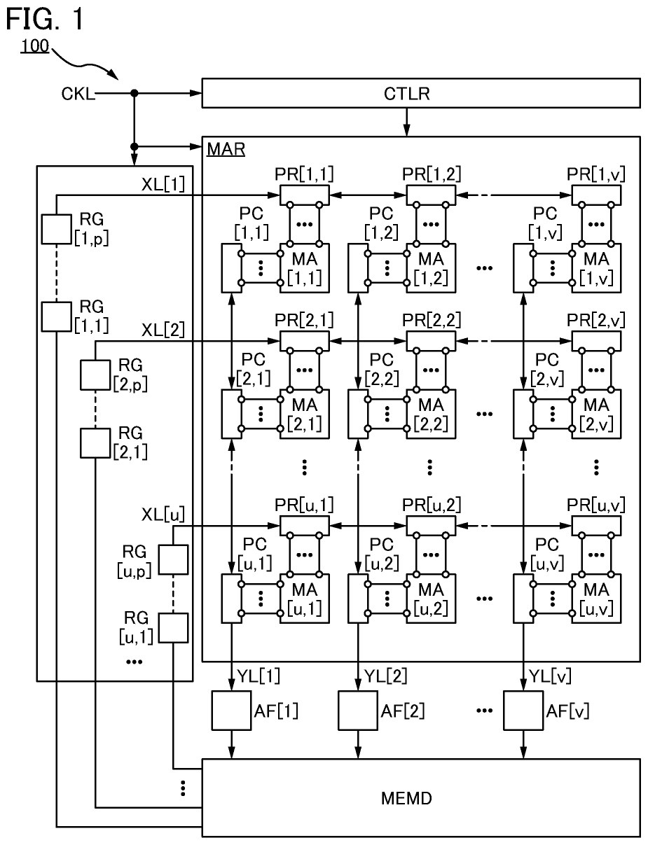

FIG. 1 is a block diagram illustrating a structure example of an operation apparatus 100. The operation apparatus 100 includes a control circuit CTLR, a MAC (Multiply-Accumulate) array MAR, a memory unit MEMD, and a circuit AF[1] to a circuit AF[v] (v is an integer of 2 or more). The MAC array MAR includes, for example, a plurality of operation circuits MA, and the operation circuits MA are arranged in a matrix of u×v (u is an integer of 2 or more) in the MAC array MAR. That is, the MAC array MAR includes u×v operation circuits MA. Note that to indicate the positions where the operation circuits MA are provided, [,] is added to each of their reference numerals in FIG. 1. For example, the operation circuit MA positioned in the first row and the first column is represented as an operation circuit MA[1,1], and the operation circuit MA positioned in the u-th row and the v-th column is represented as an operation circuit MA[u,v].

The operation circuit MA has a function of MAC, for example. Specifically, the operation circuit MA has a function of performing a product-sum operation of first data (e.g., w[1] to w[m], where m is a positive integer) and second data (e.g., x[1] to x[m]). Note that, for example, the first data can be one of multiplier data and multiplicand data, and the second data can be the other of the multiplier data and the multiplicand data. For example, when an operation in a hierarchical neural network is performed in the operation apparatus 100, in which the first data is a weighting coefficient and the second data is the value of an output signal of a neuron, the sum of products of the weighting coefficient and the value of the output signal of the neuron can be calculated.

The MAC array MAR further includes a plurality of programmable switches PR and a plurality of programmable switches PC. In FIG. 1, one of the plurality of programmable switches PR is electrically connected to one of the plurality of operation circuits MA, and one of the plurality of programmable switches PC is electrically connected to one of the plurality of operation circuits MA. Therefore, in a manner similar to that for the operation circuits MA, [,] is added to each of the reference numerals of the programmable switches PR and the programmable switches PC in FIG. 1 to indicate their positions.

The number of wirings electrically connected between the operation circuit MA and the programmable switch PR may be one or may be two or more. The number of wirings electrically connected between the operation circuit MA and the programmable switch PC may be one or may be two or more. In other words, the number of wirings electrically connecting the programmable switch PR and the programmable switch PC to the operation circuit MA can be determined in accordance with the number of terminals of the operation circuit MA.

The programmable switch PR[1,1] to the programmable switch PR[1,v], which are positioned in the first row of the MAC array MAR, are electrically connected in series. Similarly, the programmable switch PR[2,1] to the programmable switch PR[2,v], which are positioned in the second row of the MAC array MAR, are electrically connected in series; and the programmable switch PR[u,1] to the programmable switch PR[u,v], which are positioned in the u-th row of the MAC array MAR, are electrically connected in series.

The programmable switch PC[1,1] to the programmable switch PC[u,1], which are positioned in the first column of the MAC array MAR, are electrically connected in series. Similarly, the programmable switch PC[1,2] to the programmable switch PC[u,2], which are positioned in the second column of the MAC array MAR, are electrically connected in series; and the programmable switch PC[1,v] to the programmable switch PC[u,v], which are positioned in the v-th column of the MAC array MAR, are electrically connected in series.

The programmable switch PR[1,1] to the programmable switch PR[u,1] are, for example, electrically connected to a wiring XL[1] to a wiring XL[u], respectively. The programmable switch PC[u,1] to the programmable switch PC[u,v] are, for example, electrically connected to a wiring YL[1] to a wiring YL[v], respectively.

The wiring XL[1] to the wiring XL[u] are each electrically connected to the memory unit MEMD via a plurality of registers RG, for example. The wiring YL[1] to the wiring YL[v] are each electrically connected to the memory unit MEMD, for example.

In order to execute a product-sum operation of first data and second data in the MAC array MAR, the memory unit MEMD has a function of retaining the second data that is to be input to the MAC array MAR through the wiring XL[1] to the wiring XL[u], for example. In addition, for example, the memory unit MEMD has a function of retaining results of the product-sum operation of the first data and the second data transmitted from the MAC array MAR through the wiring YL[1] to the wiring YL[v].

The plurality of registers RG electrically connected to the wirings XL[1] to XL[u] are provided to perform pipeline processing in the operation apparatus 100. As for the plurality of registers RG, specifically, for example, in FIG. 1, the register RG[1,1] to the register RG[1,p] (p is an integer of 1 or more) are provided for the wiring XL[1] between the programmable switch PR[1,1] of the MAC array MAR and the memory unit MEMD. Note that input terminals and output terminals of the adjacent registers RG of the register RG[1,1] to the register RG[1,p] are electrically connected, the input terminal of the register RG[1,1] is electrically connected to the memory unit MEMD, and the output terminal of the register RG[1,p] is electrically connected to the programmable switch PR[1,1].

Similarly, the register RG[2,1] to the register RG[2,p] are provided for the wiring XL[2] between the programmable switch PR[2,1] of the MAC array MAR and the memory unit MEMD. Note that input terminals and output terminals of the adjacent registers RG of the register RG[2,1] to the register RG[2,p] are electrically connected, the input terminal of the register RG[2,1] is electrically connected to the memory unit MEMD, and the output terminal of the register RG[2,p] is electrically connected to the programmable switch PR[2,1]. The register RG[u,1] to the register RG[u,p] are provided for the wiring XL[u] between the programmable switch PR[u,1] of the MAC array MAR and the memory unit MEMD. Note that input terminals and output terminals of the adjacent registers RG of the register RG[u,1] to the register RG[u,p] are electrically connected, the input terminal of the register RG[u,1] is electrically connected to the memory unit MEMD, and the output terminal of the register RG[u,p] is electrically connected to the programmable switch PR[u,1].

For example, the register RG has a function of temporarily retaining data (which can be, for example, a digital data or can be a potential in some cases) supplied to the input terminal of the register RG when a pulse voltage is supplied as a clock signal to the register RG. Furthermore, the register RG has a function of outputting the data retained in the register RG to the output terminal of the register RG, for example. In this specification and the like, the register RG temporarily retains the data supplied to the input terminal of the register RG when a high-level potential is supplied as a clock signal to the register RG and outputs first data to the output terminal of the register RG. Therefore, the register RG functions as an input register for transmitting first data to the MAC array MAR.

Note that the clock signal can be a signal transmitted by a wiring CKL described later, for example.

The register RG preferably retains 8-bit data, further preferably 16-bit data, still further preferably data of 32 or more bits, for example.

For example, the register RG[1,1] to the register RG[1,p] that are between the programmable switch PR[1,1] and the memory unit MEMD may be replaced with one shift register. Similarly, for example, the register RG[2,1] to the register RG[2,p] that are between the programmable switch PR[2,1] and the memory unit MEMD may be replaced with one shift register, and the register RG[u,1] to the register RG[u,p] that are between the programmable switch PR[u,1] and the memory unit MEMD may be replaced with one shift register.

As described above, when the plurality of registers RG are electrically connected in series between the memory unit MEMD and the MAC array MAR as illustrated in FIG. 1, data transmission from the memory unit MEMD to the MAC array MAR can be performed by pipelining. Furthermore, with the plurality of registers RG connected in series, it is possible to reduce delay of a signal for transmitting data, which is caused from a parasitic resistance, a parasitic capacitance, and the like.

The control circuit CTLR is electrically connected to the MAC array MAR. The wiring CKL is electrically connected to the control circuit CTLR and the MAC array MAR.

The wiring CKL functions as a wiring for supplying a clock signal, for example. The clock signal can be, for example, a pulse voltage or the like.

The control circuit CTLR has a function of controlling the operation circuit MA[1,1] to the operation circuit MA[u,v] included in the MAC array MAR, for example. Specifically, for example, the control circuit CTLR has a function of transmitting a selection signal for writing data to a memory unit (corresponding to a memory unit OSM or the like described later) included in the operation circuit MA and a function of transmitting the data. Furthermore, for example, the control circuit CTLR has a function of transmitting a signal for controlling registers (registers RG2 to RG4 and the like described later) included in the operation circuit MA. The control circuit CTLR may have a function of generating a different clock signal on the basis of the clock signal from the wiring CKL.

The circuit AF[1] to the circuit AF[v] are electrically connected to the wiring YL[1] to the wiring YL[v], respectively. Furthermore, the circuit AF[1] to the circuit AF[v] are each electrically connected to the memory unit MEMD.

Each of the circuit AF[1] to the circuit AF[v] can be, for example, a function circuit that outputs the value of an activation function by using results of a product-sum operation transmitted from the wiring YL[1] to the wiring YL[v]. Note that the activation function can be a step function, a ReLU function, a sigmoid function, a tanh function, or the like, for example.

Each of the circuit AF[1] to the circuit AF[v] may be a circuit that performs pooling processing, for example. The pooling processing can be max pooling, average pooling, or Lp pooling, for example.

Each of the circuit AF[1] to the circuit AF[v] may be a circuit that includes a function circuit outputting the value of an activation function, a circuit performing pooling processing, or the like.

In other words, it is possible to perform an operation in a hierarchical neural network, an operation in a convolutional neural network (CNN), or the like by using the operation apparatus 100.

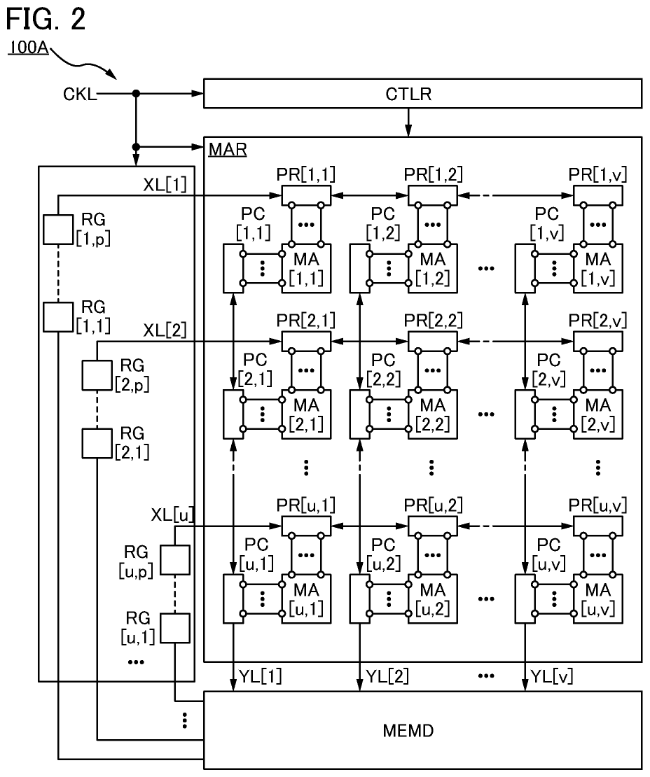

Note that one embodiment of the present invention is not limited to the semiconductor device illustrated in FIG. 1. In one embodiment of the present invention, the structure of the semiconductor device illustrated in FIG. 1 may be changed depending on the situation. For example, a structure in which the circuit AF[1] to the circuit AF[v] are not provided in the operation apparatus 100 in FIG. 1 may be employed as in an operation apparatus 100A in FIG. 2.

### <Structure Example of Operation Circuit MA>

Next, a structure example of the operation circuit MA will be described.

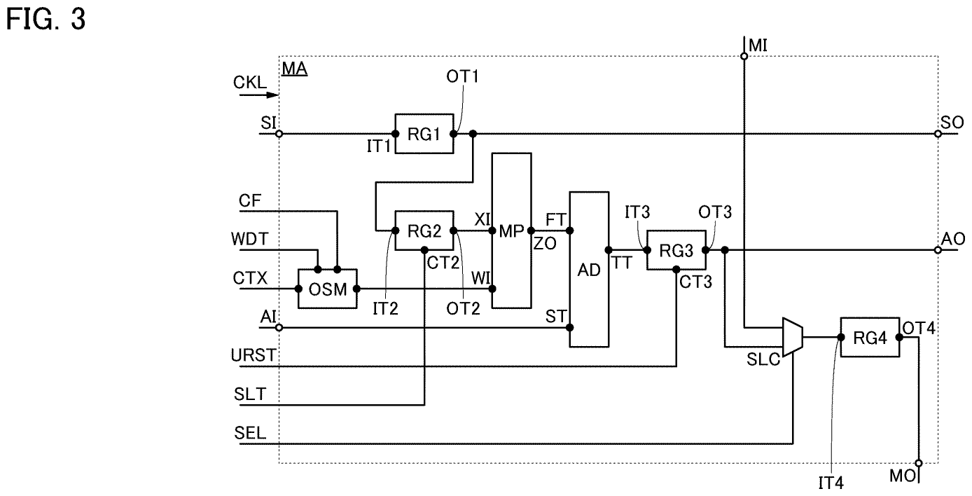

FIG. 3 is a block diagram illustrating an example of the operation circuit MA. The operation circuit MA includes a register RG1, a register RG2, a register RG3, a register RG4, a multiplier NP, an adder AD, a selector SLC, and a memory unit OSM, for example.

The operation circuit MA illustrated in FIG. 3 further includes, a terminal SI, a terminal SO, a terminal MI, a terminal MO, a terminal AI, and a terminal AO, for example.

The register RG1 includes a terminal ITT corresponding to an input terminal and a terminal OT1 corresponding to an output terminal. The register RG2 includes a terminal IT2 corresponding to an input terminal, a terminal OT2 corresponding to an output terminal, and a terminal CT2 corresponding to an enable input terminal. The register RG3 includes a terminal IT3 corresponding to an input terminal, a terminal OT3 corresponding to an output terminal, and a terminal CT3 corresponding to an enable input terminal. The register RG4 includes a terminal IT4 corresponding to an input terminal and a terminal OT4 corresponding to an output terminal. Although not illustrated in FIG. 3, each of the register RGT to the register RG4 is electrically connected to the wiring CKL and receives a clock signal from the wiring CKL.

The multiplier MP includes a terminal WI corresponding to a first input terminal, a terminal XI corresponding to a second input terminal, and a terminal ZO corresponding to an output terminal. The adder AD includes a terminal FT corresponding to a first input terminal, a terminal ST corresponding to a second input terminal, and a terminal TT corresponding to an output terminal.

The terminal ITT of the register RGT is electrically connected to the terminal SI, and the terminal OT1 of the register RG1 is electrically connected to the terminal IT2 of the register RG2 and the terminal SO. The terminal OT2 of the register RG2 is electrically connected to the terminal XI of the multiplier MP, and the terminal CT2 of the register RG2 is electrically connected to a wiring SLT.

The memory unit OSM is electrically connected to a wiring CF, a wiring WDT, and a wiring CTX. In addition, the memory unit OSM is electrically connected to the terminal WI of the multiplier MP.

The terminal ZO of the multiplier MP is electrically connected to the terminal FT of the adder AD. The terminal ST of the adder AD is electrically connected to the terminal AI.

The terminal IT3 of the register RG3 is electrically connected to the terminal TT of the adder AD, and the terminal OT3 of the register RG3 is electrically connected to the terminal AO and a first input terminal of the selector SLC. The terminal CT3 of the register RG3 is electrically connected to a wiring URST.

The terminal IT4 of the register RG4 is electrically connected to an output terminal of the selector SLC, and the terminal OT4 of the register RG4 is electrically connected to the terminal MO.

A second input terminal of the selector SLC is electrically connected to the terminal MI. A control terminal of the selector SLC is electrically connected to a wiring SEL.

For example, the register RG1 has a function of temporarily retaining data (which can be, for example, a digital data or can be a potential in some cases) supplied to the terminal ITT when a pulse voltage is supplied as a clock signal. Note that in this specification and the like, for example, when potential change of the clock signal from a low-level potential to a high-level potential occurs, the register RG1 temporarily retains the data supplied to the input terminal of the register RG1 and outputs the data from the output terminal of the register RGT. Furthermore, the register RGT has a function of outputting the data retained in the register RGT to the terminal OT1, for example.

For example, the register RG2 can be data supplied to the terminal IT2 (which can be, for example, a digital data when an enable signal is supplied to the terminal CT2 serving as an enable input terminal and a pulse voltage is supplied as a clock signal. Note that in this specification and the like, for example, when a high-level potential is input to the enable input terminal and potential change of the clock signal from a low-level potential to a high-level potential occurs, the register RG2 temporarily retains the data supplied to the input terminal of the register RG2. Furthermore, the register RG2 has a function of outputting the data retained in the register RG2 to the terminal OT2, for example.

When a low-level potential is input to the terminal CT2 of the register RG2, the register RG2 does not retain data input to the terminal IT2 even though potential change of the clock signal from a low-level potential to a high-level potential occurs. Note that output of the data retained in the register RG2 is performed even when the low-level potential is input to the terminal CT2 of the register RG2.

The wiring SLT functions as a wiring that supplies an enable signal to the register RG2, for example.

For example, when the potential supplied by the wiring CKL is changed from a low-level potential to a high-level potential, the register RG1 retains data input to the terminal ITT and transmits the data to the terminal IT2 of the register RG2 from the terminal OT1 of the register RGT. For example, when the potential supplied by the wiring CKL is changed from a low-level potential to a high-level potential with a high-level potential supplied to the wiring SLT, the register RG2 retains the data input to the terminal IT2 and transmits the data to the terminal XI of the multiplier MP from the terminal OT2 of the register RG2.

The memory unit OSM has a function of retaining data corresponding to context, for example. Here, data corresponding to context can be first data used for an operation in the multiplier MP, for example. The memory unit OSM has a function of selecting a data set corresponding to a context signal by obtaining the context signal from the wiring CTX and inputting a plurality pieces of first data to the terminal WI of the multiplier MP. Note that the context signal may be either a digital signal or an analog signal.

In addition, the memory unit OSM has a function of obtaining a writing signal from the wiring WDT to perform writing on configuration data transmitted from the wiring CF with respect to context according to the write signal.

Note that the context signal, the write signal, and the configuration data can be supplied from the control circuit CTLR, for example. In this case, the wiring CTX, the wiring WDT, and the wiring CF may be electrically connected to the control circuit CTLR.

The multiplier MP has, for example, a function of multiplying first data input to the terminal WI and second data input to the terminal XI and outputting a result of the multiplication (hereinafter, referred to as multiplication data) to the terminal ZO. For example, when w is input as first data to the terminal WI and x is input as second data to the terminal XI, w×x is output as multiplication data to the terminal ZO of the multiplier MP.

The adder AD has, for example, a function of adding the multiplication data input to the terminal ZO and data input to the terminal ST and outputting a result of the addition (hereinafter, referred to as addition data) to the terminal TT.

The register RG3 has, for example, a function of temporarily retaining the addition data supplied to the terminal IT3 when an enable signal is supplied to the terminal CT3 serving as an enable input terminal and a pulse voltage is supplied as a clock signal. Note that in this specification and the like, for example, when a high-level potential is input to the enable input terminal and potential change of the clock signal from a low-level potential to a high-level potential occurs, the register RG3 temporarily retains the data supplied to the input terminal of the register RG3. Furthermore, the register RG3 has a function of outputting the data retained in the register RG3 to the terminal OT3, for example.

When a low-level potential is supplied to the terminal CT3 of the register RG3, the register RG3 does not retain data input to the terminal IT3 even though potential change of the clock signal from a low-level potential to a high-level potential occurs. Note that output of the data retained in the register RG3 is performed even when the low-level potential is input to the terminal CT3 of the register RG3.

The wiring URST functions as a wiring that supplies an enable signal to the register RG3, for example.

The selector SLC has a function of establishing electrical continuity between one of the first input terminal and the second input terminal and the output terminal and breaking electrical continuity between the other of the first input terminal and the second input terminal and the output terminal. Note that whether the selector SLC selects the first input terminal or the second input terminal as a terminal to have electrical continuity with the output terminal is determined depending on the potential of the wiring SEL input to the control terminal. Here, as an example, the selector SLC establishes electrical continuity between the first input terminal and the output terminal when a high-level potential is input to the control terminal; the selector SLC establishes electrical continuity between the second input terminal and the output terminal when a low-level potential is input to the control terminal.

In the selector SLC, when electrical continuity is established between the first input terminal and the output terminal and electrical continuity is not established between the second input terminal and the output terminal, the addition data from the terminal OT3 of the register RG3 is input to the terminal IT4 of the register RG4. Alternatively, in the selector SLC, when electrical continuity is established between the second input terminal and the output terminal and electrical continuity is not established between the first input terminal and the output terminal, data from the terminal MI is input to the terminal IT4 of the register RG4.

The wiring SEL functions as a wiring that supplies a signal for controlling the selector SLC, for example.

For example, the register RG4 can be data supplied to the terminal IT4 (which can be, for example, a digital data when a pulse voltage is supplied as a clock signal. Note that in this specification and the like, for example, when potential change of the clock signal from a low-level potential to a high-level potential occurs, the register RG4 temporarily retains the data supplied to the input terminal of the register RG4. Furthermore, the register RG4 has a function of outputting the data retained in the register RG4 to the terminal OT4, for example.

### <Structure of Programmable Switch>

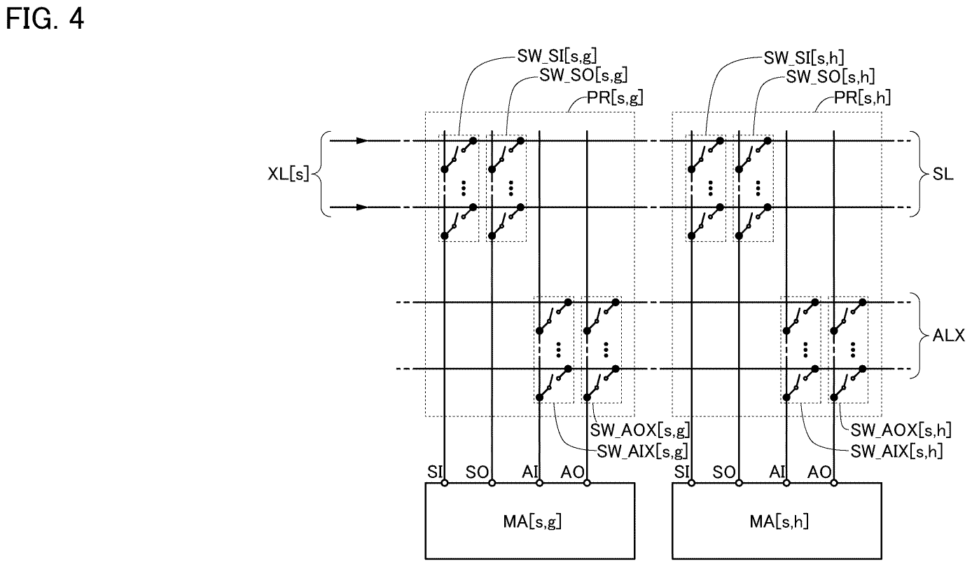

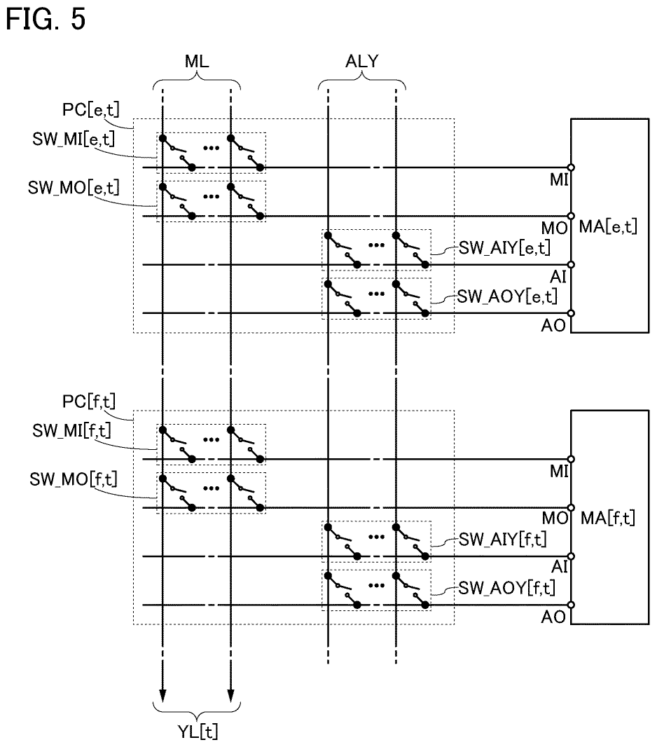

Next, the programmable switch PR and the programmable switch PC will be described with reference to FIG. 4 and FIG. 5.

The programmable switch PR[s,1] to the programmable switch PR[s,v] (not illustrated in FIG. 1 and FIG. 2) positioned in the s-th row (s is an integer greater than or equal to 1 and less than or equal to u) have a function of controlling conduction and non-conduction states among the operation circuits MA[s,1] to MA[s,v].

For example, the programmable switch PR can have a circuit structure illustrated in FIG. 4. Note that FIG. 4 illustrates not only a structure example of the programmable switch PR[s,g] (g is an integer greater than or equal to 1 and less than or equal to v−1) and the programmable switch PR[s,h] (h is an integer greater than g and less than or equal to v) but also the operation circuit MA[s,g] and the operation circuit MA[s,h].

FIG. 4 also illustrates the terminals SI, the terminals SO, the terminals AI, and the terminals AO, which are terminals included in the operation circuit MA[s,g] and the operation circuit MA[s,h].

The programmable switch PR[s,g] and the programmable switch PR[s,h] are electrically connected to a plurality of wirings SL. Furthermore, the programmable switch PR[s,g] and the programmable switch PR[s,h] are electrically connected to a plurality of wirings ALX.

The plurality of wirings SL and the plurality of wirings ALX are wirings extending in the row direction of the MAC array MAR, for example.

The plurality of wirings SL are electrically connected to the wiring XL[s]. Although the wiring XL[s] is illustrated as a plurality of wirings in FIG. 4, the wiring XL[s] may be one wiring electrically connected to one of the plurality of wirings SL.

For example, the programmable switch PR[s,g] and the programmable switch PR[s,h] each include a plurality of switches. FIG. 4 illustrates, as an example, a structure in which the programmable switch PR[s,g] includes a plurality of switches SW_SI[s,g], a plurality of switches SW_SO[s,g], a plurality of switches SW_AIX[s,g], and a plurality of switches SW_AOX[s,g]; and the programmable switch PR[s,h] includes a plurality of switches SW_SI[s,h], a plurality of switches SW_SO[s,h], a plurality of switches SW_AIX[s,h], and a plurality of switches SW_AOX[s,h].

The terminal SI of the operation circuit MA[s,g] is electrically connected to each of first terminals of the plurality of switches SW_SI[s,g], and a second terminal of one of the plurality of switches SW_SI[s,g] is electrically connected to one of the plurality of wirings SL. The terminal SO of the operation circuit MA[s,g] is electrically connected to each of first terminals of the plurality of switches SW_SO[s,g], and a second terminal of one of the plurality of switches SW_SO[s,g] is electrically connected to one of the plurality of wirings SL. The terminal AI of the operation circuit MA[s,g] is electrically connected to each of first terminals of the plurality of switches SW_AIX[s,g], and a second terminal of one of the plurality of switches SW_AIX[s,g] is electrically connected to one of the plurality of wirings ALX. The terminal AO of the operation circuit MA[s,g] is electrically connected to each of first terminals of the plurality of switches SW_AOX[s,g], and a second terminal of one of the plurality of switches SW_AOX[s,g] is electrically connected to one of the plurality of wirings ALX.

The terminal SI of the operation circuit MA[s,h] is electrically connected to each of first terminals of the plurality of switches SW_SI[s,h], and a second terminal of one of the plurality of switches SW_SI[s,h] is electrically connected to one of the plurality of wirings SL. The terminal SO of the operation circuit MA[s,h] is electrically connected to each of first terminals of the plurality of switches SW_SO[s,h], and one of second terminals of the plurality of switches SW_SO[s,h] is electrically connected to one of the plurality of wirings SL. The terminal AI of the operation circuit MA[s,h] is electrically connected to each of first terminals of the plurality of switches SW_AIX[s,h], and a second terminal of one of the plurality of switches SW_AIX[s,h] is electrically connected to one of the plurality of wirings ALX. The terminal AO of the operation circuit MA[s,h] is electrically connected to each of first terminals of the plurality of switches SW_AOX[s,h] and a second terminal of one of the plurality of switches SW_AOX[s,h] is electrically connected to one of the plurality of wirings ALX.

For example, in the case where electrical continuity is established between the terminal SO of the operation circuit MA[s,g] and the terminal SI of the operation circuit MA[s,h], one of the plurality of wirings SL is selected, the switch SW_SO[s,g] and the switch SW_SI[s,h] that are connected directly to the wiring are turned on, and the other switches SW_SO[s,g] and the other switches SW_SI[s,h] are turned off.

Similarly to the programmable switch PR, the programmable switch PC[1,t] to the programmable switch PC[u,t] (not illustrated in FIG. 1 and FIG. 2) positioned in the t-th column (t is an integer greater than or equal to 1 and less than or equal to v) have a function of controlling conduction and non-conduction states among the operation circuits MA[1,t] to MA[u,t].

For example, the programmable switch PC can have a circuit structure illustrated in FIG. 5. Note that FIG. 5 illustrates not only a structure example of the programmable switch PC[e,t] (e is an integer greater than or equal to 1 and less than or equal to u−1) and the programmable switch PC[f,t] (f is an integer greater than e and less than or equal to u) but also the operation circuit MA[e,t] and the operation circuit MA[f,t].

FIG. 5 also illustrates the terminals AI, the terminals AO, the terminals MI, and the terminals MO, which are terminals included in the operation circuit MA[e,t] and the operation circuit MA[f,t].

The programmable switch PC[e,t] and the programmable switch PC[f,t] are electrically connected to a plurality of wirings ML and a plurality of wirings ALY.

The plurality of wirings ML and the plurality of wirings ALY are wirings extending in the column direction of the MAC array MAR, for example.

The plurality of wirings ML are electrically connected to the wiring YL[t]. Although the wiring YL[t] is illustrated as a plurality of wirings in FIG. 5, the wiring YL[t] may be one wiring electrically connected to one of the plurality of wirings ML.

For example, the programmable switch PC[e,t] and the programmable switch PC[f,t] each include a plurality of switches. FIG. 5 illustrates, as an example, a structure in which the programmable switch PC[e,t] includes a plurality of switches SW_MI[e,t], a plurality of switches SW_MO[e,t], a plurality of switches SW_AIY[e,t], and a plurality of switches SW_AOY[e,t]; and the programmable switch PC[f,t] includes a plurality of switches SW_MI[f,t] a plurality of switches SW_MO[f,t], a plurality of switches SW_AIY[f,t], and a plurality of switches SW_AOY[f,t].

The terminal MI of the operation circuit MA[e,t] is electrically connected to each of first terminals of the plurality of switches SW_MI[e,t], and a second terminal of one of the plurality of switches SW_MI[e,t] is electrically connected to one of the plurality of wirings ML. The terminal MO of the operation circuit MA[e,t] is electrically connected to each of first terminals of the plurality of switches SW_MO[e,t], and a second terminal of one of the plurality of switches SW_MO[e,t] is electrically connected to one of the plurality of wirings ML. The terminal AI of the operation circuit MA[e,t] is electrically connected to each of first terminals of the plurality of switches SW_AIY[e,t], and a second terminal of one of the plurality of switches SW_AIY[e,t] is electrically connected to one of the plurality of wirings ALY. The terminal AO of the operation circuit MA[e,t] is electrically connected to each of first terminals of the plurality of switches SW_AOY[e,t], and a second terminal of one of the plurality of switches SW_AOY[e,t] is electrically connected to one of the plurality of wirings ALY.

The terminal MI of the operation circuit MA[f,t] is electrically connected to each of first terminals of the plurality of switches SW_MI[f,t], and a second terminal of one of the plurality of switches SW_MI[f,t] is electrically connected to one of the plurality of wirings ML. The terminal MO of the operation circuit MA[f,t] is electrically connected to each of first terminals of the plurality of switches SW_MO[f,t], and a second terminal of one of the plurality of switches SW_MO[f,t] is electrically connected to one of the plurality of wirings ML. The terminal AI of the operation circuit MA[f,t] is electrically connected to each of first terminals of the plurality of switches SW_AIY[f,t], and a second terminal of one of the plurality of switches SW_AIY[f,t] is electrically connected to one of the plurality of wirings ALY. The terminal AO of the operation circuit MA[f,t] is electrically connected to each of first terminals of the plurality of switches SW_AOY[f,t], and a second terminal of one of the plurality of switches SW_AOY[f,t] is electrically connected to one of the plurality of wirings ALY.

For example, in the case where electrical continuity is established between the terminal MO of the operation circuit MA[e,t] and the terminal MI of the operation circuit MA[f,t], one of the plurality of wirings ML is selected, the switch SW_MO[e,t] and the switch SW_MI[f,t] that are connected directly to the wiring are turned on, and the other switches SW_MO[e,t] and the other switches SW_MI[f,t] are turned off. For example, in the case where electrical continuity is established between the terminal AO of the operation circuit MA[e,t] and the terminal AI of the operation circuit MA[f,t], one of the plurality of wirings ALY is selected, the switch SW_AOY[e,t] and the switch SW_SI[f,t] that are connected directly to the wiring are turned on, and the other switches SW_AOY[e,t] and the other switches SW_AIY[f,t] are turned off.

FIG. 4 illustrates the structure in which the programmable switch PR is electrically connected to the terminal SI, the terminal SO, the terminal AI, and the terminal AO of the operation circuit MA and FIG. 5 illustrates the structure in which the programmable switch PC is electrically connected to the terminal AI, the terminal AO, the terminal MI, and the terminal MO of the operation circuit MA; however, one embodiment of the present invention is not limited thereto. For example, the operation apparatus 100 may have a structure in which the programmable switch PR is electrically connected to not only the terminal SI, the terminal SO, the terminal AI, and the terminal AO but also the terminal MI and the terminal MO and may have a structure in which the programmable switch PC is electrically connected to not only the terminal AI, the terminal AO, the terminal MI, and the terminal MO but also the terminal SI and the terminal SO.

The MAC array MAR can change the scale of a circuit relating to a product-sum operation with the programmable switch PR[1,1] to the programmable switch PR[u,v] and the programmable switch PC[1,1] to the programmable switch PC[u,v]. For example, in the case where a product-sum operation is perfumed using the MAC array MAR and a sufficient operation can be performed only with the operation circuit MA[1,t] to the operation circuit MA[u,t], the programmable switch PR[1,t] to the programmable switch PR[u,t] and the programmable switch PC[1,t] to the programmable switch PC[u,t] are turned on and the other programmable switches are turned off.

### <Operation Method>

Next, an operation example of the operation apparatus 100 will be described. Note that in this operation method, an operation example in an operation in a convolutional neural network (CNN) will be described.

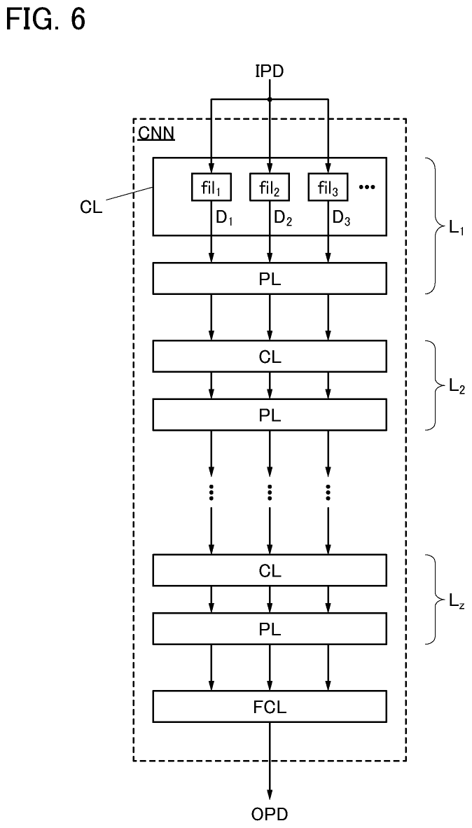

A CNN is one of calculation models used for feature extraction of an image or the like. FIG. 6 illustrates a structure example of the CNN. The CNN is formed of a convolutional layer CL, a pooling layer PL, and a fully connected layer FCL. In this operation method, for example, image data IPD read out from the memory unit MEMD is input to the MAC array MAR, and feature extraction is performed.

The convolutional layer CL has a function of performing convolutional processing on the image data. The convolutional processing is performed by repeating a product-sum operation using a partial region of the image data and the filter value of a weight filter. By the convolution in the convolutional layer CL, a feature of an image are extracted.

For the convolutional processing, one or a plurality of weight filters can be used. In the case of using a plurality of weight filters, a plurality of features of the image data can be extracted. FIG. 6 illustrates a filter fil₁, a filter fil₂, and a filter fil₃ as the plurality of weight filters. Although three filters are illustrated in FIG. 6, the number of filters used in the convolution processing may be one, two, four, or more. FIG. 6 illustrates an example in which the image data input to the convolutional layer CL is subjected to filter processing using the filters fil₁, fil₂, and fil₃ to generate image data D₁, D₂, and D₃.

For example, an operation with an activation function may be performed on the image data D₁, D₂, and D₃ that have been subjected to convolution. As the activation function, a ReLU (Rectified Linear Units) or the like can be used, for example. A ReLU is a function that outputs “0” when an input value is negative and outputs the input value as it is when the input value is greater than or equal to “0”. Alternatively, as the activation function, a sigmoid function, a tanh function, or the like can be used as well.

Regardless of whether or not the operation with the activation function is performed, the image data D₁, D₂, and D₃ are output to the pooling layer PL, for example. The pooling layer PL has a function of performing pooling on the image data input from the convolutional layer CL. Pooling is processing in which the image data is partitioned into a plurality of regions and predetermined data extracted from each of the regions are arranged in a matrix to form new data. By the pooling, the image data is shrunk while the features extracted by the convolution layer CL remains. As the pooling processing, max pooling, average pooling, Lp pooling, or the like can be used.

In the CNN, feature extraction is performed using the above convolutional processing and pooling processing, for example. Note that the CNN may include a plurality of convolutional layers CL and/or a plurality of pooling layers PL. FIG. 6 illustrates, as an example, a structure in which z layers L (a layer L₁ to a layer L₂) (here, z is an integer greater than or equal to 1) each of which is formed of the convolutional layer CL and the pooling layer PL are provided and the convolutional processing and the pooling processing are performed z times. In this case, feature extraction can be performed in each layer L, which enables more advanced feature extraction. Note that FIG. 6 illustrates the layer L₁, the layer L₂, and the layer L₂, and the other layers L are omitted.

The fully connected layer FCL has a function of determining an image using image data obtained through the layer L₁ to the layer L₂, for example. The fully connected layer FCL has a structure in which all the nodes in one layer are connected to all the nodes in the next layer. That is, an operation by a fully connected neural network (FNN) is performed in the fully connected layer FCL. The image data output from the convolutional layer CL or the pooling layer PL is a two-dimensional feature map and is unfolded into a one-dimensional feature map when input to the fully connected layer FCL. Then, image data OPD obtained as a result of inference by the fully connected layer FCL is output.

### <<Operation 1 in Convolutional Layer CL>>

Here, an operation method in the convolutional layer CL with the use of the operation apparatus 100 will be described. Note that the operation circuits MA included in the MAC array MAR of the operation apparatus 100 are arranged in a matrix of 9 rows and 10 columns, for example. In other words, the MAC array MAR used in this operating method includes the operation circuit MA[1,1] to the operation circuit MA[9,10].

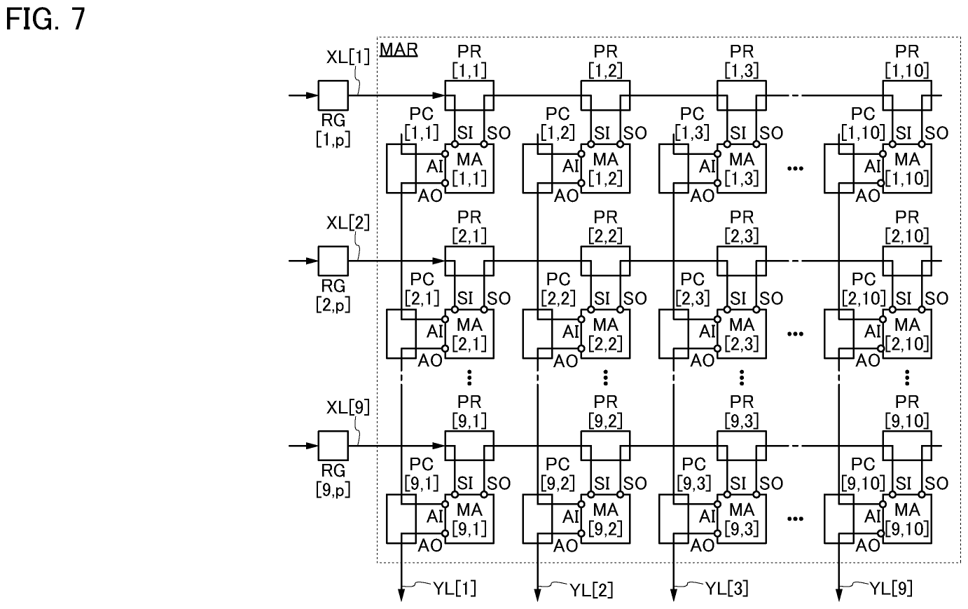

Furthermore, the MAC array MAR in this operating method has a circuit structure with the programmable switches PR and the programmable switches PC, as illustrated in FIG. 7. Specifically, in the operation circuits MA included in one row of the MAC array MAR, the programmable switches PR are set in a manner such that the terminal SO of the operation circuit MA is electrically continuous with the terminal SI of the next operation circuit MA. For example, the programmable switch PR[1,1] and the programmable switch PR[1,2] are set in a manner such that the terminal SO of the operation circuit MA[1,1] is electrically continuous with the terminal SI of the operation circuit MA[1,2], and the programmable switch PR[1,2] and the programmable switch PR[1,3] are set in a manner such that the terminal SO of the operation circuit MA[1,2] is electrically continuous with the terminal SI of the operation circuit MA[1,3]. Note that the wiring XL[1] is electrically continuous with the terminal SI of the operation circuit MA[1,1] via the programmable switch PR[1,1]. As described above, in this operating method, the programmable switches PR are set in a manner such that the operation circuits MA in each row of the MAC array MAR are electrically connected in series.

In the MAC array MAR in this operation method, specifically, in the operation circuits MA included in one column of the MAC array MAR, the programmable switches PC are set in a manner such that the terminal AO of the operation circuit MA is electrically continuous with the terminal AI of the next operation circuit MA. For example, the programmable switch PC[1,1] and the programmable switch PC[2,1] are set in such a manner that the terminal AO of the operation circuit MA[1,1] is electrically continuous with the terminal AI of the operation circuit MA[2,1]. Note that the wiring YL[1] is electrically continuous with the terminal AO of the operation circuit MA[9,1] via the programmable switch PC[9,1]. As described above, in this operating method, the programmable switches PC are set in a manner such that the operation circuits MA in each column of the MAC array MAR are electrically connected in series.

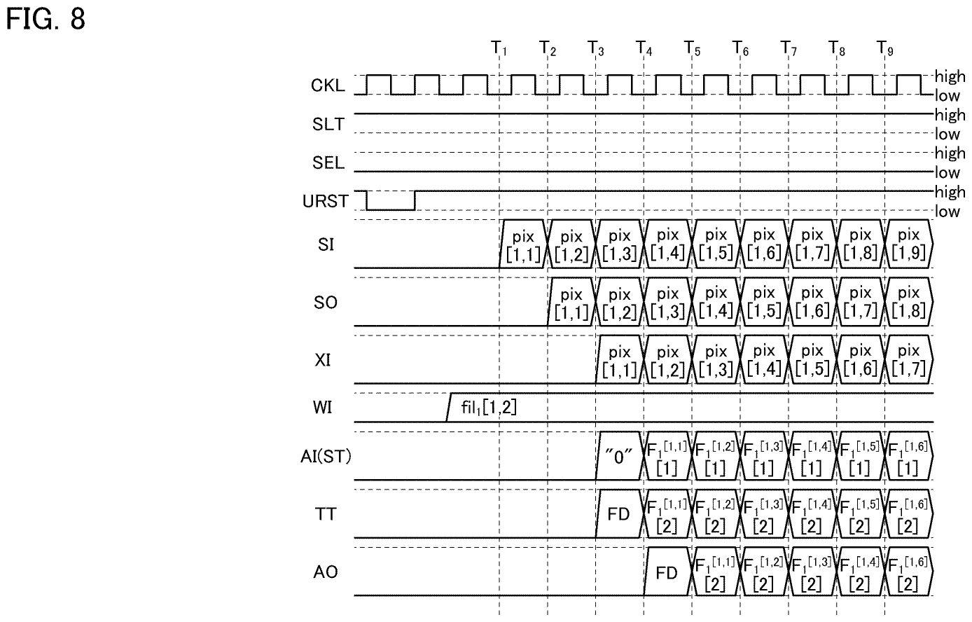

FIG. 8 is a timing chart showing change in data input to the terminal SI, the terminal SO, the terminal XI, the terminal WI, the terminal AI (the terminal ST), the terminal TT, and the terminal AO included in the operation circuit MA[2,1] in a period from Time T₁ to Time T₉ and at times around the period. FIG. 8 also shows change in the potentials of the wiring CKL, the wiring SLT, the wiring SEL, and the wiring URST. Note that “high” denotes a high-level potential and “low” denotes a low-level potential in FIG. 8.

Note that in this operation method, a high-level potential is input to the wiring SLT all the times. Thus, the register RG2 is in an enable state in the middle of this operating method.

In this operating method, a low-level potential is input to the wiring SEL all the times. Accordingly, in the selector SLC, electrical continuity is broken between the first input terminal and the output terminal and electrical continuity is established between the second input terminal and the output terminal.

A method for performing an operation in the MAC array MAR is described below using the timing chart of FIG. 8.

### [Step 0: Initialization]

First, an initialization operation is performed in the operation apparatus 100. Specifically, before Time T₁, it is preferable that data for initialization be input to the terminal SI, the terminal SO, a terminal XT, a terminal WT, the terminal AI (the terminal ST), the terminal TT, and the terminal AO of each of the operation circuits MA[1,1] to MA[9,10] (not shown in FIG. 8). The data for initialization can be data with a value of “0”, for example. The potential of the wiring URST is changed from a low-level potential to a high-level potential, so that the potential of the terminal AO is made appropriate by the register RG3. The potential of the terminal AO at this time is preferably a potential corresponding to the value of “0”, for example.

### [Step 1: Readout of Filter Value]

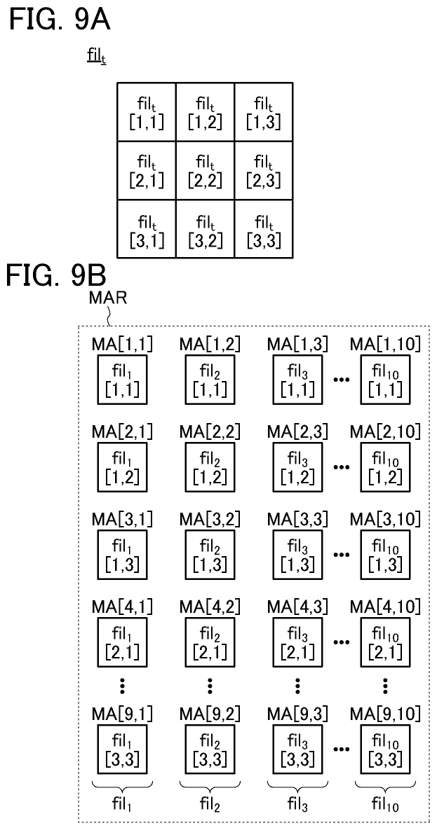

After Step 0 and before Time T₁, a filter value is read out from each of the memory units OSM of the operation circuits MA[1,1] to MA[9,10] of the MAC array MAR in the operation apparatus 100. Specifically, an operation in which a context signal is supplied from the wiring CTX and data corresponding to a desired context, i.e., a filter value, is read out from the memory unit OSM is performed. Here, as an example, the filter value of a filter filₜ is read to each of the memory units OSM of the operation circuits MA[1,t] to MA[9,t] positioned in the t-th column (here, t is an integer greater than or equal to 1 and less than or equal to 10). As an example, the filter filₜ has a matrix of three rows and three columns shown in FIG. 9A, and the filter filₜ has filₜ[1,1] to filₜ[3,3] as the matrix elements. For example, here, the memory unit OSM of the operation circuit MA[1,t] reads the filₜ[1,1], the memory unit OSM of the operation circuit MA[2,t] reads out the filₜ[1,2], the memory unit OSM of the operation circuit MA[3,t] reads out the filₜ[1,3], the memory unit OSM of the operation circuit MA[4,t] reads out the filₜ[2,1], the memory unit OSM of the operation circuit MA[5,t] reads out the filₜ[2,2], the memory unit OSM of the operation circuit MA[6,t] reads out the filₜ[2,3], the memory unit OSM of the operation circuit MA[7,t] reads out the filₜ[3,1], the memory unit OSM of the operation circuit MA[8,t] reads out the filₜ[3,2], and the memory unit OSM of the operation circuit MA[9,t] reads out the filₜ[3,3].

Thus, as illustrated in FIG. 9B, the filter fil₁ to the filter fil₁₀ are read out in the first column to the tenth column of the operation circuits MA in the MAC array MAR, respectively.

In each of the operation circuits MA[1,1] to MA[9,10], the filter value read out from the memory unit OSM is input to the terminal WI of the multiplier MP.

### [Step 2: Input of Image Data]

Next, an operation of inputting the image data IPD to the MAC array MAR will be described.

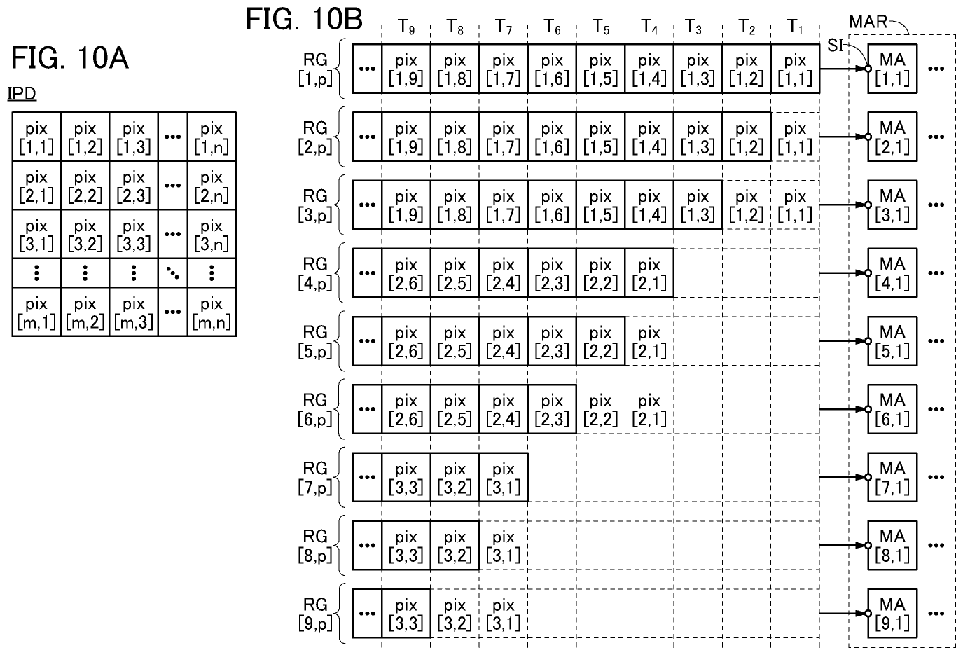

Here, as an example, the image data IPD is composed of a plurality pieces of pixel data pix[1,1] to pix[m,n] of m rows and n columns (here, m and n are each an integer of 1 or more) as illustrated in FIG. 10A.

The image data IPD is read out from the memory unit MEMD of the operation apparatus 100, for example.

Since the operation circuits MA of the MAC array MAR are arranged in a matrix of 9 rows and 10 columns, the register RG[1,p] to the register RG[9,p] are electrically connected to the MAC array MAR. In addition, the register RG[s,1] to the register RG[s,p] are electrically connected to the s-th row (here, s is an integer greater than or equal to 1 and less than or equal to 9) of the MAC array MAR. In other words, the pixel data pix read out from the memory unit MEMD is input to the operation circuit MA[s,1] of the MAC array MAR via the registers RG[s,1] to RG[s,p].

The register RG[s,1] to the register RG[s,p] sequentially transmit a plurality pieces of pixel data pix read out from the memory unit MEMD, for example, every time potential change from a low-level potential to a high-level potential is input as a clock signal to the wiring CKL.

FIG. 10B is a block diagram of the pixel data pix that is retained in each of the registers RG[1,p] to RG[9,p] and input to the MAC array MAR in the period from Time T₁ to Time T₉.

For example, FIG. 10B shows that, at Time T₁, potential change from a low-level potential to a high-level potential occurs in the wiring CKL, the pixel data pix[1,1] is stored in each of the registers RG[1,p] to RG[3,p], and the pixel data pix[1,1] is input to each of the terminals SI of the operation circuits MA[1,1] to MA[3,1]. Furthermore, for example, FIG. 10B shows that, at Time T₂, potential change from a low-level potential to a high-level potential occurs in the wiring CKL, the pixel data pix[1,2] is stored in each of the registers RG[1,p] to RG[3,p], and the pixel data pix[1,2] is input to each of the terminals SI of the operation circuits MA[1,1] to MA[3,1]. Moreover, for example, FIG. 10B shows that, at Time T₃, potential change from a low-level potential to a high-level potential occurs in the wiring CKL, the pixel data pix[1,3] is stored in each of the registers RG[1,p] to RG[3,p], and the pixel data pix[1,3] is input to the terminals SI of the operation circuits MA[1,1] to MA[1,3].

Moreover, for example, FIG. 10B shows that, at Time T₄, potential change from a low-level potential to a high-level potential occurs in the wiring CKL, the pixel data pix[1,4] is stored in each of the registers RG[1,p] to RG[3,p], the pixel data pix[1,4] is input to each of the terminals SI of the operation circuits MA[1,1] to MA[3,1], the pixel data pix[2,1] is stored in each of the registers RG[4,p] to RG[6,p], and the pixel data pix[2,1] is input to the terminals SI of the operation circuits MA[4,1] to MA[6,1].

In addition, for example, FIG. 10B shows that, at Time T₇, potential change from a low-level potential to a high-level potential occurs in the wiring CKL, the pixel data pix[1,7] is stored in each of the registers RG[1,p] to RG[3,p], the pixel data pix[1,7] is input to each of the terminals SI of the operation circuits MA[1,1] to MA[3,1], the pixel data pix[2,4] is stored in the registers RG[4,p] to RG[6,p], the pixel data pix[2,4] is input to each of the terminal SI of the operation circuits MA[4,1] to MA[6,1], the pixel data pix[3,1] is stored in the register RG[7,p], and the pixel data pix[3,1] is input to the terminal SI of the operation circuit MA[7,1].

As described above, the pixel data pix[1,1] to pix[1,n] are sequentially input to the operation circuit MA[1,1] to the operation circuit MA[3,1] every time potential change of the clock signal from a low-level to a high-level potential occurs in the wiring CKL. After data is input to the operation circuits MA[1,1] to MA[3,1] and then potential change of the clock signal from a low-level to a high-level potential occurs in the wiring CKL three times, the pixel data pix[2,1] to pix[2,n] are sequentially input to the operation circuits MA[4,1] to MA[6,1]. After data is input to the operation circuits MA[4,1] to MA[6,1] and then potential change of the clock signal from a low-level to a high-level potential occurs in the wiring CKL three times, the pixel data pix[3,1] to pix[3,n] are sequentially input to the operation circuits MA[7,1] to MA[9,1].

Note that after the pixel data pix[1,n] is input to the operation circuits MA[1,1] to MA[3,1], for example, the pixel data pix[4,1] to pix[4,n] may be sequentially input to thereto. Similarly, after the pixel data pix[2,n] is input to the operation circuits MA[4,1] to MA[6,1], for example, the pixel data pix[5,1] to pix[5,n] may be sequentially input to thereto; after the pixel data pix[3,n] is input to the operation circuits MA[7,1] to MA[9,1], for example, the pixel data pix[6,1] to pix[6,n] may be sequentially input thereto. In this manner, after the pixel data pix for one row is input to the operation circuits MA[1,1] to MA[9,1], the pixel data pix for the next row is input, whereby operation processing can be performed sequentially.

Although described in detail later, in FIG. 10B, the pixel data pix surrounded by dotted lines (e.g., a pixel pix[1,1] stored in the registers RG[2,p] and RG[3,p] and input to each of the operation circuits MA[2,1] and MA[3,1] at Time T₁) is data that is not used for the operation in the CNN. Therefore, in the case where calculation is performed in the MAC array MAR, only data of the pixel pix surrounded by solid lines may be input to the MAC array MAR. However, in the case where an operation apparatus is actually constructed, as compared to the structure in which only the data of the pixel pix surrounded by solid lines is input to the MAC array MAR, a structure in which data of the pixel pix surrounded by dotted lines is transmitted as dummy data together with the pixel pix surrounded by black lines facilitates construction of the operation apparatus in some cases.

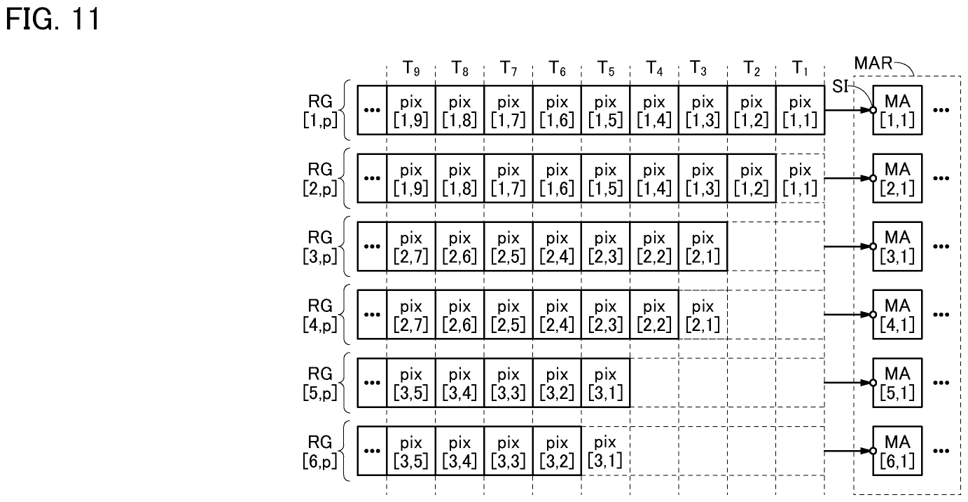

Note that the above method for inputting the pixel data pix to the MAC array MAR is applicable to only the case where the filter fil₁ to the filter fil₁₀ each have three rows and three columns. For this reason, in the case the filter fil₁ to the filter fil₁₀ each have a matrix other than a matrix of three rows and three rows, the method for inputting the pixel data pix to the MAC array MAR needs to be changed. For example, in the case where the filter read out to the operation circuit MA of the MAC array MAR has a rows and b columns (a is an integer of 1 or more and b is an integer of 1 or more), the MAC array MAR to which the pixel data pix is input from the register RG has a×b rows (that is, the number of rows of the operation circuits MA in the MAC array MAR is a×b). Input of the pixel data pix to the MAC array MAR is performed for every a rows with a difference of a clock signals. For example, in the case where the filter read out to the operation circuit MA in the MAC array MAR has two rows and three columns, pixel data input from the register RG to the MAC array MAR and the timing are as shown in FIG. 11.

Next, the case where the pixel data pix is input to the terminal SI of the operation circuit MA is considered with reference to FIG. 3. The pixel data pix input to the terminal SI of the operation circuit MA is input to the terminal IT1 of the register RG1 included in the operation circuit MA. For example, when the potential of a clock signal is changed from a low-level potential to a high-level potential, the register RG1 retains the pixel data pix input to the terminal IT1 and outputs the pixel data pix from the terminal OT1.

Since the register RG1 is electrically connected to the wiring CKL, the register RG1 can output the pixel data pix to the terminal OT1 in synchronization with the above-described register RG on the outside of the MAC array MAR. The pixel data pix output from the terminal OT1 is input to the terminal SO of the operation circuit MA, and the terminal SO of the operation circuit MA is electrically continuous with the terminal SI of the next operation circuit MA. Accordingly, the operation circuits MA included in one row of the MAC array MAR can be regarded as registers connected in series with the terminal SI serving as an input terminal and the terminal SO serving as an output terminal. Therefore, the operation circuits MA included in one row of the MAC array MAR can sequentially transmit pixel data pix in accordance with clock signals, like the register RG on the outside of the MAC array MAR. For example, the pixel data pix is transmitted to the registers RG[s,1] to RG[s,p] sequentially, and then sequentially transmitted to the operation circuits MA[s,1] to MA[s,v] (v=10 in this operation example) of the MAC array MAR.

In this operating method, a high-level potential is supplied to the terminal CT2 of the register RG2 all the times. That is, a high-level potential is supplied to the wiring SLT all the times.

The pixel data pix output from the terminal OT1 of the register RG1 is input to the terminal IT2 of the register RG2. Since the register RG2 is electrically connected to the wiring CKL, the register RG2 can output the pixel data pix to the terminal OT2 in synchronization with the above-described register RG on the outside of the MAC array MAR and the register RG1. Thus, the register RG2 retains the pixel data pix input to the terminal IT2 and outputs the pixel data pix to the terminal OT2. The pixel data pix output to the terminal OT2 is input to the terminal XI of the multiplier MP.

That is, when potential change from a low-level potential to a high-level potential occurs twice to the clock signal input to the wiring CKL, the pixel data pix input to the terminal IT T of the register RG1 is output to the terminal OT2 of the register RG2.

[Step 3: Sum of products of filter value and pixel data pix] The pixel data pix is input to the operation circuit MA in Step 2, and multiplication of the pixel data pix with the filter value read out from the memory unit OSM of the operation circuit MA is performed in the operation circuit MA.

### [Time T₁]

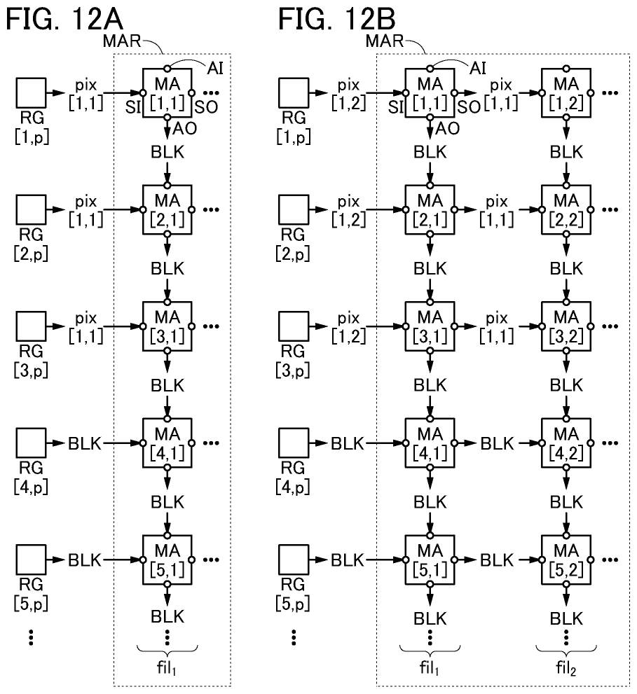

FIG. 12A is a block diagram illustrating data output to the terminals AO of some operation circuits MA of the MAC array MAR at Time T₁, as an example. Note that FIG. 12A illustrates only the register RG[1,p] to the register RG[5,p] and the operation circuit MA[1,1] to the operation circuit MA[5,1].

At Time T₁, the pixel data is input from each of the registers RG[1,p] to RG[9,p] to the MAC array MAR. Note that at Time T₁, the pixel data pix[1,1] is input to the operation circuits MA[1,1] to MA[3,1], and no pixel data is input to the operation circuits MA[4,1] to MA[9,1]. Therefore, in FIG. 12A, BLK is used for the operation circuits MA[4,1] to MA[9,1] to denote that no pixel data is input to thereto.

The pixel data pix[1,1] is input to each of the terminals ITT of the registers RG1 of the operation circuits MA[1,1] to MA[3,1].

At the stage of Time T₁, no operation result is performed in all the operation circuits MA in the MAC array MAR. Thus, in FIG. 12A, BLK is used for each of the terminals AO of the operation circuits MA[1,1] to MA[9,1] to denote that no operation result is output therefrom.

### [Time T₂]

FIG. 12B is a block diagram illustrating data output to the terminals AO and the terminals SI of some operation circuits MA of the MAC array MAR at Time T₂, as an example. Note that FIG. 12B illustrates only the register RG[1,p] to the register RG[5,p], the operation circuit MA[1,1] to the operation circuit MA[5,1], and the operation circuit MA[1,3] to the operation circuit MA[5,3].

At Time T₂, the pixel data pix[1,2] is output from the registers RG[1,p] to RG[3,p], and no pixel data is input from the operation circuits MA[4,1] to MA[9,1]. Since the operation circuit MA of the MAC array MAR also functions as a register as described above, the pixel data pix[1,1] is output from each of the terminals SO of the operation circuits MA[1,1] to MA[3,1] at Time T₂. Furthermore, no pixel data pix is output from each of the terminals SO of the operation circuits MA[4,1] to MA[9,1].

At this time, the pixel data pix[1,1] is input to each of the terminals IT2 of the registers RG2 of the operation circuits MA[1,1] to MA[3,1]. Furthermore, the pixel data pix[1,2] is input to each of the terminals ITT of the registers RGT of the operation circuits MA[1,1] to MA[3,1].

The pixel data pix[1,1] is input to each of the terminals ITT of the registers RG1 of the operation circuits MA[1,2] to MA[3,2].

At the stage of Time T₂, no operation result is performed in all the operation circuits MA in the MAC array MAR. Thus, in FIG. 12B, BLK is used for each of the terminals AO of the operation circuits MA[1,1] to MA[9,1] to denote that no operation result is output therefrom, in a manner similar to that in FIG. 12A.

### [Time T₃]

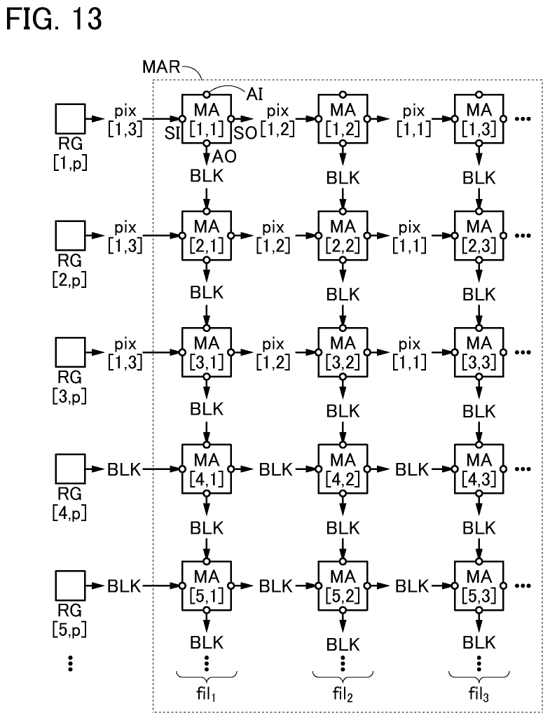

Next, an operation of the MAC array MAR at Time T₃ is considered. FIG. 13 is a block diagram illustrating data output to the terminals AO and the terminals SI of some operation circuits MA of the MAC array MAR at Time T₃, as an example. Note that FIG. 13 illustrates only the register RG[1,p] to the register RG[5,p], the operation circuit MA[1,1] to the operation circuit MA[5,1], the operation circuit MA[1,2] to the operation circuit MA[5,2], and the operation circuit MA[1,3] to the operation circuit MA[5,3].

At Time T₃, the pixel data pix[1,3] is input from the registers RG[1,p] to RG[3,p] to the operation circuits MA[1,1] to MA[3,1], and no pixel data is input to the operation circuits MA[4,1] to MA[9,1]. Since the operation circuit MA in the MAC array MAR also functions as a register as described above, the pixel data pix[1,2] is output from each of the terminals SO of the operation circuits MA[1,1] to MA[3,1] and the pixel data pix[1,1] is output from each of the terminals SO of the operation circuits MA[1,2] to MA[3,2] at Time T₃. Furthermore, no pixel data pix is output from each of the terminals SO of the operation circuits MA[4,1] to MA[9,1] and MA[4,2] to MA[9,2].

At this time, the pixel data pix[1,2] is input to each of the terminals IT2 of the registers RG2 of the operation circuits MA[1,1] to MA[3,1]. Furthermore, the pixel data pix[1,3] is input to each of the terminals IT1 of the registers RG1 of the operation circuits MA[1,1] to MA[3,1].

The pixel data pix[1,1] is input to each of the terminals IT2 of the registers RG2 of the operation circuits MA[1,2] to MA[3,2]. The pixel data pix[1,2] is input to each of the terminals IT1 of the registers RG1 of the operation circuits MA[1,2] to MA[3,2].

The pixel data pix[1,1] is input to each of the terminals IT1 of the registers RG1 of the operation circuits MA[1,3] to MA[3,3].

The pixel data pix[1,1] is output from each of the terminals OT2 of the registers RG2 of the operation circuits MA[1,1] to MA[3,1]. Since the terminal OT2 of the register RG2 is electrically connected to the terminal XI of the multiplier MP, the pixel data pix[1,1] is input to the terminal XI of the multiplier MP.

Here, an operation performed in the operation circuit MA[1,1] to the operation circuit MA[9,1] will be described.

In the operation circuit MA[1,1], fil₁[1,1] is input as a filter value to the terminal WI of the multiplier MP, and the pixel pix[1,1] is input to the terminal XI of the multiplier MP. Accordingly, fil₁[1,1]×pix[1,1] is output to the terminal ZO of the multiplier MP and input to the terminal FT of the adder AD. Furthermore, a value of “0” is input to the terminal ST of the adder AD. Thus, fil₁[1,1]×pix[1,1] is output to the terminal TT of the adder AD. Note that F₁^{[1,1]}[1]=fil₁[1,1]×pix[1,1] in this operating example. F₁^{[1,1]}[1] is input to the terminal IT3 of the register RG3 of the operation circuit MA[1,1].

In the operation circuit MA[2,1], fil₁[1,2] is input as a filter value to the terminal WI of the multiplier MP, and the pixel pix[1,1] is input to the terminal XI of the multiplier MP. Accordingly, fil₁[1,2]×pix[1,1] is output to the terminal ZO of the multiplier MP and input to the terminal FT of the adder AD. Furthermore, a value of “0” is input to the terminal ST of the adder AD, for example. Thus, fil₁[1,2]×pix[1,1] is output to the terminal TT of the adder AD. Note that this operation result is not used for the operation in the CNN and thus will be described as FD. This FD is input to the terminal IT3 of the register RG3 of the operation circuit MA[2,1].

In the operation circuit MA[3,1], fil₁[1,3] is input as a filter value to the terminal WI of the multiplier MP, and the pixel pix[1,1] is input to the terminal XI of the multiplier MP. Accordingly, fil₁[1,3]×pix[1,1] is output to the terminal ZO of the multiplier MP and input to the terminal FT of the adder AD. Furthermore, a value of “0” is input to the terminal ST of the adder AD, for example. Thus, fil₁[1,3]×pix[1,1] is output to the terminal TT of the adder AD. Note that this operation result is not used for the operation in the CNN and thus will be described as FD, in a manner similar to that in the above-described operation circuit MA[2,1]. This FD is input to the terminal IT3 of the register RG3 of the operation circuit MA[3,1].

Note that no operation is executed in the operation circuits MA[4,1] to MA[9,1] because no pixel data pix is input to the terminals XI of the multipliers MP of the operation circuits MA[4,1] to MA[9,1].

### [Time T₄]

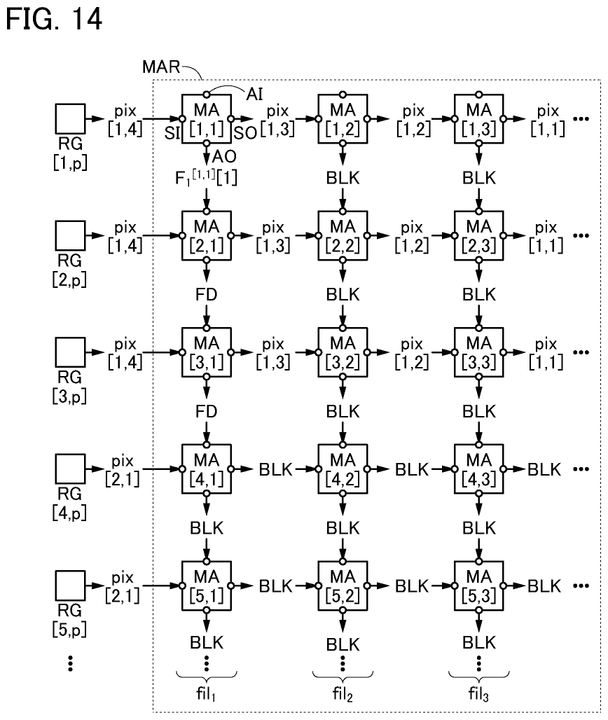

Next, an operation of the MAC array MAR at Time T₄ is considered. FIG. 14 is a block diagram illustrating data output to the terminals AO and the terminals SI of some operation circuits MA of the MAC array MAR at Time T₄, as an example. Note that FIG. 14 illustrates only the register RG[1,p] to the register RG[5,p], the operation circuit MA[1,1] to the operation circuit MA[5,1], the operation circuit MA[1,2] to the operation circuit MA[5,2], and the operation circuit MA[1,3] to the operation circuit MA[5,3].

In this operating method, a high-level potential is supplied to each of the terminals CT3 of the registers RG3 of the operation circuits MA[1,1] to MA[9,10] all the times. That is, a high-level potential is supplied to the wiring URST all the times.

In the operation circuit MA[1,1], when potential change of the clock signal from a low-level potential to a high-level potential occurs, the register RG3 outputs F₁^{[1,1]}[1] from the terminal OT3. Since the terminal OT3 of the register RG3 is electrically connected to the terminal AO of the operation circuit MA[1,1] and electrical continuity is established between the terminal AO of the operation circuit MA[1,1] and the terminal AI of the operation circuit MA[2,1], F₁^{[1,1]}[1] is input to the terminal AI of the operation circuit MA[2,1].

Similarly, in each of the operation circuits MA[2,1] and MA[3,1], when potential change of the clock signal from a low-level potential to a high-level potential occurs, the register RG3 outputs FD from the terminal OT3. Since the terminal OT3 of the register RG3 of the operation circuit MA[2,1] is electrically continuous with the terminal AI of the operation circuit MA[3,1] via the terminal AO of the operation circuit MA[2,1], the result FD of the operation performed in the operation circuit MA[2,1] is input to the terminal AI of the circuit MA[3,1]. Since the terminal OT3 of the register RG3 of the operation circuit MA[3,1] is electrically continuous with the terminal AI of the operation circuit MA[4,1] via the terminal AO of the operation circuit MA[3,1], the result FD of the operation performed in the operation circuit MA[3,1] is input to the terminal AI of the circuit MA[4,1].

At Time T₄, the pixel data pix[1,4] is input from the registers RG[1,p] to RG[3,p] to the operation circuits MA[1,1] to MA[3,1], the pixel data pix[2,1] is input from the registers RG[4,p] to RG[6,p] to the operation circuits MA[4,1] to MA[6,1], and no pixel data is input to the operation circuits MA[7,1] to MA[9,1]. Since the operation circuit MA in the MAC array MAR also functions as a register as described above, the pixel data pix[1,3] is output from each of the terminals SO of the operation circuits MA[1,1] to MA[3,1], the pixel data pix[1,2] is output from each of the terminals SO of the operation circuits MA[1,2] to MA[3,2], and the pixel data pix[1,1] is output from each of the terminals SO of the operation circuits MA[1,3] to MA[3,3] at Time T₄. Furthermore, no pixel data pix is output from each of the terminals SO of the operation circuits MA[4,1] to MA[9,1], MA[4,2] to MA[9,2], and MA[4,3] to MA[9,3].

At this time, the pixel data pix[1,3] is input to each of the terminals IT2 of the registers RG2 of the operation circuits MA[1,1] to MA[3,1]. Furthermore, the pixel data pix[1,4] is input to each of the terminals IT1 of the registers RGT of the operation circuits MA[1,1] to MA[3,1].

The pixel data pix[1,2] is input to each of the terminals IT2 of the registers RG2 of the operation circuits MA[1,2] to MA[3,2]. The pixel data pix[1,3] is input to each of the terminals ITT of the registers RGT of the operation circuits MA[1,2] to MA[3,2].

The pixel data pix[1,1] is input to each of the terminals IT2 of the registers RG2 of the operation circuits MA[1,3] to MA[3,3]. The pixel data pix[1,2] is input to each of the terminals ITT of the registers RGT of the operation circuits MA[1,3] to MA[3,3].

The pixel data pix[2,1] is input to each of the terminals ITT of the registers RG1 of the operation circuits MA[4,1] to MA[6,1].

The pixel data pix[1,2] is output from each of the terminals OT2 of the registers RG2 of the operation circuits MA[1,1] to MA[3,1]. Since the terminal OT2 of the register RG2 is electrically connected to the terminal XI of the multiplier MP, the pixel data pix[1,2] is input to the terminal XI of the multiplier MP.

The pixel data pix[1,1] is output from each of the terminals OT2 of the registers RG2 of the operation circuits MA[1,2] to MA[3,2]. Since the terminal OT2 of the register RG2 is electrically connected to the terminal XI of the multiplier MP, the pixel data pix[1,1] is input to the terminal XI of the multiplier MP.

Here, an operation performed in the operation circuit MA[1,1] to the operation circuit MA[9,1] and the operation circuit MA[1,2] to the operation circuit MA[9,2] will be described.

In the operation circuit MA[1,1], fil₁[1,1] is input as a filter value to the terminal WI of the multiplier MP, and a pixel pix[1,2] is input to the terminal XI of the multiplier MP. Accordingly, fil₁[1,1]×pix[1,2] is output to the terminal ZO of the multiplier MP and input to the terminal FT of the adder AD. Furthermore, a value of “0” is input to the terminal ST of the adder AD. Thus, fil₁[1,1]×pix[1,2] is output to the terminal TT of the adder AD. Note that F₁^{[1,2]}[1] =fil₁[1,1]×pix[1,2] in this operating example. F₁^{[1,2]}[1] is input to the terminal IT3 of the register RG3 of the operation circuit MA[1,1].

In the operation circuit MA[2,1], fil₁[1,2] is as a filter value input to the terminal WI of the multiplier MP, and the pixel pix[1,2] is input to the terminal XI of the multiplier MP. Accordingly, fil₁[1,2]×pix[1,2] is output to the terminal ZO of the multiplier MP and input to the terminal FT of the adder AD. Furthermore, a value of F₁^{[1,1]}[1] is input to the terminal ST of the adder AD. Thus, F₁^{[1,1]}[1]+fil₁[1,1]×pix[1,2] is output to the terminal TT of the adder AD. Note that F₁^{[1,1]}[2]=F₁^{[1,1]}[1]+fil₁[1,1]×pix[1,2] in this operating example. F₁^{[1,1]}[2] is input to the terminal IT3 of the register RG3 of the operation circuit MA[2,1].

In the operation circuit MA[3,1], fil₁[1,3] is input as a filter value to the terminal WI of the multiplier MP, and the pixel pix[1,1] is input to the terminal XI of the multiplier MP. Accordingly, fil₁[1,3]×pix[1,2] is output to the terminal ZO of the multiplier MP and then input to the terminal FT of the adder AD. Furthermore, FD output from the terminal AO of the operation circuit MA[2,1] is input to the terminal ST of the adder AD. Note that this operation result is not used for the operation in the CNN and thus will be described as FD. This FD is input to the terminal IT3 of the register RG3 of the operation circuit MA[3,1].

In the operation circuit MA[1,2], fil₂[1,1] is input as a filter value to the terminal WI of the multiplier NP, and the pixel pix[1,1] is input to the terminal XI of the multiplier MP. Accordingly, fil₂[1,1]×pix[1,1] is output to the terminal ZO of the multiplier MP and input to the terminal FT of the adder AD. Furthermore, a value of “0” is input to the terminal ST of the adder AD. Thus, fil₂[1,1]×pix[1,1] is output to the terminal TT of the adder AD. Note that F₂^{[1,1]}[1]=fil₂[1,1]×pix[1,1] in this operating example. F₂^{[1,1]}[1] is input to the terminal IT3 of the register RG3 of the operation circuit MA[1,2].

In the operation circuit MA[2,2], fil₂[1,2] is input as a filter value to the terminal WI of the multiplier NP, and the pixel pix[1,1] is input to the terminal XI of the multiplier MP. Accordingly, fil₂[1,2]×pix[1,1] is output to the terminal ZO of the multiplier MP and input to the terminal FT of the adder AD. Furthermore, a value of “0” is input to the terminal ST of the adder AD, for example. Thus, fil₂[1,2]×pix[1,1] is output to the terminal TT of the adder AD. Note that this operation result is not used for the operation in the CNN and thus will be described as FD. This FD is input to the terminal IT3 of the register RG3 of the operation circuit MA[2,2].

In the operation circuit MA[3,2], fil₂[1,3] is input as a filter value to the terminal WI of the multiplier MP, and the pixel pix[1,1] is input to the terminal XI of the multiplier MP. Accordingly, fil₂[1,3]×pix[1,1] is output to the terminal ZO of the multiplier MP and input to the terminal FT of the adder AD. Furthermore, a value of “0” is input to the terminal ST of the adder AD, for example. Thus, fil₂[1,3]×pix[1,1] is output to the terminal TT of the adder AD. Note that this operation result is not used for the operation of the CNN in a manner similar to that in the operation circuit MA[2,2] and thus will be described as FD. This FD is input to the terminal IT3 of the register RG3 of the operation circuit MA[3,2].

Note that no operation is executed in the operation circuits MA[4,1] to MA[9,1] and MA[4,2] to MA[9,2] because no pixel data pix is input to the terminals XI of the multipliers MP of the operation circuits MA[4,1] to MA[9,1] and MA[4,2] to MA[9,2].

### [Time T₅]

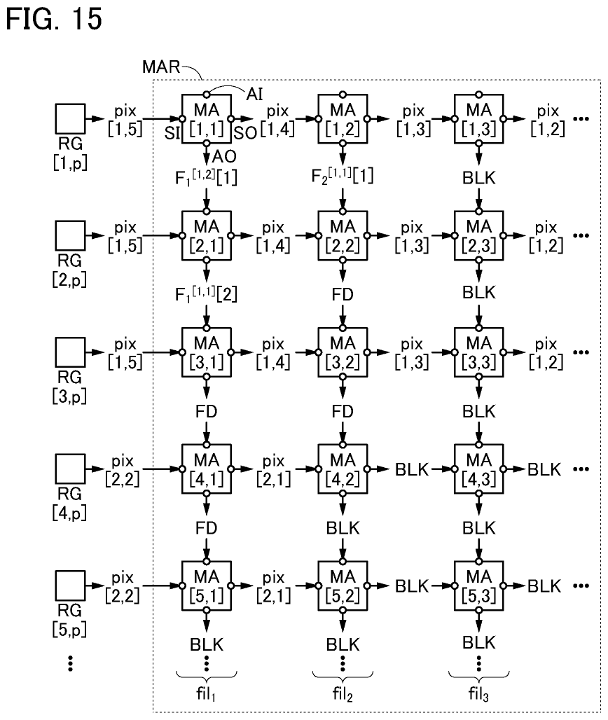

Next, an operation of the MAC array MAR at Time T₅ is considered. FIG. 15 is a block diagram illustrating data output to the terminals AO and the terminals SI of some operation circuits MA of the MAC array MAR at Time T₅, as an example. Note that FIG. 15 illustrates only the register RG[1,p] to the register RG[5,p], the operation circuit MA[1,1] to the operation circuit MA[5,1], the operation circuit MA[1,2] to the operation circuit MA[5,2], and the operation circuit MA[1,3] to the operation circuit MA[5,3].

In the operation circuit MA[1,1], when potential change of the clock signal from a low-level potential to a high-level potential occurs, the register RG3 outputs F₁^{[1,2]}[1] from the terminal OT3. Since the terminal OT3 of the register RG3 is electrically connected to the terminal AO of the operation circuit MA[1,1] and electrical continuity is established between the terminal AO of the operation circuit MA[1,1] and the terminal AI of the operation circuit MA[2,1], F₁^{[1,2]}[1] is input to the terminal AI of the operation circuit MA[2,1]. Similarly, in the operation circuit MA[2,1], when potential change of the clock signal from a low-level potential to a high-level potential occurs, the register RG3 outputs F₁^{[1,2]}[2] from the terminal OT3. Since the terminal OT3 of the register RG3 is electrically connected to the terminal AO of the operation circuit MA[2,1] and electrical continuity is established between the terminal AO of the operation circuit MA[2,1] and the terminal AI of the operation circuit MA[3,1], F₁^{[1,1]}[2] is input to the terminal AI of the operation circuit MA[3,1].

Similarly, in each of the operation circuit MA[3,1] and the operation circuit MA[4,1], when potential change of the clock signal from a low-level potential to a high-level potential occurs, the register RG3 outputs FD from the terminal OT3. Since the terminal OT3 of the register RG3 of the operation circuit MA[3,1] is electrically continuous with the terminal AI of the operation circuit MA[4,1] via the terminal AO of the operation circuit MA[3,1], the result FD of the operation performed in the operation circuit MA[3,1] is output to the terminal AI of the circuit MA[4,1]. Since the terminal OT3 of the register RG3 of the operation circuit MA[4,1] is electrically continuous with the terminal AI of the operation circuit MA[5,1] via the terminal AO of the operation circuit MA[4,1], the result FD of the operation performed in the operation circuit MA[4,1] is output to the terminal AI of the circuit MA[5,1].

In the operation circuit MA[1,2], when potential change of the clock signal from a low-level potential to a high-level potential occurs, the register RG3 outputs F₂^{[1,1]}[1] from the terminal OT3. Since the terminal OT3 of the register RG3 is electrically connected to the terminal AO of the operation circuit MA[1,2] and electrical continuity is established between the terminal AO of the operation circuit MA[1,2] and the terminal AI of the operation circuit MA[2,2], F₂^{[1,1]}[1] is input to the terminal AI of the operation circuit MA[2,2].

Similarly, in each of the operation circuit MA[2,2] and the operation circuit MA[3,2], when potential change of the clock signal from a low-level potential to a high-level potential occurs, the register RG3 outputs FD from the terminal OT3. Since the terminal OT3 of the register RG3 of the operation circuit MA[2,2] is electrically continuous with the terminal AI of the operation circuit MA[3,2] via the terminal AO of the operation circuit MA[2,2], the result FD of the operation performed in the operation circuit MA[2,2] is output to the terminal AI of the circuit MA[3,2]. Since the terminal OT3 of the register RG3 of the operation circuit MA[3,2] is electrically continuous with the terminal AI of the operation circuit MA[4,2] via the terminal AO of the operation circuit MA[3,2], the result FD of the operation performed in the operation circuit MA[3,2] is output to the terminal AI of the circuit MA[4,2].

At Time T₅, the pixel data pix[1,5] is input from the registers RG[1,p] to RG[3,p] to the operation circuits MA[1,1] to MA[3,1], the pixel data pix[2,2] is input from the registers RG[3,p] to RG[6,p] to the operation circuits MA[4,1] to MA[6,1], and no pixel data is input to the operation circuits MA[7,1] to MA[9,1]. Since the operation circuit MA in the MAC array MAR also functions as a register as described above, the pixel data pix[1,4] is output from each of the terminals SO of the operation circuits MA[1,1] to MA[3,1], the pixel data pix[1,3] is output from each of the terminals SO of the operation circuits MA[1,2] to MA[3,2], and the pixel data pix[1,2] is output from each of the terminals SO of the operation circuits MA[1,3] to MA[3,3] at Time T₅. Furthermore, the pixel data pix[2,1] is output from each of the terminals SO of the operation circuits MA[4,1] to MA[6,1]. Furthermore, no pixel data pix is output from each of the terminals SO of the operation circuits MA[7,1] to MA[9,1], MA[4,2] to MA[9,2], and MA[4,3] to MA[9,3].

At this time, the pixel data pix[1,4] is input to each of the terminals IT2 of the registers RG2 of the operation circuits MA[1,1] to MA[3,1]. Furthermore, the pixel data pix[1,5] is input to each of the terminals ITT of the registers RG1 of the operation circuits MA[1,1] to MA[3,1].

The pixel data pix[1,3] is input to each of the terminals IT2 of the registers RG2 of the operation circuits MA[1,2] to MA[3,2]. The pixel data pix[1,4] is input to each of the terminals ITT of the registers RG1 of the operation circuits MA[1,2] to MA[3,2].

The pixel data pix[1,2] is input to each of the terminals IT2 of the registers RG2 of the operation circuits MA[1,3] to MA[3,3]. The pixel data pix[1,3] is input to each of the terminals ITT of the registers RG1 of the operation circuits MA[1,3] to MA[3,3].

The pixel data pix[2,1] is input to each of the terminals IT2 of the registers RG2 of the operation circuits MA[4,1] to MA[6,1]. The pixel data pix[2,2] is input to each of the terminals ITT of the registers RG1 of the operation circuits MA[4,1] to MA[6,1].

The pixel data pix[2,1] is input to each of the terminals ITT of the registers RG1 of the operation circuits MA[4,2] to MA[6,2].

The pixel data pix[1,3] is output from each of the terminals OT2 of the registers RG2 of the operation circuits MA[1,1] to MA[3,1]. Since the terminal OT2 of the register RG2 is electrically connected to the terminal XI of the multiplier MP, the pixel data pix[1,3] is input to the terminal XI of the multiplier MP.

The pixel data pix[1,2] is output from each of the terminals OT2 of the registers RG2 of the operation circuits MA[1,2] to MA[3,2]. Since the terminal OT2 of the register RG2 is electrically connected to the terminal XI of the multiplier MP, the pixel data pix[1,2] is input to the terminal XI of the multiplier MP.

The pixel data pix[1,1] is output from each of the terminals OT2 of the registers RG2 of the operation circuits MA[1,3] to MA[3,3]. Since the terminal OT2 of the register RG2 is electrically connected to the terminal XI of the multiplier MP, the pixel data pix[1,1] is input to the terminal XI of the multiplier MP.

Here, an operation performed in the operation circuit MA[1,1] to the operation circuit MA[9,1], the operation circuit MA[1,2] to the operation circuit MA[9,2], and the operation circuit MA[1,3] to the operation circuit MA[9,3] will be described.

In the operation circuit MA[1,1], fil₁[1,1] is input as a filter value to the terminal WI of the multiplier MP, and a pixel pix[1,3] is input to the terminal XI of the multiplier MP. Accordingly, fil₁[1,1]×pix[1,3] is output to the terminal ZO of the multiplier MP and input to the terminal FT of the adder AD. Furthermore, a value of “0” is input to the terminal ST of the adder AD. Thus, fil₁[1,1]×pix[1,3] is output to the terminal TT of the adder AD. Note that F₁^{[1,3]}[1]=fil₁[1,1]×pix[1,3] in this operating example. F₁^{[1,3]}[1] is input to the terminal IT3 of the register RG3 of the operation circuit MA[1,1].

In the operation circuit MA[2,1], fil₁[1,2] is input as a filter value to the terminal WI of the multiplier MP, and the pixel pix[1,3] is input to the terminal XI of the multiplier MP. Accordingly, fil₁[1,2]×pix[1,3] is output to the terminal ZO of the multiplier MP and input to the terminal FT of the adder AD. Furthermore, a value of F₁^{[1,2]}[1] is input to the terminal ST of the adder AD. Thus, F₁^{[1,2]}[1]+fil₁[1,2]×pix[1,3] is output to the terminal TT of the adder AD. Note that F₁^{[1,2]}[2]=F₁^{[1,2]}[1]+fil₁[1,2]×pix[1,3] in this operating example. F₁^{[1,2]}[2] is input to the terminal IT3 of the register RG3 of the operation circuit MA[2,1].

In the operation circuit MA[3,1], fil₁[1,3] is input as a filter value to the terminal WI of the multiplier MP, and the pixel pix[1,3] is input to the terminal XI of the multiplier MP. Accordingly, fil₁[1,3]×pix[1,3] is output to the terminal ZO of the multiplier MP and input to the terminal FT of the adder AD. Furthermore, a value of F₁^{[1,1]}[2] is input to the terminal ST of the adder AD. Thus, F₁^{[1,1]}[2]+fil₁[1,3]×pix[1,3] is output to the terminal TT of the adder AD. Note that F₁^{[1,1]}[3]=F₁^{[1,1]}[2]+fil₁[1,3]×pix[1,3] in this operating example. F₁^{[1,1]}[3] is input to the terminal IT3 of the register RG3 of the operation circuit MA[3,1].

In the operation circuit MA[1,2], fil₂[1,1] is input as a filter value to the terminal WI of the multiplier MP, and the pixel pix[1,2] is input to the terminal XI of the multiplier MP. Accordingly, fil₂[1,1]×pix[1,2] is output to the terminal ZO of the multiplier MP and input to the terminal FT of the adder AD. Furthermore, a value of “0” is input to the terminal ST of the adder AD. Thus, fil₂[1,1]×pix[1,2] is output to the terminal TT of the adder AD. Note that F₁^{[1,2]}[1]=fil₂[1,1]×pix[1,2] in this operating example. F₂^{[1,2]}[1] is input to the terminal IT3 of the register RG3 of the operation circuit MA[1,2].

In the operation circuit MA[2,2], fil₂[1,2] is input as a filter value to the terminal WI of the multiplier MP, and the pixel pix[1,2] is input to the terminal XI of the multiplier MP. Accordingly, fil₂[1,2]×pix[1,2] is output to the terminal ZO of the multiplier MP and input to the terminal FT of the adder AD. Furthermore, a value of F₂^{[1,1]}[1] is input to the terminal ST of the adder AD. Thus, F₂^{[1,1]}[1]+fil₂[1,2]×pix[1,2] is output to the terminal TT of the adder AD. Note that F₂^{[1,1]}[2]=F₂^{[1,1]}[1]+fil₂[1,2]×pix[1,2] in this operating example. F₂^{[1,1]}[2] is input to the terminal IT3 of the register RG3 of the operation circuit MA[2,1].

In the operation circuit MA[3,2], fil₂[1,3] is input as a filter value to the terminal WI of the multiplier MP, and the pixel pix[1,2] is input to the terminal XI of the multiplier MP. Accordingly, fil₂[1,3]×pix[1,2] is output to the terminal ZO of the multiplier MP and input to the terminal FT of the adder AD. Furthermore, FD output from the terminal AO of the operation circuit MA[2,2] is input to the terminal ST of the adder AD. Note that this operation result is not used for the operation in the CNN and thus will be described as FD. This FD is input to the terminal IT3 of the register RG3 of the operation circuit MA[3,2].

In the operation circuit MA[1,3], fil₃[1,1] is input as a filter value to the terminal WI of the multiplier NP, and the pixel pix[1,1] is input to the terminal XI of the multiplier MP. Accordingly, fil₃[1,1]×pix[1,1] is output to the terminal ZO of the multiplier MP and input to the terminal FT of the adder AD. Furthermore, a value of “0” is input to the terminal ST of the adder AD. Thus, fil₃[1,1]×pix[1,1] is output to the terminal TT of the adder AD. Note that F₃^{[1,1]}[1]=fil₃[1,1]×pix[1,1] in this operating example. F₃^{[1,1]}[1] is input to the terminal IT3 of the register RG3 of the operation circuit MA[1,3].

In the operation circuit MA[2,3], fil₃[1,2] is as a filter value input to the terminal WI of the multiplier NP, and the pixel pix[1,1] is input to the terminal XI of the multiplier MP. Accordingly, fil₃[1,2]×pix[1,1] is output to the terminal ZO of the multiplier MP and input to the terminal FT of the adder AD. Furthermore, a value of “0” is input to the terminal ST of the adder AD, for example. Thus, fil₃[1,2]×pix[1,1] is output to the terminal TT of the adder AD. Note that this operation result is not used for the operation of the CNN and thus will be described as FD. This FD is input to the terminal IT3 of the register RG3 of the operation circuit MA[2,3].

In the operation circuit MA[3,3], fil₃[1,3] is as a filter value input to the terminal WI of the multiplier MP, and the pixel pix[1,1] is input to the terminal XI of the multiplier MP. Accordingly, fil₃[1,3]×pix[1,1] is output to the terminal ZO of the multiplier MP and input to the terminal FT of the adder AD. Furthermore, a value of “0” is input to the terminal ST of the adder AD, for example. Thus, fil₃[1,3]×pix[1,1] is output to the terminal TT of the adder AD. Note that this operation result is not used for the operation in the CNN and thus will be described as FD, in a manner similar to that in the above-described operation circuit MA[2,3]. This FD is input to the terminal IT3 of the register RG3 of the operation circuit MA[3,3].

Note that no operation is executed in the operation circuits MA[4,1] to MA[9,1], the operation circuits MA[4,2] to MA[9,2], and the operation circuits MA[4,3] to MA[9,3] because no pixel data pix is input to the terminals XI of the multipliers MP of the operation circuits MA[4,1] to MA[9,1], the operation circuits MA[4,2] to MA[9,2], and the operation circuits MA[4,3] to MA[9,3].

### [Time T₆]

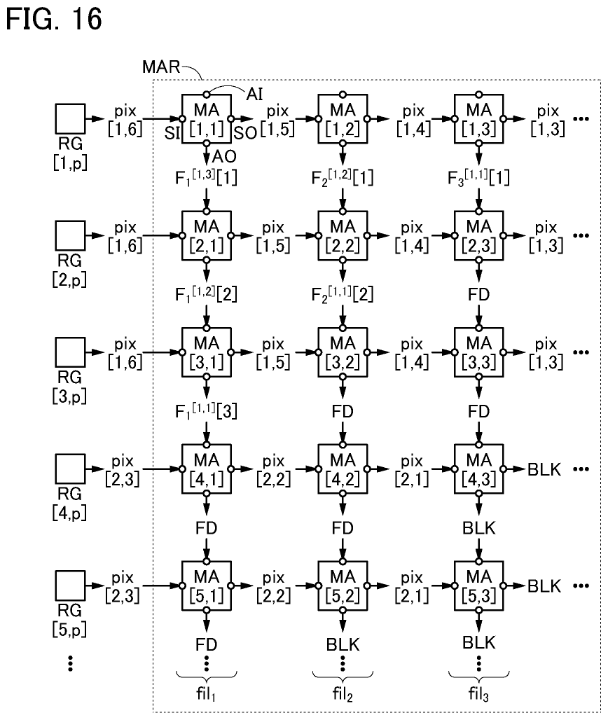

Next, an operation of the MAC array MAR at Time T₆ is considered. FIG. 16 is a block diagram illustrating data output to the terminals AO and the terminals SI of some operation circuits MA in the MAC array MAR at Time T₆, as an example. Note that FIG. 16 illustrates only the register RG[1,p] to the register RG[5,p], the operation circuit MA[1,1] to the operation circuit MA[5,1], the operation circuit MA[1,2] to the operation circuit MA[5,2], and the operation circuit MA[1,3] to the operation circuit MA[5,3].

In the operation circuit MA[1,1], when potential change of the clock signal from a low-level potential to a high-level potential occurs, the register RG3 outputs F₁^{[1,3]}[1] from the terminal OT3. Since the terminal OT3 of the register RG3 is electrically connected to the terminal AO of the operation circuit MA[1,1] and electrical continuity is established between the terminal AO of the operation circuit MA[1,1] and the terminal AI of the operation circuit MA[2,1], F₁^{[1,3]}[1] is input to the terminal AI of the operation circuit MA[2,1]. Similarly, in the operation circuit MA[2,1], when potential change of the clock signal from a low-level potential to a high-level potential occurs, the register RG3 outputs F₁^{[1,2]}[2] from the terminal OT3. Since the terminal OT3 of the register RG3 is electrically connected to the terminal AO of the operation circuit MA[2,1] and electrical continuity is established between the terminal AO of the operation circuit MA[2,1] and the terminal AI of the operation circuit MA[3,1], F₁^{[1,2]}[2] is input to the terminal AI of the operation circuit MA[3,1]. In the operation circuit MA[3,1], when potential change of the clock signal from a low-level potential to a high-level potential occurs, the register RG3 outputs F₁^{[1,1]}[3] from the terminal OT3. Since the terminal OT3 of the register RG3 is electrically connected to the terminal AO of the operation circuit MA[3,1] and electrical continuity is established between the terminal AO of the operation circuit MA[3,1] and the terminal AI of the operation circuit MA[4,1], F₁^{[1,1]}[3] is input to the terminal AI of the operation circuit MA[3,1].

Similarly, in each of the operation circuit MA[4,1] and the operation circuit MA[5,1], when potential change of the clock signal from a low-level potential to a high-level potential occurs, the register RG3 outputs FD from the terminal OT3. Since the terminal OT3 of the register RG3 of the operation circuit MA[4,1] is electrically continuous with the terminal AI of the operation circuit MA[5,1] via the terminal AO of the operation circuit MA[4,1], the result FD of the operation performed in the operation circuit MA[4,1] is output to the terminal AI of the circuit MA[5,1]. Since the terminal OT3 of the register RG3 of the operation circuit MA[5,1] is electrically continuous with the terminal AI of the operation circuit MA[6,1] via the terminal AO of the operation circuit MA[5,1], the result FD of the operation performed in the operation circuit MA[5,1] is output to the terminal AI of the circuit MA[6,1].

In the operation circuit MA[1,2], when potential change of the clock signal from a low-level potential to a high-level potential occurs, the register RG3 outputs F₂^{[1,2]}[1] from the terminal OT3. Since the terminal OT3 of the register RG3 is electrically connected to the terminal AO of the operation circuit MA[1,2] and electrical continuity is established between the terminal AO of the operation circuit MA[1,2] and the terminal AI of the operation circuit MA[2,2], F₂^{[1,2]}[1] is input to the terminal AI of the operation circuit MA[2,2]. Similarly, in the operation circuit MA[2,2], when potential change of the clock signal from a low-level potential to a high-level potential occurs, the register RG3 outputs F₂^{[1,1]}[2] from the terminal OT3. Since the terminal OT3 of the register RG3 is electrically connected to the terminal AO of the operation circuit MA[2,2] and electrical continuity is established between the terminal AO of the operation circuit MA[2,2] and the terminal AI of the operation circuit MA[3,2], F₂^{[1,1]}[2] is input to the terminal AI of the operation circuit MA[3,2].

Similarly, in each of the operation circuit MA[3,2] and the operation circuit MA[4,2], when potential change of the clock signal from a low-level potential to a high-level potential occurs, the register RG3 outputs FD from the terminal OT3. Since the terminal OT3 of the register RG3 of the operation circuit MA[3,2] is electrically continuous with the terminal AI of the operation circuit MA[4,2] via the terminal AO of the operation circuit MA[3,2], the result FD of the operation performed in the operation circuit MA[3,2] is output to the terminal AI of the circuit MA[4,2]. Since the terminal OT3 of the register RG3 of the operation circuit MA[4,2] is electrically continuous with the terminal AI of the operation circuit MA[5,2] via the terminal AO of the operation circuit MA[4,2], the result FD of the operation performed in the operation circuit MA[4,2] is output to the terminal AI of the circuit MA[5,2].

In the operation circuit MA[1,3], when potential change of the clock signal from a low-level potential to a high-level potential occurs, the register RG3 outputs F₃^{[1,1]}[1] from the terminal OT3. Since the terminal OT3 of the register RG3 is electrically connected to the terminal AO of the operation circuit MA[1,3] and electrical continuity is established between the terminal AO of the operation circuit MA[1,3] and the terminal AI of the operation circuit MA[2,3], F₃^{[1,1]}[1] is input to the terminal AI of the operation circuit MA[2,3].

Similarly, in each of the operation circuit MA[2,3] and the operation circuit MA[3,3], when potential change of the clock signal from a low-level potential to a high-level potential occurs, the register RG3 outputs FD from the terminal OT3. Since the terminal OT3 of the register RG3 of the operation circuit MA[2,3] is electrically continuous with the terminal AI of the operation circuit MA[3,3] via the terminal AO of the operation circuit MA[2,3], the result FD of the operation performed in the operation circuit MA[2,3] is output to the terminal AI of the circuit MA[3,3]. Since the terminal OT3 of the register RG3 of the operation circuit MA[3,3] is electrically continuous with the terminal AI of the operation circuit MA[4,3] via the terminal AO of the operation circuit MA[3,3], the result FD of the operation performed in the operation circuit MA[3,3] is output to the terminal AI of the circuit MA[4,3].

At Time T₆, the pixel data pix[1,6] is input from the registers RG[1,p] to RG[3,p] to the operation circuits MA[1,1] to MA[3,1], the pixel data pix[2,3] is input from the registers RG[4,p] to RG[6,p] to the operation circuits MA[4,1] to MA[6,1], and no pixel data is input to the operation circuits MA[7,1] to MA[9,1]. Since the operation circuit MA in the MAC array MAR also functions as a register as described above, the pixel data pix[1,5] is output from each of the terminals SO of the operation circuits MA[1,1] to MA[3,1], the pixel data pix[1,4] is output from each of the terminals SO of the operation circuits MA[1,2] to MA[3,2], and the pixel data pix[1,3] is output from each of the terminals SO of the operation circuits MA[1,3] to MA[3,3] at Time T₆. Furthermore, the pixel data pix[2,2] is output from each of the terminals SO of the operation circuits MA[4,1] to MA[6,1], and the pixel data pix[2,1] is output from each of the terminals SO of the operation circuits MA[4,2] to MA[6,2]. Furthermore, no pixel data pix is output from each of the terminals SO of the operation circuits MA[7,1] to MA[9,1], MA[4,2] to MA[9,2], and MA[4,3] to MA[9,3].

At this time, the pixel data pix[1,5] is input to each of the terminals IT2 of the registers RG2 of the operation circuits MA[1,1] to MA[3,1]. Furthermore, the pixel data pix[1,6] is input to each of the terminals IT1 of the registers RG1 of the operation circuits MA[1,1] to MA[3,1].

The pixel data pix[1,4] is input to each of the terminals IT2 of the registers RG2 of the operation circuits MA[1,2] to MA[3,2]. The pixel data pix[1,5] is input to each of the terminals IT1 of the registers RG1 of the operation circuits MA[1,2] to MA[3,2].

The pixel data pix[1,3] is input to each of the terminals IT2 of the registers RG2 of the operation circuits MA[1,3] to MA[3,3]. The pixel data pix[1,4] is input to each of the terminals IT1 of the registers RG1 of the operation circuits MA[1,3] to MA[3,3].

The pixel data pix[2,2] is input to each of the terminals IT2 of the registers RG2 of the operation circuits MA[4,1] to MA[6,1]. The pixel data pix[2,3] is input to each of the terminals IT1 of the registers RG1 of the operation circuits MA[4,1] to MA[6,1].

The pixel data pix[2,1] is input to each of the terminals IT2 of the registers RG2 of the operation circuits MA[4,2] to MA[6,2]. The pixel data pix[2,2] is input to each of the terminals IT1 of the registers RG1 of the operation circuits MA[4,2] to MA[6,2].

The pixel data pix[2,1] is input to each of the terminals IT1 of the registers RG1 of the operation circuits MA[4,3] to MA[6,3].

The pixel data pix[1,4] is output from each of the terminals OT2 of the registers RG2 of the operation circuits MA[1,1] to MA[3,1]. Since the terminal OT2 of the register RG2 is electrically connected to the terminal XI of the multiplier MP, the pixel data pix[1,4] is input to the terminal XI of the multiplier MP.

The pixel data pix[1,3] is output from each of the terminals OT2 of the registers RG2 of the operation circuits MA[1,2] to MA[3,2]. Since the terminal OT2 of the register RG2 is electrically connected to the terminal XI of the multiplier MP, the pixel data pix[1,3] is input to the terminal XI of the multiplier MP.

The pixel data pix[1,2] is output from each of the terminals OT2 of the registers RG2 of the operation circuits MA[1,3] to MA[3,3]. Since the terminal OT2 of the register RG2 is electrically connected to the terminal XI of the multiplier MP, the pixel data pix[1,2] is input to the terminal XI of the multiplier MP.

The pixel data pix[2,1] is output from each of the terminals OT2 of the registers RG2 of the operation circuits MA[4,1] to MA[6,1]. Since the terminal OT2 of the register RG2 is electrically connected to the terminal XI of the multiplier MP, the pixel data pix[2,1] is input to the terminal XI of the multiplier MP.

Here, an operation performed in the operation circuit MA[1,1] to the operation circuit MA[9,1], the operation circuit MA[1,2] to the operation circuit MA[9,2], and the operation circuit MA[1,3] to the operation circuit MA[9,3] will be described.

In the operation circuit MA[1,1], fil₁[1,1] is input as a filter value to the terminal WI of the multiplier MP, and a pixel pix[1,4] is input to the terminal XI of the multiplier MP. Accordingly, fil₁[1,1]×pix[1,4] is output to the terminal ZO of the multiplier MP and input to the terminal FT of the adder AD. Furthermore, a value of “0” is input to the terminal ST of the adder AD. Thus, fil₁[1,1]×pix[1,4] is output to the terminal TT of the adder AD. Note that F₁^{[1,4]}[1]=fil₁[1,1]×pix[1,4] in this operating example. F₁^{[1,4]}[1] is input to the terminal IT3 of the register RG3 of the operation circuit MA[1,1].

In the operation circuit MA[2,1], fil₁[1,2] is input as a filter value to the terminal WI of the multiplier MP, and the pixel pix[1,4] is input to the terminal XI of the multiplier MP. Accordingly, fil₁[1,2]×pix[1,4] is output to the terminal ZO of the multiplier MP and input to the terminal FT of the adder AD. Furthermore, a value of F₁^{[1,3]}[1] is input to the terminal ST of the adder AD. Thus, F₁^{[1,3]}[1]+fil₁[1,2]×pix[1,4] is output to the terminal TT of the adder AD. Note that F₁^{[1,3]}[2]=F₁^{[1,3]}[1]+fil₁[1,2]×pix[1,4] in this operating example. F₁^{[1,3]}[2] is input to the terminal IT3 of the register RG3 of the operation circuit MA[2,1].

In the operation circuit MA[3,1], fil₁[1,3] is input as a filter value to the terminal WI of the multiplier MP, and the pixel pix[1,4] is input to the terminal XI of the multiplier MP. Accordingly, fil₁[1,3]×pix[1,4] is output to the terminal ZO of the multiplier MP and input to the terminal FT of the adder AD. Furthermore, a value of F₁^{[1,2]}[2] is input to the terminal ST of the adder AD. Thus, F₁^{[1,2]}[2]+fil₁[1,3]×pix[1,4] is output to the terminal TT of the adder AD. Note that F₁^{[1,2]}[3]=F₁^{[1,2]}[2]+fil₁[1,3]×pix[1,4] in this operating example. F₁^{[1,2]}[3] is input to the terminal IT3 of the register RG3 of the operation circuit MA[3,1].

In the operation circuit MA[4,1], fil₁[2,1] is input as a filter value to the terminal WI of the multiplier NP, and a pixel pix[2,1] is input to the terminal XI of the multiplier MP. Accordingly, fil₁[2,1]×pix[2,1] is output to the terminal ZO of the multiplier MP and input to the terminal FT of the adder AD. Furthermore, a value of F₁^{[1,1]}[3] is input to the terminal ST of the adder AD. Thus, F₁^{[1,1]}[3]+fil₁[2,1]×pix[2,1] is output to the terminal TT of the adder AD. Note that F₁^{[1,1]}[4]=F₁^{[1,1]}[3]+fil₁[2,1]×pix[2,1] in this operating example. F₁^{[1,1]}[4] is input to the terminal IT3 of the register RG3 of the operation circuit MA[4,1].

In the operation circuit MA[5,1], fil₁[2,2] is input as a filter value to the terminal WI of the multiplier NP, and the pixel pix[2,1] is input to the terminal XI of the multiplier MP. Accordingly, fil₁[2,2]×pix[2,1] is output to the terminal ZO of the multiplier MP and input to the terminal FT of the adder AD. Furthermore, FD output from the terminal AO of the operation circuit MA[4,1] is input to the terminal ST of the adder AD. Note that this operation result is not used for the operation in the CNN and thus will be described as FD. This FD is input to the terminal IT3 of the register RG3 of the operation circuit MA[5,1].

In the operation circuit MA[1,2], fil₂[1,1] is input as a filter value to the terminal WI of the multiplier NP, and the pixel pix[1,3] is input to the terminal XI of the multiplier MP. Accordingly, fil₂[1,1]×pix[1,3] is output to the terminal ZO of the multiplier MP and input to the terminal FT of the adder AD. Furthermore, a value of “0” is input to the terminal ST of the adder AD. Thus, fil₂[1,1]×pix[1,3] is output to the terminal TT of the adder AD. Note that F₂^{[1,3]}[1]=fil₂[1,1]×pix[1,3] in this operating example. F₂^{[1,3]}[1] is input to the terminal IT3 of the register RG3 of the operation circuit MA[1,1].

In the operation circuit MA[2,2], fil₂[1,2] is input as a filter value to the terminal WI of the multiplier MP, and the pixel pix[1,3] is input to the terminal XI of the multiplier MP. Accordingly, fil₂[1,2]×pix[1,3] is output to the terminal ZO of the multiplier MP and input to the terminal FT of the adder AD. Furthermore, a value of F₂^{[1,2]}[1] is input to the terminal ST of the adder AD. Thus, F₂^{[1,2]}[1]+fil₂[1,2]×pix[1,3] is output to the terminal TT of the adder AD. Note that F₂^{[1,2]}[2]=F₂^{[1,2]}[1]+fil₂[1,2]×pix[1,3] in this operating example. F₂^{[1,2]}[2] is input to the terminal IT3 of the register RG3 of the operation circuit MA[2,2].

In the operation circuit MA[3,2], fil₁[1,3] is input as a filter value to the terminal WI of the multiplier MP, and the pixel pix[1,3] is input to the terminal XI of the multiplier MP. Accordingly, fil₂[1,3]×pix[1,3] is output to the terminal ZO of the multiplier MP and input to the terminal FT of the adder AD. Furthermore, a value of F₂^{[1,1]}[2] is input to the terminal ST of the adder AD. Thus, F₂^{[1,1]}[2]+fil₂[1,3]×pix[1,3] is output to the terminal TT of the adder AD. Note that F₂^{[1,1]}[3]=F₂^{[1,1]}[2]+fil₂[1,3]×pix[1,3] in this operating example. F₂^{[1,1]}[3] is input to the terminal IT3 of the register RG3 of the operation circuit MA[3,2].

In the operation circuit MA[1,3], fil₃[1,1] is input as a filter value to the terminal WI of the multiplier MP, and the pixel pix[1,2] is input to the terminal XI of the multiplier MP. Accordingly, fil₃[1,1]×pix[1,2] is output to the terminal ZO of the multiplier MP and input to the terminal FT of the adder AD. Furthermore, a value of “0” is input to the terminal ST of the adder AD, for example. Thus, fil₃[1,1]×pix[1,2] is output to the terminal TT of the adder AD. Note that F₃^{[1,2]}[1]=fil₃[1,1]×pix[1,2] in this operating example. F₃^{[1,2]}[1] is input to the terminal IT3 of the register RG3 of the operation circuit MA[1,3].

In the operation circuit MA[2,3], fil₃[1,2] is input as a filter value to the terminal WI of the multiplier MP, and the pixel pix[1,2] is input to the terminal XI of the multiplier MP. Accordingly, fil₃[1,2]×pix[1,2] is output to the terminal ZO of the multiplier MP and input to the terminal FT of the adder AD. Furthermore, a value of F₃^{[1,1]}[1] is input to the terminal ST of the adder AD. Thus, F₃^{[1,1]}[1]+fil₃[1,2]×pix[1,2] is output to the terminal TT of the adder AD. Note that F₃^{[1,1]}[2]=F₃^{[1,1]}[1]+fil₃[1,2]×pix[1,2] in this operating example. F₃^{[1,1]}[2] is input to the terminal IT3 of the register RG3 of the operation circuit MA[2,3].

In the operation circuit MA[3,3], fil₃[1,3] is input as a filter value to the terminal WI of the multiplier MP, and the pixel pix[1,2] is input to the terminal XI of the multiplier MP. Accordingly, fil₂[1,3]×pix[1,2] is output to the terminal ZO of the multiplier MP and input to the terminal FT of the adder AD. Furthermore, FD output from the terminal AO of the operation circuit MA[2,3] is input to the terminal ST of the adder AD. Note that this operation result is not used for the operation in the CNN and thus will be described as FD. This FD is input to the terminal IT3 of the register RG3 of the operation circuit MA[3,3].

Note that no operation is executed in the operation circuits MA[6,1] to MA[9,1], the operation circuits MA[4,2] to MA[9,2], and the operation circuits MA[4,3] to MA[9,3] because no pixel data pix is input to the terminals XI of the multipliers MP of the operation circuits MA[6,1] to MA[9,1], the operation circuits MA[4,2] to MA[9,2], and the operation circuits MA[4,3] to MA[9,3].

The above operations are continued until a certain time (e.g., Time T₁₁ here), F₁^{[1,1]}[9] is output from the terminal AO of the operation circuit MA[9,1]. According to the above operations, F₁^{[1,1]}[9]=fil₁[1,1]×pix[1,1]+fil₁[1,2]×pix[1,2]+fil₁[1,3]×pix[1,3]+fil₁[2,1]×pix[2,1]+fil₁[2,2]×pix[2,2]+fil₁[2,3]×pix[2,3]+fil₁[3,1]×pix[3,1]+fil₁[3,2]×pix[3,2]+fil₁[3,3]×pix[3,3].

That is, F₁^{[1,1]}[9] is a value obtained by performing convolution on the regions of the pixel data pix[1,1] to pix[1,3], the pixel data pix[2,1] to pix[2,3], and the pixel data pix[3,1] to pix[3,3] in the image data IPD with the filter fil₁.

From Time T₁₁ to a time (e.g., Time T₁₂ here) when potential change from a low-level potential to a high-level potential occurs once to the clock signal of the wiring CKL, F₁^{[1,2]}[9] is output from the terminal AO of the operation circuit MA[9,1]. According to the above operations, F₁^{[1,2]}[9]=fil₁[1,1]×pix[1,2]+fil₁[1,2]×pix[1,3]+fil₁[1,3]×pix[1,4]+fil₁[2,1]×pix[2,2]+fil₁[2,2]×pix[2,3]+fil₁[2,3]×pix[2,4]+fil₁[3,1]×pix[3,2]+fil₁[3,2]×pix[3,3]+fil₁[3,3]×pix[3,4].

That is, F₁^{[1,2]}[9] is a value obtained by performing convolution on the regions of the pixel data pix[1,2] to pix[1,4], the pixel data pix[2,2] to pix[2,4], and the pixel data pix[3,2] to pix[3,4] in the image data IPD with the filter fil₁.

At Time T₁₂, F₂^{[1,1]}[9] is output from the terminal AO of the operation circuit MA[9,2]. According to the above operations, F₂^{[1,1]}[9]=fil₂[1,1]×pix[1,1]+fil₂[1,2]×pix[1,2]+fil₂[1,3]×pix[1,3]+fil₂[2,1]×pix[2,1]+fil₂[2,2]×pix[2,2]+fil₂[2,3]×pix[2,3]+fil₂[3,1]×pix[3,1]+fil₂[3,2]×pix[3,2]+fil₂[3,3]×pix[3,3].

That is, F₂^{[1,1]}[9] is a value obtained by performing convolution on the regions of the pixel data pix[1,1] to pix[1,3], the pixel data pix[2,1] to pix[2,3], and the pixel data pix[3,1] to pix[3,3] in the image data IPD with the filter fil₂.

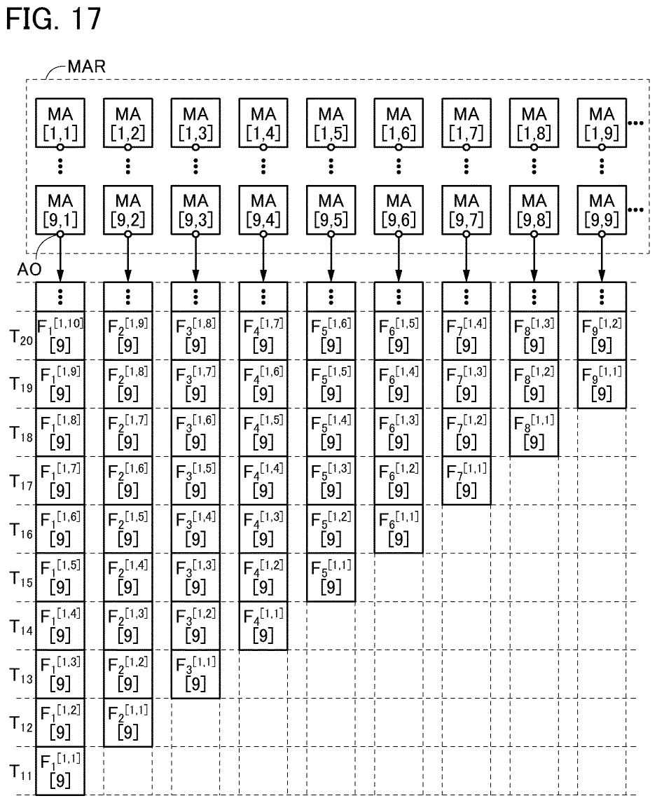

In this manner, the image data IPD is input to the MAC array MAR, whereby the results of the convolution operations performed with the filter fil₁ to the filter fil₁₀ are sequentially output from the operation circuits MA[9,1] to MA[9,10], respectively. The results obtained by the convolution operations can be as shown in FIG. 17, for example. Note that only the operation circuit MA[1,1] to the operation circuit MA[1,9], the operation circuit MA[9,1] to the operation circuit MA[9,9] are illustrated in the MAC array MAR in FIG. 17. Time T₁₂ to Time T₂₀ are times when potential change of the clock signal of the wiring CKL from a low-level potential to a high-level potential occurs once to nine times at Time T₁n, respectively.

For example, at Time T₁₈, when potential change of the clock signal of the wiring CKL from a low-level potential to a high-level potential occurs, F₁^{[1,8]}[9], F₂^{[1,7]}[9], F₃^{[1,6]}[9], F₄^{[1,5]}[9], F₅^{[1,4]}[9], F₆^{[1,3]}[9], F₇^{[1,2]}[9], and F₈^{[1,1]}[9] are output from the operation circuits MA[9,1] to MA[9,8], respectively, as the results of the convolution operations performed with the filters fil₁ to fil₈. Note that no operation result is output from the operation circuit MA[9,9] and the operation circuit MA[9,10] because the convolution operation is not completed in the ninth column and the tenth column of the MAC array MAR.

Processing with an activation function, a pooling layer, or the like may be performed on the convolution operation results output from the operation circuits MA[9,1] to MA[9,10], by the circuits AF[1] to AF[10]. Here, as an example, an operation with an activation function is performed on each of Fₜ^{[1,1]}[9] to Fₜ^{[m-2,n-2]}[9] obtained by convolution on all the pixel data pix[1,1] to pix[m,n] of the image data IPD with the filter filₜ, whereby F_{At}^{[1,1]} to F_{A}^{[m-2,n-2]} are obtained.

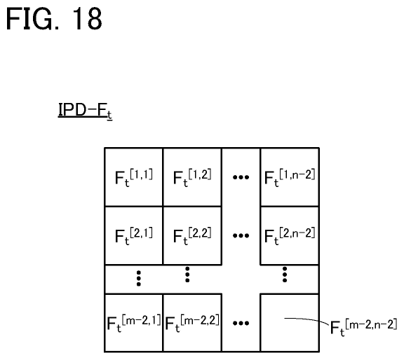

Here, F_{At}^{[1,1]} to F_{At}^{[m-2,n-2]} arranged in a matrix of m−2 rows and n−2 columns are referred to as image data IPD-Fₜ. The image data IPD-Fₜ can be image data of extracted feature portions (also referred to as a feature map in some cases) having a dependence on the filter filₜ, which is obtained by performing convolution processing on the image data IPD with the filter filₜ and performing an operation on the convolution processing results with an activation function, for example. Note that the image data IPD-Fₜ can be represented as illustrated in FIG. 18, for example.

### <<Operation 2 in Convolutional Layer CL>>

Next, an operation method in the convolutional layer CL and the pooling layer PL with the use of the operation apparatus 100, which is different from the above-described method, will be described. Note that the operations circuit MA included in the MAC array MAR of the operation apparatus 100 are arranged in a matrix of nine rows and ten columns as an example, in a manner similar to that in the above-described operation method.

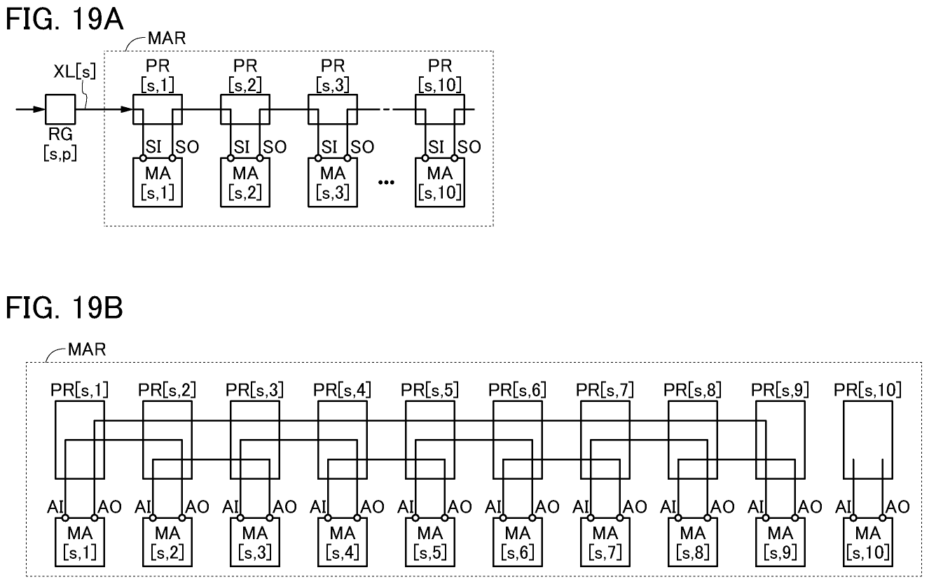

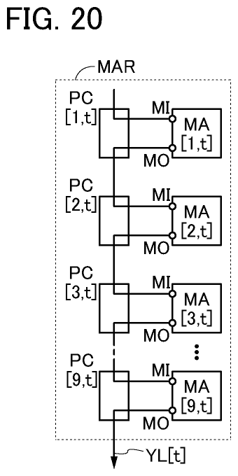

Furthermore, the MAC array MAR in this operating method has a circuit structure with the programmable switches PR and the programmable switches PC, as illustrated in FIG. 19A, FIG. 19B, and FIG. 20. Specifically, as illustrated in FIG. 19A, in the operation circuits MA included in the s-th row (here, s is an integer greater than or equal to 1 and less than or equal to 9) of the MAC array MAR, the programmable switches PR are set in a manner such that the terminal SO of the operation circuit MA is electrically continuous with the terminal SI of the next operation circuit MA. For example, the programmable switch PR[s,1] and the programmable switch PR[s,2] are set in a manner such that the terminal SO of the operation circuit MA[s,1] is electrically continuous with the terminal SI of the operation circuit MA[s,2] and the programmable switch PR[s,2] and the programmable switch PR[s,3] are set in a manner such that the terminal SO of the operation circuit MA[s,2] is electrically continuous with the terminal SI of the operation circuit MA[s,3]. Note that the wiring XL[s] is electrically continuous with the terminal SI of the operation circuit MA[s,1] via the programmable switch PR[s,1]. As described above, in the above operating method, the programmable switches PR are set in a manner such that the operation circuits MA in each row of the MAC array MAR are electrically connected in series.

In the MAC array MAR in this operating method, specifically, as illustrated in FIG. 19B, in the operation circuits MA[s,1] to MA[s,9] included in one column of the MAC array MAR, the programmable switches PC are set in a manner such that the terminal AO of the operation circuit MA is electrically continuous with the terminal AI of another operation circuit MA and data output from the terminal AO of a certain operation circuit MA is input to the terminal AI of the original operation circuit MA via different operation circuits MA. For example, the programmable switch PR[s,9] and the programmable switch PR[s,8] are set in such a manner that the terminal AO of the operation circuit MA[s,9] is electrically continuous with the terminal AI of the operation circuit MA[s,8]. Furthermore, for example, the programmable switch PR[s,8] and the programmable switch PR[s,7] are set in such a manner that the terminal AO of the operation circuit MA[s,8] is electrically continuous with the terminal AI of the operation circuit MA[s,7]. Moreover, the programmable switch PR[s,1] and the programmable switch PR[s,9] are set in such a manner that the terminal AO of the operation circuit MA[s,1] is electrically continuous with the terminal AI of the operation circuit MA[s,9]. In other words, in this operating method, the programmable switch PR[s,1] to the programmable switch PR[s,9] are set in a manner such that, in the operation circuits MA in each row of the MAC array MAR, data output from the operation circuit MA circulates in the other operation circuits MA in the same row. Note that in this operating method, the operation circuit MA[s,10] is not used; therefore, the operation circuit MA[s,10] is not electrically continuous with the other operation circuits MA by the programmable switch PR[s,10].

Furthermore, in the MAC array MAR in this operating method, specifically, as illustrated in FIG. 20, in the operation circuits MA included in the t-th column (here, t is an integer greater than or equal to 1 and less than or equal to 10) of the MAC array MAR, the programmable switches PC are set in a manner such that the terminal MO of the operation circuit MA is electrically continuous with the terminal MI of the next operation circuit MA. For example, the programmable switch PC[1,t] and the programmable switch PC[2,t] are set in such a manner that the terminal MO of the operation circuit MA[1,t] is electrically continuous with the terminal MI of the operation circuit MA[2,t]. Furthermore, for example, the programmable switch PC[2,t] and the programmable switch PC[3,t] are set in such a manner that the terminal MO of the operation circuit MA[2,t] is electrically continuous with the terminal MI of the operation circuit MA[3,t]. Note that the wiring YL[t] is electrically continuous with the terminal MO of the operation circuit MA[9,t] via the programmable switch PC[9,t]. As described above, in this operating method, the programmable switches PC are set in a manner such that the operation circuits MA in each column of the MAC array MAR are electrically connected in series.

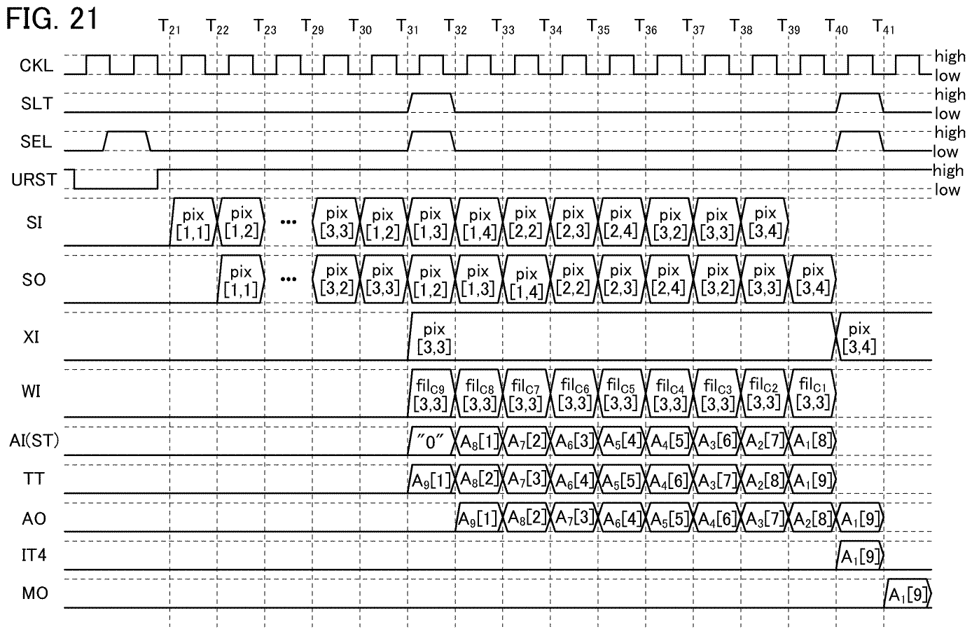

FIG. 21 is a timing chart showing change in data input to the terminal SI, the terminal SO, the terminal AI (the terminal ST of the adder), the terminal AO, the terminal MO, the terminals XI and WI of the multiplier MP, the terminal TT of the adder, and the terminal IT4 of the register RG4 that are included in the operation circuit MA[1,1] in a period from Time T₂₁ to Time T₄₁ and at times around the period. FIG. 21 also shows change in the potentials of the wiring CKL, the wiring SLT, the wiring SEL, and the wiring URST. Note that “high” denotes a high-level potential and “low” denotes a low-level potential in FIG. 21.

A method for performing an operation in the MAC array MAR is described below using the timing chart of FIG. 21. Note that the operation method is performed in the operation circuit MA[1,1] to the operation circuit MA[1,9] otherwise specified.

### [Step 0: Initialization]

First, an initialization operation is performed in the operation apparatus 100. Specifically, before Time T₂₁, it is preferable that data for initialization be input to the terminal SI, the terminal SO, the terminal XT, the terminal WT, the terminal AI (the terminal ST), the terminal TT, and the terminal AO of each of the operation circuits MA[1,1] to MA[9,10] (not shown in FIG. 21). The data for initialization can be data with a value of “0”, for example. The potential of the wiring URST is changed from a low-level potential to a high-level potential, so that the potential of the terminal AO is made appropriate by the register RG3. The potential of the terminal AO at this time is preferably a potential corresponding to, for example, the value of “0”, for example. When the potential of the wiring URST is a low-level potential, the potential of the wiring SEL is set to a high-level potential, whereby the potential of the terminal MO is made appropriate by the register RG4. The potential of the terminal MO at this time is preferably a potential corresponding to, for example, the value of “0”.

[Step 1: Input of image data]

Next, the pixel data pix of the image data IPD is input to each of the operation circuits MA[1,1] to MA[9,10] of the MAC array MAR in the operation apparatus 100. Here, as an example, the image data IPD is composed of the plurality pieces of pixel data pix[1,1] to pix[m,n] of m rows and n columns as shown in FIG. 10A, in a manner similar to that in the above-described operation method.

The image data IPD is read out from the memory unit MEMD of the operation apparatus 100, for example.

Like in the above-described operation method, the register RG[1,p] to the register RG[9,p] are electrically connected to the MAC array MAR also in this operation method. Accordingly, the pixel data pix is input to the s-th row of the MAC array MAR via the registers RG[s,1] to RG[s,p].

The register RG[s,1] to the register RG[s,p] sequentially transmit a plurality pieces of pixel data pix read out from the memory unit MEMD every time potential change from a low-level potential to a high-level potential is input as a clock signal to the wiring CKL. Furthermore, as described above, since the operation circuit MA[s,1] to the operation circuit MA[s,10] of the s-th row each have a function of a register with the terminal SI serving as an input terminal and the terminal SO serving as an output terminal, the pixel data pix transmitted to the register RG[s,p] is transmitted to the operation circuits MA[s,1] to MA[s,10] sequentially in accordance with clock signals.

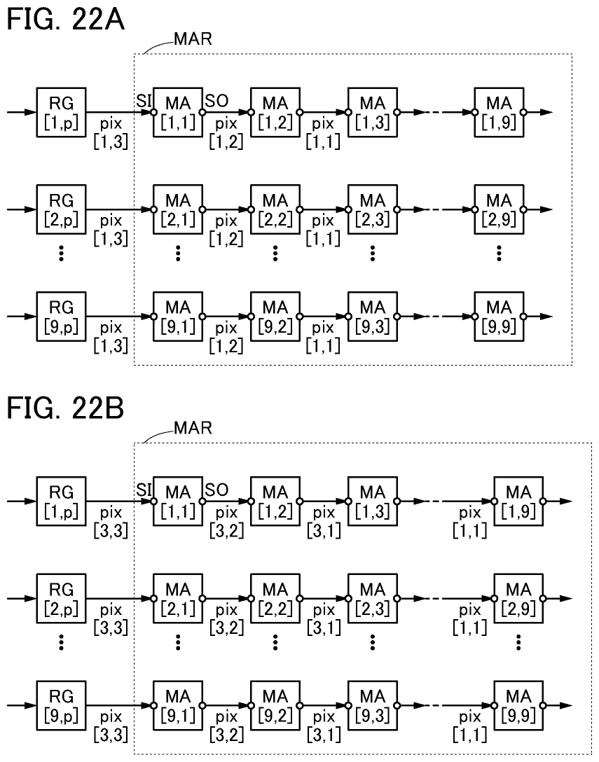

In this operating method, as for the transmission of the pixel data pix to the MAC array MAR, the same pixel data pix is input to the same column of the operation circuit MA at the same timing for every row, as illustrated in FIG. 22A. Note that FIG. 22A illustrates input of the pixel data pix to the MAC array MAR at Time T₂₃. Specifically, for example, the pixel data pix[1,1] is retained by each of the registers RG1 of the operation circuits MA[1,2] to MA[9,2] and output to each of the terminals SO of the operation circuits MA[1,2] to MA[9,2]. Similarly, the pixel data pix[1,2] is retained by each of the registers RG1 of the operation circuits MA[1,1] to MA[9,1]. Note that the registers RG[1,p] to RG[9,p] on the outside of the MAC array MAR retain the pixel data pix[1,3] and input the pixel data pix[1,3] to the operation circuits MA[1,1] to MA[9,1]. Note that the operation circuit MA[1,10] to the operation circuit MA[9,10] and the like are not illustrated in FIG. 22A.

Potential change of the clock signal from a low-level potential to a high-level potential occurs six times from the stage illustrated in FIG. 22A, whereby the pixel data pix[3,3] is input to the terminals SI of the operation circuits MA[1,1] to MA[9,1] as illustrated in FIG. 22B. Note that the time at this point is Time T₂₉.

Note that a low-level potential is input to the wiring SLT until the pixel data pix[1,1] is retained in the registers RG1 of the operation circuits MA[1,9] to MA[9,9]. That is, in a period from the time when the pixel data pix[1,1] input to the MAC ARRAY MAR to the time when the pixel data pix[1,1] is retained in the registers RG1 of the operation circuits MA[1,1] to MA[9,9], the register RG2 does not obtain the pixel data pix from the terminal IT2.

After the pixel data pix[1,1] is retained in the registers RG1 of the operation circuits MA[1,9] to MA[9,9], a high-level potential is input to the wiring SLT temporarily (the time at this point is Time T₃₁). At this time, potential change of the clock signal from a low-level potential to a high-level potential occurs, whereby the registers RG2 retain the pixel data pix[1,1] input to the terminals IT2 of the registers RG2 of the operation circuits MA[1,9] to MA[9,9] and output the pixel data pix[1,1] to the terminals OT2. Note that after the pixel data pix[1,1] is retained in each of the registers RG2 of the operation circuits MA[1,9] to MA[9,9], a low-level potential is input to the wiring SLT. This is performed in order to prevent the pixel data pix[1,1] retained in the register RG2 from being rewritten when potential change of the clock signal from a low-level potential to a high-level potential occurs.

Similarly, also in the operation circuits in the MAC array MAR other than the operation circuits MA[1,9] to MA[9,9], a high-level potential is temporarily input to the wiring SLT at Time T₃₁. Accordingly, the pixel data pix input to each of the terminals IT2 of the registers RG2 of the operation circuits MA[1,1] to MA[9,8] at Time T₃₁ is retained, and the pixel data pix is output to each of the terminals OT2. For example, since the pixel data pix[3,3] is input to the terminal IT2 of the register RG2 of the operation circuit MA[9,1], a high-level potential is input to the wiring SLT at this time, whereby the pixel data pix[3,3] is output to the terminal OT2.

### [Step 2: Readout of Filter Value]

Furthermore, at Time T₃₁, a filter value is read out from each of the memory units OSM of the operation circuits MA[1,1] to MA[1,9] of the MAC array MAR in the operation apparatus 100. The filter value is one of components of a matrix included in a filter fil_{Ct}. Here, the matrix is a matrix of three rows and three columns like in filₜ illustrated in FIG. 9A. Note that as an example, a filter value corresponding to a context CTEX1 is read out from each of the memory units OSM of the operation circuits MA[1,1] to MA[1,10] positioned in the first row of the MAC array MAR.

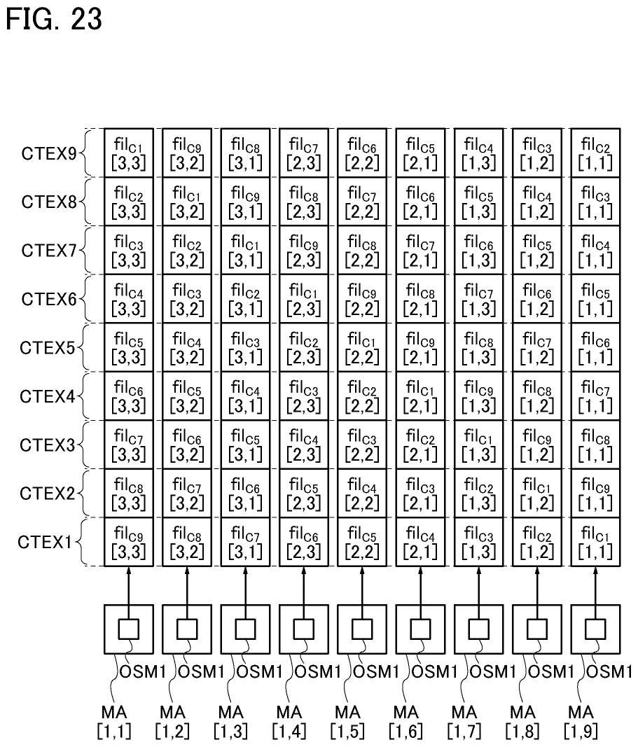

The filter value corresponding to the context CTEX1 is a value that is read out from each of the memory units OSM of the operation circuits MA[1,1] to MA[1,9] and is in a block denoted by the context CTEX1 in FIG. 23. Note that FIG. 23 also illustrates filter values corresponding to a context CTEX2 to a context CTEX9 in addition to those corresponding to the context CTEX1.

Specifically, a signal of the context CTEX1 is supplied to each of the memory units OSM of the operation circuits MA[1,1] to MA[1,9], whereby fil_{C1}[1,1] is read out from the memory unit OSM of the operation circuit MA[1,9], fil_{C2}[1,2] is read out from the memory unit OSM of the operation circuit MA[1,8], fil_{C3}[1,3] is read out from the memory unit OSM of the operation circuit MA[1,7], fil_{C4}[2,1] is read out from the memory unit OSM of the operation circuit MA[1,6], fil_{C5}[2,2] is read out from the memory unit OSM of the operation circuit MA[1,5], fil_{C6}[2,3] is read out from the memory unit OSM of the operation circuit MA[1,4], fil_{C7}[3,1] is read out from the memory unit OSM of the operation circuit MA[1,3], fil_{C8}[3,2] is read out from the memory unit OSM of the operation circuit MA[1,2], and fil_{C9}[3,3] is read out from the memory unit OSM of the operation circuit MA[1,1].

### [Step 3: Multiplication of Pixel Data and Filter Value]

Next, pixel data and a filter value that are performed in each of the multipliers MP of the operation circuits MA[1,1] to MA[1,9] in the first row of the MAC array MAR will be described.

For example, fil_{C1}[1,1] is input as a filter value to the terminal WI of the multiplier MP in the operation circuit MA[1,9]. Since the pixel data pix[1,1] is retained in the register RG2, the pixel data pix[1,1] is input to the terminal XI of the multiplier MP. Accordingly, fil_{C1}[1,1]×pix[1,1] is output to the terminal ZO of the multiplier MP. In addition, data of “0” is input as the initial value to the terminal ST of the adder AD. Therefore, fil_{C1}[1,1]×pix[1,1] is input to the terminal FT of the adder AD, so that fil_{C1}[1,1]×pix[1,1] is output to the terminal TT of the adder AD. Note that in this operating example, A₁[1]=fil_{C1}[1,1]×pix[1,1]. A₁[1] is input to the terminal IT3 of the register RG3 of the operation circuit MA[1,9].

For example, fil_{C9}[3,3] is input as a filter value to the terminal WI of the multiplier MP in the operation circuit MA[1,1]. Since the pixel data pix[3,3] is retained in the register RG2, the pixel data pix[3,3] is input to the terminal XI of the multiplier MP. Accordingly, fil_{C1}[3,3]×pix[3,3] is output to the terminal ZO of the multiplier MP. In addition, data of “0” is input as the initial value to the terminal ST of the adder AD. Therefore, fil_{C9}[3,3]×pix[3,3] is input to the terminal FT of the adder AD, so that fil_{C9}[3,3]×pix[3,3] is output to the terminal TT of the adder AD. Note that in this operating example, A₉[1]=fil_{C9}[3,3]×pix[3,3]. A₉[1] is input to the terminal IT3 of the register RG3 of the operation circuit MA[1,1].

An operation similar to those in the operation circuit MA[1,9] and the operation circuit MA[1,1] is performed in the operation circuit MA[1,2] to the operation circuit MA[1,8]. Here, the multiplication result output from each of the adders AD is input to each of the terminals IT3 of the registers RG3. The following table shows multiplication results input to the terminals IT3 of the registers RG3 of the operation circuits MA[1,1] to MA[1,9]. Note that the multiplication results are A₉[1], As[1], A₇[1], A₆[1], A₅[1], A₄[1], A₃[1], and A₂[1].

TABLE 1

| Operation circuit | Operation result |
|---|---|
| Operation circuit MA[1, 1] | A₉[1] = fil_{C9}[3, 3] × pix[3, 3] |
| Operation circuit MA[1, 2] | A₈[1] = fil_{C8}[3, 2] × pix[3, 2] |
| Operation circuit MA[1, 3] | A₇[1] = fil_{C7}[3, 1] × pix[3, 1] |
| Operation circuit MA[1, 4] | A₆[1] = fil_{C6}[2, 3] × pix[2, 3] |
| Operation circuit MA[1, 5] | A₅[1] = fil_{C5}[2, 2] × pix[2, 2] |
| Operation circuit MA[1, 6] | A₄[1] = fil_{C4}[2, 1] × pix[2, 1] |
| Operation circuit MA[1, 7] | A₃[1] = fil_{C3}[1, 3] × pix[1, 3] |
| Operation circuit MA[1, 8] | A₂[1] = fil_{C2}[1, 2] × pix[1, 2] |
| Operation circuit MA[1, 9] | A₁[1] = fil_{C1}[1, 1] × pix[1, 1] |

### [Step 4: Switching of Filter Value and Addition of Operation Result]

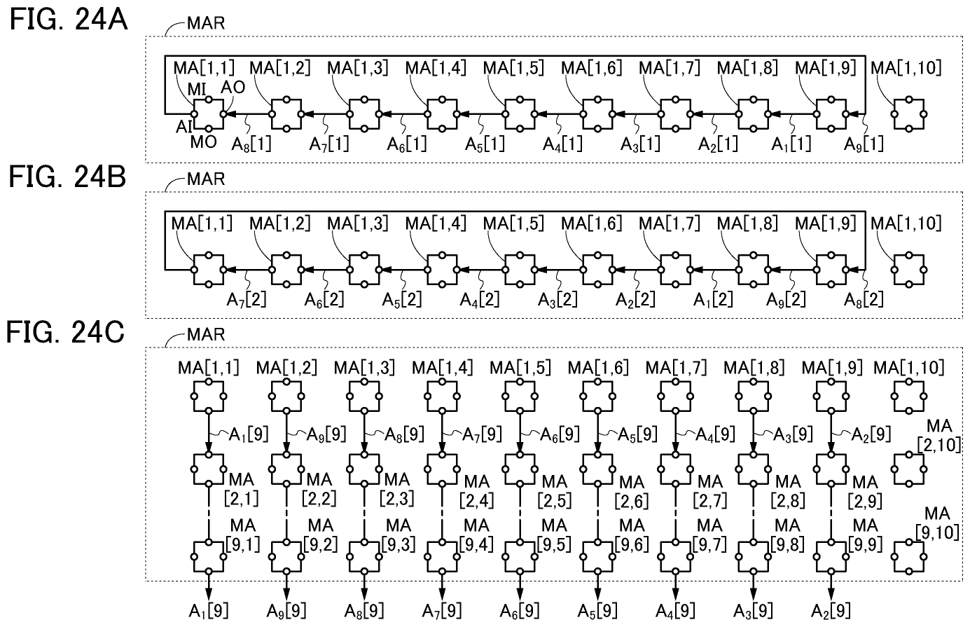

Here, in the case where potential change of the clock signal from a low-level potential to a high-level potential occurs, each of the registers RG3 of the operation circuits MA[1,1] to MA[1,9] retains addition data input to the terminal IT3 and outputs the addition data to the terminal OT3 of the register RG3 (the time at this point is Time T₃₂). Accordingly, as illustrated in FIG. 24A, A₉[1], A₈[1], A₇[1], A₆[1], A₅[1], A₄[1], A₃[1], A₂[1], and A₁[1] are output from the terminals AO of the operation circuits MA[1,1] to MA[1,9], respectively.

A₁[1] is input to the terminal AI of the operation circuit MA[1,8], A₂[1] is input to the terminal AI of the operation circuit MA[1,7], A₃[1] is input to the terminal AI of the operation circuit MA[1,6], A₄[1] is input to the terminal AI of the operation circuit MA[1,5], A₅[1] is input to the terminal AI of the operation circuit MA[1,4], A₆[1] is input to the terminal AI of the operation circuit MA[1,3], A₇[1] is input to the terminal AI of the operation circuit MA[1,2], A₈[1] is input to the terminal AI of the operation circuit MA[1,1], and A₉[1] is input to the terminal AI of the operation circuit MA[1,9].

In addition, in each of the operation circuits MA[1,1] to MA[1,9], a filter value corresponding to the context CNTX2 shown in FIG. 23 is read out from the memory unit OSM.

Specifically, fil_{C1}[1,2] is read out from the memory unit OSM of the operation circuit MA[1,8], fil_{C2}[1,3] is read out from the memory unit OSM of the operation circuit MA[1,7], fil_{C3}[2,1] is read out from the memory unit OSM of the operation circuit MA[1,6], fil_{C4}[2,2] is read out from the memory unit OSM of the operation circuit MA[1,5], fil_{C5}[2,3] is read out from the memory unit OSM of the operation circuit MA[1,4], fil_{C6}[3,1] is read out from the memory unit OSM of the operation circuit MA[1,3], fil_{C7}[3,2] is read out from the memory unit OSM of the operation circuit MA[1,2], fil_{C8}[3,3] is read out from the memory unit OSM of the operation circuit MA[1,1], and fil_{C9}[1,1] is read out from the memory unit OSM of the operation circuit MA[1,9].

Therefore, in each of the operation circuits MA[1,1] to MA[1,9], the pixel data pix retained by the register RG2 is input to the terminal XI of the multiplier MP and the changed filter value is input to the terminal WI of the multiplier MP, so that the result of multiplication of the pixel data and the filter value is output from the terminal ZO of the multiplier MP, in a manner similar to that in Step 3.

Furthermore, in each of the adders AD of the operation circuits MA[1,1] to MA[1,9], the multiplication result is input to the terminal FT of the adder AD and the data input to the terminal AI is input to the terminal ST of the adder AD. Therefore, addition data output from the terminal TT of the adder AD is as shown in the following table. Note that the multiplication results are A₈[2], A₇[2], A₆[2], A₅[2], A₄[2], A₃[2], A₂[2], A₁[2], and A₉[2].

TABLE 2

| Operation circuit | Operation result |
|---|---|
| Operation circuit MA[1, 1] | A₈[2] = A₈[1] + fil_{C8}[3, 3] × pix[3, 3] |
| Operation circuit MA[1, 2] | A₇[2] = A₇[1] + fil_{C7}[3, 2] × pix[3, 2] |
| Operation circuit MA[1, 3] | A₆[2] = A₆[1] + fil_{C6}[3, 1] × pix[3, 1] |
| Operation circuit MA[1, 4] | A₅[2] = A₅[1] + fil_{C5}[2, 3] × pix[2, 3] |
| Operation circuit MA[1, 5] | A₄[2] = A₄[1] + fil_{C4}[2, 2] × pix[2, 2] |
| Operation circuit MA[1, 6] | A₃[2] = A₃[1] + fil_{C3}[2, 1] × pix[2, 1] |
| Operation circuit MA[1, 7] | A₂[2] = A₂[1] + fil_{C2}[1, 3] × pix[1, 3] |
| Operation circuit MA[1, 8] | A₁[2] = A₁[1] + fil_{C1}[1, 2] × pix[1, 2] |
| Operation circuit MA[1, 9] | A₉[2] = A₉[1] + fil_{C9}[1, 1] × pix[1, 1] |

Then, As[2], A₇[2], A₆[2], A₅[2], A₄[2], A₃[2], A₂[2], A₁[2], and A₉[2] are input to the terminals IT3 of the registers RG3 of the operation circuits MA[1,1] to MA[1,9], respectively.

Note that when potential change of the clock signal from a low-level potential to a high-level potential occurs, the registers RG3 of the operation circuits MA[1,1] to MA[1,9] output A₈[2], A₇[2], A₆[2], A₅[2], A₄[2], A₃[2], A₂[2], A₁[2], and A₉[2] from the terminals AO of the operation circuits MA[1,1] to MA[1,9], respectively, as shown in FIG. 24B.

### [Step 5: Repetition of Step 4]

The following sequence of operations of Step 4 is performed repeatedly: retention of data input to each of the registers RG3 of the operation circuits MA[1,1] to MA[1,9], output of the data to the terminals OT3 of the registers RG3, readout of a corresponding filter value from each of the memory units OSM of the operation circuits MA[1,1] to MA[1,9], and addition of the multiplication result of the filter value and the pixel data pix to the data. In particular, as the filter value read out from each of the memory units OSM of the operation circuits MA[1,1] to MA[1,9], a context CNTX3 to a context CNTX9 illustrated in FIG. 23 are sequentially selected.

For example, in the operation circuit MA[1,1], as a filter value read out from the memory unit OSM in a period from Time T₃₃ to Time T₄₀, the context CNTX3 to the context CNTX9 in FIG. 23 are sequentially selected to be switched to fil₇[3,3], fil_{C6}[3,3], fil_{C5}[3,3], fil_{C4}[3,3], fil_{C3}[3,3], fil_{C2}[3,3], and fil_{C1}[3,3]. Then, the operation circuit MA[1,1] outputs A₇[3], A₆[4], A₅[5], A₄[6], A₃[7], A₂[8], and A₁[9] from the terminal AO by an operation for each of the context CNTX3 to the context CNTX9.

From the above, at the stage of Time T₄₀, A₁[9], A₉[9], A₈[9], A₇[9], A₆[9], A₅[9], A₄[9], A₃[9], and A₂[9] are input to the terminals IT3 of the registers RG3 of the operation circuits MA[1,1] to MA[1,9], respectively.

As an example, A₁[9] is a value obtained as a result of product-sum operations of the filter value and the pixel data pix by the operation circuits MA[1,1] to MA[1,9]. Specifically, according to the above operation, A₁[9]=fil_{C1}[1,1]×pix[1,1]+fil_{C1}[1,2]×pix[1,2]+fil_{C1}[1,3]×pix[1,3]+fil_{C1}[2,1]×pix[2,1]+fil_{C1}[2,2]×pix[2,2]+fil_{C1}[2,3]×pix[2,3]+fil_{C1}[3,1]×pix[3,1]+fil_{C1}[3,2]×pix[3,2]+fil_{C1}[3,3]×pix[3,3].

That is, A₁[9] is the value obtained by performing convolution on the regions of the pixel data pix[1,1] to pix[1,3], the pixel data pix[2,1] to pix[2,3], and the pixel data pix[3,1] to pix[3,3] in the image data IPD with the filter fil_{C1}.

Similarly, according to the above operation, A₉[9]=fil_{C9}[3,3]×pix[3,3]+fil_{C9}[1,1]×pix[1,1]+fil_{C9}[1,2]×pix[1,2]+fil_{C9}[1,3]×pix[1,3]+fil_{C9}[2,1]×pix[2,1]+fil_{C9}[2,2]×pix[2,2]+fil_{C9}[2,3]×pix[2,3]+fil_{C9}[3,1]×pix[3,1]+fil_{C9}[3,2]×pix[3,2].

That is, A₉[9] is the value obtained by performing convolution on the regions of the pixel data pix[1,1] to pix[1,3], the pixel data pix[2,1] to pix[2,3], and the pixel data pix[3,1] to pix[3,3] in the image data IPD with the filter fil_{C9}.

Accordingly, like A₁[9] and A₉[9], A₂[9] to A₈[9] are the values obtained by performing convolution on the regions of the pixel data pix[1,1] to pix[1,3], the pixel data pix[2,1] to pix[2,3], and the pixel data pix[3,1] to pix[3,3] in the image data IPD with the filters fil_{C2} to fil_{C8}

### [Step 6: Output of Product-Sum Operation Result]

In Step 6, the value of the product-sum operation is output from each of the terminals MO of the operation circuits MA[1,1] to MA[1,9]. Specifically, since a high-level potential is input to each of the control terminals of the selectors SLC of the operation circuits MA[1,1] to MA[1,9] at Time T₄₀, electrical continuity is established between the first input terminal and the output terminal and electrical continuity is not established between the second input terminal and the output terminal. Thus, electrical continuity is established between the terminal OT3 of the register RG3 and the terminal IT4 of the register RG4.

At this time, potential change of the clock signal from a low-level potential to a high-level potential occurs, so that data input to each of the terminals IT3 of the registers RG3 of the operation circuits MA[1,1] to MA[1,9] is retained and the data is output to the terminal OT3 of the register RG3. Therefore, the data is input to the terminal IT4 of the register RG4.

In other words, A₁[9], A₉[9], A₈[9], A₇[9], A₆[9], A₅[9], A₄[9], A₃[9], and A₂[9] are retained in the registers RG3 of the operation circuits MA[1,1] to MA[1,9], respectively, and each data is input to the terminal IT4 of the register RG4.

When potential change of the clock signal from a low-level potential to a high-level potential occurs again (the time at this point is T₄₁), the data input to the terminal IT4 of the register RG4 is retained by the register RG4 and the data is output to the terminal OT4 of the register RG4. Therefore, A₁[9], A₉[9], A₈[9], A₇[9], A₆[9], A₅[9], A₄[9], A₃[9], and A₂[9], which are output from the registers RG4 of the operation circuits MA[1,1] to MA[1,9], respectively, are output from the terminals MO of the operation circuits MA[1,1] to MA[1,9].

In addition, in Step 6, a low-level potential is input to the control terminal of the selector SLC of each of the operation circuits MA other than the operation circuits MA[1,1] to MA[1,9] of the MAC array MAR. Accordingly, electrical continuity is broken between the first input terminal and the output terminal and electrical continuity is established between the second input terminal and the output terminal. Therefore, electrical continuity is established between the terminal MI of the corresponding operation circuit MA and the terminal IT4 of the register RG4.

The programmable switches PC[1,t] to PC[9,t] of the MAC array MAR in this operating method each have a setting illustrated in FIG. 20 as described above; therefore, in the first column of the MAC array MAR, the terminal MO of the operation circuit MA[1,1] is electrically continuous with the terminal MI of the operation circuit MA[9,1] via the operation circuits MA[2,1] to MA[8,1]. This applies to the other columns; in one column of the MAC array MAR, the terminal MO of the operation circuit MA positioned in the first row is electrically continuous with the terminal MI of the operation circuit MA in the ninth row via the operation circuits MA in the second to eighth rows.

Accordingly, potential change of the clock signal from a low-level potential to a high-level potential occurs eight times since A₁[9], A₉[9], A₈[9], A₇[9], A₆[9], A₅[9], A₄[9], A₃[9], and A₂[9] are output from the terminals MO of the operation circuits MA[1,1] to MA[1,9], respectively, whereby A₁[9], A₉[9], A₈[9], A₇[9], A₆[9], A₅[9], A₄[9], A₃[9], and A₂[9] are output from the terminals MO of the operation circuits MA[9,1] to MA[9,9], respectively, as shown in FIG. 24C.

On the other hand, in each of the operation circuits MA other than the operation circuits MA[1,1] to MA[1,9] of the MAC array MAR, a low-level potential is input to the control terminal of the selector SLC; accordingly, electrical continuity is not established between the first input terminal and the output terminal. Therefore, the operation circuits MA other than the operation circuits MA[1,1] to MA[1,9] of MAC array MAR can perform operations concurrently at the same time as the output of the operations results such as A₁[9], A₉[9], A₈[9], A₇[9], A₆[9], A₅[9], A₄[9], A₃[9], and A₂[9] described above. Thus, in the operation circuits MA in the rows other than the first row of the MAC array MAR, for example, an convolution operation may be performed in regions other than the regions of the pixel data pix[1,1] to pix[1,3], the pixel data pix[2,1] to pix[2,3], and the pixel data pix[3,1] to pix[3,3] in the image data IPD in the image data IPD.

As shown in the timing chart of FIG. 21, during the operation performed by the multiplier MP and the adder AD, specifically, in a period from Time T₃₀ to Time T₃₉, the pixel data pix[1,2] to pix[1,4], the pixel data pix[2,2] to pix[2,4], and the pixel data pix[3,2] to pix[3,4] for performing the next operation may be sequentially transmitted from the registers RG[1,p] to RG[9,p] to the MAC array MAR. Owing to this operation, immediately after the convolution operation on the pixel data pix[1,1] to pix[1,3], the pixel data pix[2,1] to pix[2,3], and the pixel data pix[3,1] to pix[3,3], a convolution operation can be performed on the pixel data pix[1,2] to pix[1,4], the pixel data pix[2,2] to pix[2,4], and the pixel data pix[3,2] to pix[3,4] in the same manner. In addition, since the pixel data is transmitted during the operation, the waiting time for data transmission can be reduced, so that operation efficiency can be improved.

Processing with an activation function, a pooling layer, or the like may be performed on the convolution operation results output from the operation circuits MA[9,1] to MA[9,10], by the circuits AF[1] to AF[10]. For the processing, the description of the above-described operating method is referred to.

Also by this operating method, it is possible to generate image data of extracted feature portions (a feature map) having a dependence on the filter value file_{Ct} by performing convolution processing on the image data IPD with the filter fil_{Ct}, in a manner similar to that in the above-described operating method.

Note that the above operating method can be used for not only the convolution operation of image data but also the operation in the FNN.

For example, the case where signals are transmitted from m (here, m is an integer of 1 or more) neurons N^{(k-1)}₁ to N^{(k-1)}, of the (k−1)-th layer to n (here, n is an integer of 1 or more) neurons N^{(k)}₁ to N^{(k)}ₙ of the k-th layer is considered. When a signal transmitted from the neuron N^{(k-1)}ᵢ (here, i is an integer greater than or equal to 1 and less than or equal to m) of the (k−1)-th layer is z^{(k-1)}ᵢ and a weighting coefficient between the neuron N^{(k-1)}ᵢ of the (k−1)-th layer and the neuron N^{(k)}ⱼ of the k-th layer is w^{(k-1)}ᵢ^{(k)}ⱼ, the total sum of products of the signals input from the neurons N^{(k-1)}₁ to N^{(k-1)}ₘ of the (k−1)-th layer to the neuron N^{(k-1)}ⱼ of the k-th layer and the weighting coefficient is S^{(k)})ⱼ=Σw^{(k-1)}ᵢ^{(k)}ⱼ×z^{(k-1)}ᵢ (Σ is the total sum when i varies from 1 to m).

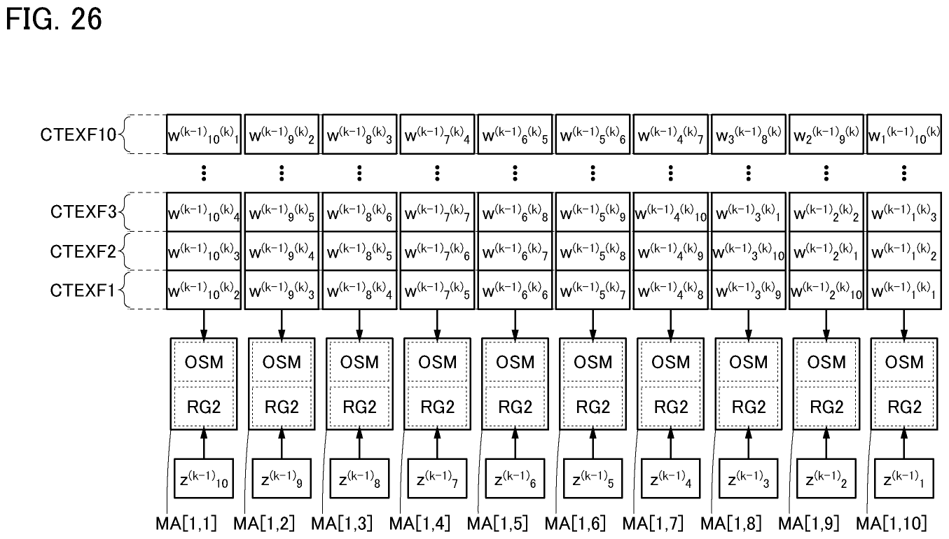

Here, a method for performing an operation on S^{(k)}ⱼ of each of the neurons N^{(k)}₁ to N^{(k)}ₙ of the k-th layer will be described. z^{(k-1)}ᵢ is retained in the registers RG2 of the operation circuits MA of one row of the MAC array MAR included in the operation apparatus 100. Specifically, for example, z^{(k-1)}₁₀ to z^{(k-1)}₁ are retained in the registers RG2 of the operation circuits MA[1,1] to MA[1,10], respectively, in FIG. 26.

Next, as an example, a context CNTXF1 to a context CNTXF10 are set for data read out from the memory units OSM of the operation circuits MA[1,1] to MA[1,10] as weighting coefficients. The context CNTXF1 to the context CNTXF10 are set as shown in FIG. 26, for example. In this manner, z^{(k-1)}₁₀ to z^{(k-1)}₁ are retained in the registers RG2 of the operation circuits MA[1,1] to MA[1,10] and the context CNTXF1 to the context CNTXF10 are set as the weighting coefficients read out from the memory units OSM as shown in FIG. 26, whereby the operation in the FNN can be performed in a manner similar to that for the above-described convolution operation.

Note that FIG. 26 illustrates the case where n is 10 as the number of neurons in the k-th layer; however, in the case where n is not 10, the number of contexts is set to n. Furthermore, FIG. 26 illustrates the case where m is 10 as the number of neurons of the (k−1)-th layer; however, in the case where m is less than 10, the number of operation circuits MA used for the operation is reduced. Alternatively, in the case where m is larger than 10, neuron signals on which an operation is performed next are retained in advance in the registers RG1 of the operation circuits MA[1,1] to MA[1,10] during the product-sum operation of the neuron signals z^{(k-1)}₁ to z^{(k-1)}₁₀ to and the weighting coefficients.

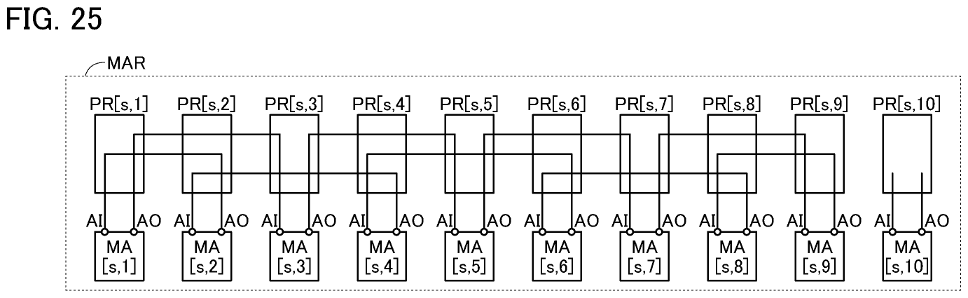

The operating method of the semiconductor device of one embodiment of the present invention is not limited to the above method. The operating method of the semiconductor device of one embodiment of the present invention can be changed depending on the situation. For example, the structure of the MAC array MAR illustrated in FIG. 19B that is set with the programmable switches PR may be changed to the structure of the MAC array MAR illustrated in FIG. 25 that is set with the programmable switches PR.

In the structure of the MAC array MAR illustrated in FIG. 25, the programmable switches PR[s,1] to PR[s,9] are set in a manner such that the terminal AO of the operation circuit MA is electrically continuous with the terminal AI of the operation circuit MA that is next to the next operation circuit MA. As for the operation circuit MA[s,1] and the operation circuit MA[s,2], the programmable switch PR[s,2] and the programmable switch PR[s,1] are set in a manner such that electrical continuity is established between the terminal AO of the operation circuit MA[s,2] and the terminal AI of the operation circuit MA[s,1]; as for the operation circuit MA[s,8] and the operation circuit MA[s,9], the programmable switch PR[s,9] and the programmable switch PR[s,8] are set in a manner such that electrical continuity is established between the terminal AO of the operation circuit MA[s,9] and the terminal AI of the operation circuit MA[s,8].

Signal delay might occur in the structure illustrated in FIG. 19B because the distance between the terminal AO of the operation circuit MA[s,1] and the terminal AI of the operation circuit MA[s,9] is long, while signal delay can be reduced in the structure illustrated in FIG. 25 because the distance between the operation circuits MA can be shortened averagely.

Note that this embodiment can be combined with any of the other embodiments in this specification as appropriate.

### Embodiment 2

In this embodiment, a memory circuit which can be used for the memory unit OSM described in the above embodiment will be described.

For example, a register, a flip-flop, an SRAM (Static Random Access Memory) or the like can be used as the memory unit OSM. Alternatively, a flash memory or the like may be used, for example.

In addition, a DOSRAM (Dynamic Oxide Semiconductor Random Access Memory) (registered trademark) or a NOSRAM (Dynamic Oxide Semiconductor Random Access Memory) (registered trademark) may be used as the memory unit OSM, for example.

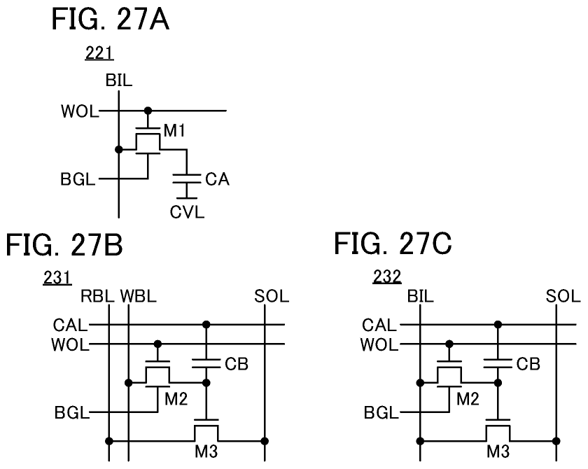

FIG. 27A illustrates a circuit structure example of a memory cell of a DOSRAM. A memory cell 221 includes a transistor M1 and a capacitor CA. Note that the transistor M1 includes a front gate (simply referred to as a gate in some cases) and a back gate.

A first terminal of the transistor M1 is connected to a first terminal of the capacitor CA, a second terminal of the transistor M1 is connected to a wiring BIL, the gate of the transistor M1 is connected to a wiring WOL, and the back gate of the transistor M1 is connected to a wiring BGL. A second terminal of the capacitor CA is connected to a wiring CVL.

The transistor M1 functions as a write transistor in the memory cell 221. Note that the write transistor is preferably an OS transistor described later.

The wiring BIL functions as a bit line, and the wiring WOL functions as a word line. A wiring CAL functions as a wiring for applying a predetermined potential to the second terminal of the capacitor CA. At the time of writing and reading out data, a low-level potential (referred to as reference potential in some cases) is preferably applied to the wiring CVL.

The wiring BGL functions as a wiring for applying a potential to the back gate of the transistor M1. By applying a given potential to the wiring BGL, the threshold voltage of the transistor M1 can be increased or decreased.

Data writing and reading are performed in such a manner that a high-level potential is applied to the wiring WOL to turn on the transistor M1 so that electrical continuity is established between the wiring BIL and the first terminal of the capacitor CA.

Specifically, data writing is performed by applying a potential corresponding to data to be written to the wiring BIL to write the potential to the first terminal of the capacitor CA via the transistor M1. After data writing, a low-level potential is applied to the wiring WOL to turn off the transistor M1, whereby the potential can be held in the memory cell 221.

In data reading, first, the wiring BIL is precharged at an appropriate potential, such as a middle potential between a low-level potential and a high-level potential, and then the wiring BIL is brought into an electrically floating state. After that, a high-level potential is applied to the wiring WOL to turn on the transistor M1, so that the potential of the wiring BIL is changed. Since the potential of the wiring BIL changes depending on the potential written to the first terminal of the capacitor CA, data retained in the memory cell 221 can be read using the changed potential of the wiring BIL.

The memory cell 221 described above is not limited to the circuit structure illustrated in FIG. 27A, and the circuit structure of the memory cell 221 may be changed as appropriate.

FIG. 27B illustrates a circuit structure example of a memory cell of a NOSRAM. A memory cell 231 includes a transistor M2, a transistor M3, and a capacitor CB. Note that the transistor M2 includes a front gate (simply referred to as a gate in some cases) and a back gate.

The transistor M2 functions as a write transistor in the memory cell 231. Note that the write transistor is preferably an OS transistor described later.

The transistor M3 functions as a read transistor in the memory cell 231. The read transistor is preferably an OS transistor, which is described later, or a transistor whose semiconductor layer includes silicon. Note that, in this operating example, the transistor M3 is assumed to operate in a saturation region unless otherwise specified. In other words, the gate voltage, the source voltage, and the drain voltage of the transistor M3 are assumed to be appropriately biased to voltages in the range where the transistor operates in the saturation region.

A first terminal of the transistor M2 is connected to a first terminal of the capacitor CB, a second terminal of the transistor M2 is connected to a wiring WBL, the gate of the transistor M2 is connected to the wiring WOL, and the back gate of the transistor M2 is connected to the wiring BGL. A second terminal of the capacitor CB is connected to the wiring CAL. A first terminal of the transistor M3 is connected to a wiring RBL, a second terminal of the transistor M3 is connected to a wiring SOL, and a gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. When data is retained, a low-level potential (referred to as a reference potential in some cases) is preferably applied to the wiring CAL and when data is written and when data is read out, a high-level potential is preferably applied to the wiring CAL.

The wiring BGL functions as a wiring for applying a potential to the back gate of the transistor M2. By applying a given potential to the wiring BGL, the threshold voltage of the transistor M2 can be increased or decreased.

Data writing is performed in such a manner that a high-level potential is applied to the wiring WOL to turn on the transistor M2, so that electrical continuity is established between the wiring WBL and the first terminal of the capacitor CB. Specifically, when the transistor M2 is in an on state, a potential corresponding to information stored in the wiring WBL is applied, whereby the potential is written to the first terminal of the capacitor CB and the gate of the transistor M3. After that, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SOL. The current flowing between a source and a drain of the transistor M3 and the potential of the first terminal of the transistor M3 are determined by the potential of the gate of the transistor M3 and the potential of the second terminal of the transistor M3; therefore, the potential of the wiring RBL electrically connected to the first terminal of the transistor M3 is read out, so that the potential retained in the first terminal of the capacitor CB (or the gate of the transistor M3) can be read out. In other words, data written into this memory cell can be read out from the potential retained in the first terminal of the capacitor CB (or the gate of the transistor M3).

The memory cell 231 described above is not limited to the circuit structure illustrated in FIG. 27B and the circuit structure of the memory cell 231 may be changed as appropriate. For example, the wiring WBL and the wiring RBL may be combined into one wiring BIL. FIG. 27C illustrates a circuit structure example of the memory cell. In a memory cell 232, one wiring BIL corresponds to the wiring WBL and the wiring RBL in the memory cell 231, and the second terminal of the transistor M2 and the first terminal of the transistor M3 are connected to the wiring BIL. In other words, the memory cell 232 operates with one wiring BIL functioning as a write bit line and a read bit line.

The DOSRAM and the NOSRAM are memory devices including OS transistors as write transistors, as described above. The semiconductor layer of the OS transistor includes a metal oxide described in Embodiment 3. For example, one or more materials selected from indium, an element M (the element M is one or more kinds of elements selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, magnesium, and the like), and zinc can be used for the metal oxide. In particular, when a metal oxide including indium, gallium, and zinc is included in the semiconductor layer, the band gap of the semiconductor layer can be increased. Thus, the off-state current of the OS transistor can be reduced.

Note that this embodiment can be combined with any of the other embodiments in this specification as appropriate.

### Embodiment 3

This embodiment describes structure examples of the semiconductor device described in the above embodiment and structure examples of a transistor that can be applied to the semiconductor device.

### <Structure Example of Semiconductor Device>

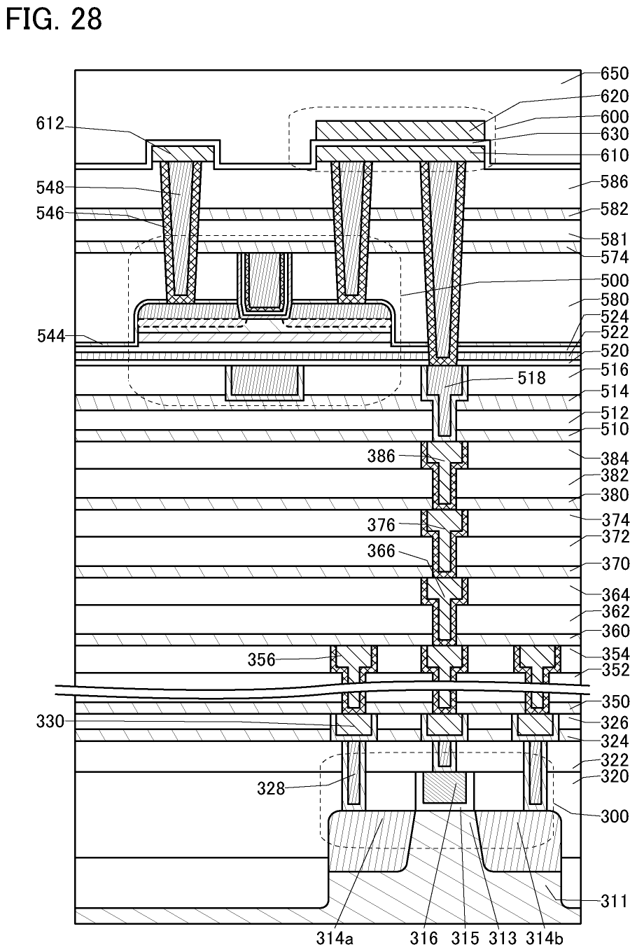

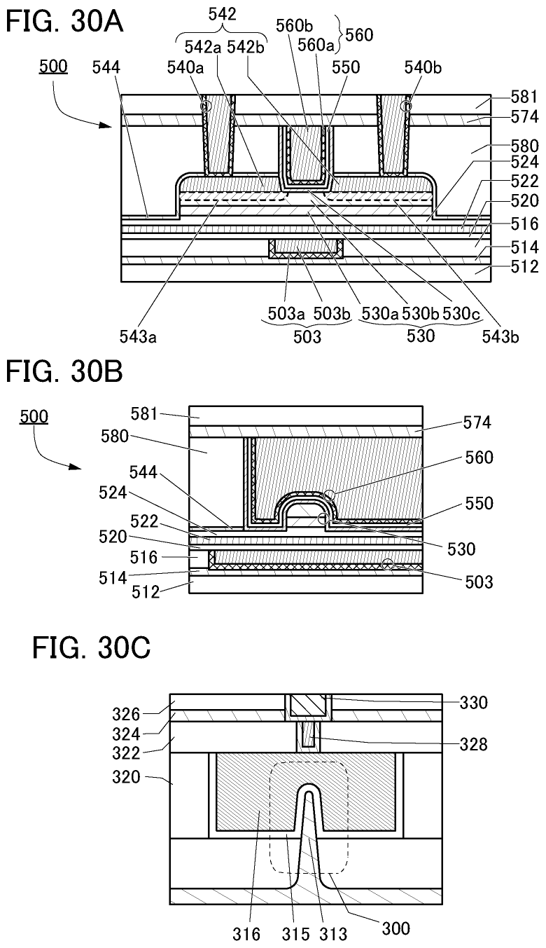

A semiconductor device illustrated in FIG. 28 includes a transistor 300, a transistor 500, and a capacitor 600. FIG. 30A is a cross-sectional view of the transistor 500 in the channel length direction, FIG. 30B is a cross-sectional view of the transistor 500 in the channel width direction, and FIG. 30C is a cross-sectional view of the transistor 300 in the channel width direction.

The transistor 500 is a transistor including a metal oxide in its channel-formation region (an OS transistor). The transistor 500 has features that the off-state current is small and that the field-effect mobility does not change even at high temperatures. The transistor 500 is used as a transistor included in a semiconductor device, for example, the operation apparatus 100, the operation apparatus 100A, or the like described in the above embodiment, whereby a semiconductor device whose operating capability does not deteriorate even at a high temperature can be obtained. In particular, by utilizing the feature of a small off-state current, the transistor 500 can be used as the transistor M1 and the transistor M2, and a potential written in the memory cell 221, the memory cell 231, the memory cell 232, and the like can be stored for a long time.

The semiconductor device described in this embodiment includes the transistor 300, the transistor 500, and the capacitor 600 as illustrated in FIG. 28, for example. The transistor 500 is provided above the transistor 300, and the capacitor 600 is provided above the transistor 300 and the transistor 500, for example. Note that the capacitor 600 can be, for example, the capacitor included in the memory cell 231, the memory cell 232, or the like described in the above embodiment. Note that depending on a circuit structure, the capacitor 600 illustrated in FIG. 28 is not necessarily provided.

The transistor 300 is provided on a substrate 311 and includes a conductor 316, an insulator 315, a semiconductor region 313 that is part of the substrate 311, and a low-resistance region 314a and a low-resistance region 314b each functioning as a source region or a drain region. Note that the transistor 300 can be used as, for example, the transistor and the like included in the operation apparatus 100, the operation apparatus 100A, and the like that are described in the above embodiment.

A semiconductor substrate (e.g., a single crystal substrate or a silicon substrate) is preferably used as the substrate 311.

In the transistor 300, the top surface and the side surface in the channel width direction of the semiconductor region 313 are covered with the conductor 316 with the insulator 315 therebetween, as illustrated in FIG. 30C. Such a Fin-type transistor 300 can have an increased effective channel width, and thus the transistor 300 can have improved on-state characteristics. In addition, since contribution of an electric field of a gate electrode can be increased, the off-state characteristics of the transistor 300 can be improved.

Note that the transistor 300 can be either a p-channel transistor or an n-channel transistor.

A region of the semiconductor region 313 where a channel is formed, a region in the vicinity thereof, the low-resistance region 314a and the low-resistance region 314b each functioning as a source region or a drain region, and the like preferably contain a semiconductor such as a silicon-based semiconductor, and preferably contain single crystal silicon. Alternatively, the regions may be formed using a material containing Ge (germanium), SiGe (silicon germanium), GaAs (gallium arsenide), GaAlAs (gallium aluminum arsenide), GaN (gallium nitride) or the like. A structure may be employed in which silicon whose effective mass is controlled by applying stress to the crystal lattice and changing the lattice spacing is used. Alternatively, the transistor 300 may be an HEMT (High Electron Mobility Transistor) with GaAs and GaAlAs, or the like.

The low-resistance region 314a and the low-resistance region 314b contain an element which imparts n-type conductivity, such as arsenic or phosphorus, or an element which imparts p-type conductivity, such as boron, in addition to the semiconductor material used for the semiconductor region 313.

For the conductor 316 functioning as a gate electrode, a semiconductor material such as silicon containing the element which imparts n-type conductivity, such as arsenic or phosphorus, or the element which imparts p-type conductivity, such as boron, or a conductive material such as a metal material, an alloy material, or a metal oxide material can be used.

Note that since the work function of a conductor depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

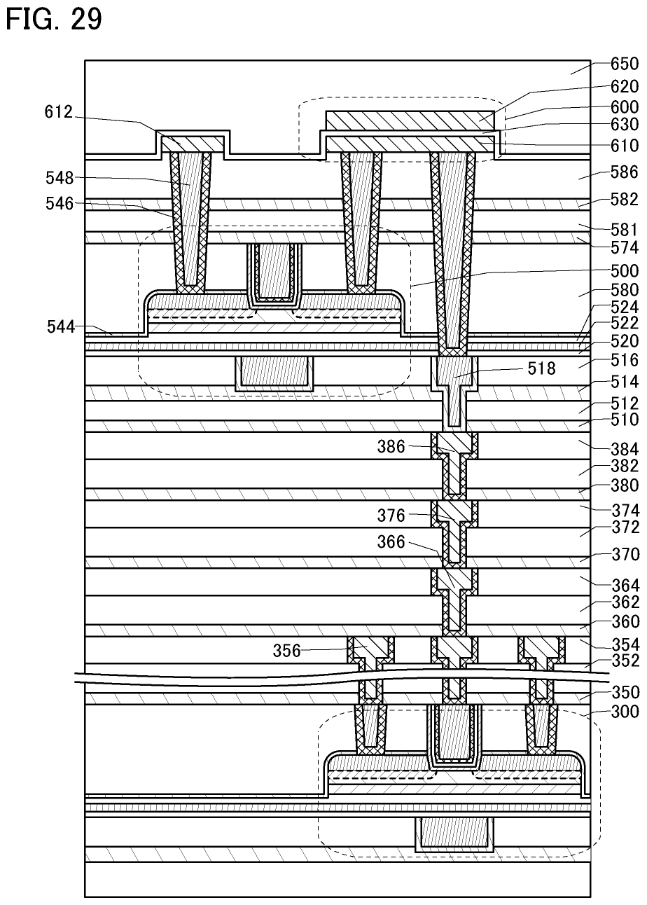

Note that the transistor 300 illustrated in FIG. 28 is just an example and is not limited to having the structure shown therein; an appropriate transistor can be used in accordance with a circuit structure or a driving method. For example, when the semiconductor device is a single-polarity circuit using only OS transistors (which means a circuit constituted by transistors having the same polarity, e.g., only n-channel transistors in this specification and the like), the transistor 300 has a structure similar to that of the transistor 500 using an oxide semiconductor, as illustrated in FIG. 29. Note that the details of the transistor 500 are described later.

An insulator 320, an insulator 322, an insulator 324, and an insulator 326 are stacked sequentially to cover the transistor 300.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like is used, for example.

Note that in this specification, silicon oxynitride refers to a material that contains oxygen at a higher proportion than nitrogen, and silicon nitride oxide refers to a material that contains nitrogen at a higher proportion than oxygen. Furthermore, in this specification, aluminum oxynitride refers to a material that contains oxygen at a higher proportion than nitrogen, and aluminum nitride oxide refers to a material that contains nitrogen at a higher proportion than oxygen.

The insulator 322 may have a function of a planarization film for planarizing a level difference caused by the transistor 300 or the like provided below the insulator 322. For example, a top surface of the insulator 322 may be planarized by planarization treatment using a chemical mechanical polishing (CMP) method or the like to improve planarity.

As the insulator 324, it is preferable to use a film having a barrier property that prevents diffusion of hydrogen or impurities from the substrate 311, the transistor 300, or the like into a region where the transistor 500 is provided.

For the film having a barrier property against hydrogen, silicon nitride formed using a CVD method can be used, for example. Here, diffusion of hydrogen into a semiconductor element including an oxide semiconductor, such as the transistor 500, degrades the characteristics of the semiconductor element in some cases. Therefore, a film that inhibits hydrogen diffusion is preferably used between the transistor 500 and the transistor 300. The film that inhibits hydrogen diffusion is specifically a film from which a small amount of hydrogen is released.

The amount of released hydrogen can be analyzed by thermal desorption spectroscopy (TDS) or the like, for example. The amount of hydrogen released from the insulator 324 that is converted into hydrogen atoms per area of the insulator 324 is less than or equal to 10×10¹⁵ atoms/cm², preferably less than or equal to 5×10¹⁵ atoms/cm², in the TDS analysis in a film-surface temperature range of 50° C. to 500° C., for example.

Note that the permittivity of the insulator 326 is preferably lower than that of the insulator 324. For example, the relative permittivity of the insulator 326 is preferably lower than 4, further preferably lower than 3. The relative permittivity of the insulator 326 is, for example, preferably 0.7 times or less, further preferably 0.6 times or less the relative permittivity of the insulator 324. When a material with a low permittivity is used for an interlayer film, parasitic capacitance generated between wirings can be reduced.

In addition, a conductor 328, a conductor 330, and the like that are connected to the capacitor 600 or the transistor 500 are embedded in the insulator 320, the insulator 322, the insulator 324, and the insulator 326. Note that the conductor 328 and the conductor 330 each have a function of a plug or a wiring. Furthermore, a plurality of conductors functioning as plugs or wirings are collectively denoted by the same reference numeral in some cases. Moreover, in this specification and the like, a wiring and a plug connected to the wiring may be a single component. That is, there are cases where part of a conductor functions as a wiring and part of a conductor functions as a plug.

As a material of each of plugs and wirings (e.g., the conductor 328 and the conductor 330), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, it is preferable to form the plugs and wirings with a low-resistance conductive material such as aluminum or copper. The use of a low-resistance conductive material can reduce wiring resistance.

A wiring layer may be provided over the insulator 326 and the conductor 330. For example, in FIG. 28, an insulator 350, an insulator 352, and an insulator 354 are stacked in this order. Furthermore, a conductor 356 is formed in the insulator 350, the insulator 352, and the insulator 354. The conductor 356 has a function of a plug or a wiring connected to the transistor 300. Note that the conductor 356 can be provided using a material similar to those for the conductor 328 and the conductor 330.

For example, like the insulator 324, the insulator 350 is preferably formed using an insulator having a barrier property against hydrogen. Furthermore, the conductor 356 preferably contains a conductor having a barrier property against hydrogen. In particular, the conductor having a barrier property against hydrogen is formed in an opening portion of the insulator 350 having a barrier property against hydrogen. With this structure, the transistor 300 and the transistor 500 can be separated by the barrier layer, so that diffusion of hydrogen from the transistor 300 into the transistor 500 can be inhibited.

Note that for the conductor having a barrier property against hydrogen, tantalum nitride is preferably used, for example. In addition, the use of a stack including tantalum nitride and tungsten, which has high conductivity, can inhibit diffusion of hydrogen from the transistor 300 while the conductivity of a wiring is maintained. In that case, a structure is preferable in which a tantalum nitride layer having a barrier property against hydrogen is in contact with the insulator 350 having a barrier property against hydrogen.

A wiring layer may be provided over the insulator 354 and the conductor 356. For example, in FIG. 28, an insulator 360, an insulator 362, and an insulator 364 are stacked in this order. Furthermore, a conductor 366 is formed in the insulator 360, the insulator 362, and the insulator 364. The conductor 366 has a function of a plug or a wiring. Note that the conductor 366 can be provided using a material similar to those for the conductor 328 and the conductor 330.

For example, like the insulator 324, the insulator 360 is preferably formed using an insulator having a barrier property against hydrogen. Furthermore, the conductor 366 preferably contains a conductor having a barrier property against hydrogen. In particular, the conductor having a barrier property against hydrogen is formed in an opening portion of the insulator 360 having a barrier property against hydrogen. With this structure, the transistor 300 and the transistor 500 can be separated by the barrier layer, so that diffusion of hydrogen from the transistor 300 into the transistor 500 can be inhibited.

A wiring layer may be provided over the insulator 364 and the conductor 366. For example, in FIG. 28, an insulator 370, an insulator 372, and an insulator 374 are stacked in this order. Furthermore, a conductor 376 is formed in the insulator 370, the insulator 372, and the insulator 374. The conductor 376 has a function of a plug or a wiring. Note that the conductor 376 can be provided using a material similar to those for the conductor 328 and the conductor 330.

For example, like the insulator 324, the insulator 370 is preferably formed using an insulator having a barrier property against hydrogen. Furthermore, the conductor 376 preferably contains a conductor having a barrier property against hydrogen. In particular, the conductor having a barrier property against hydrogen is formed in an opening portion of the insulator 370 having a barrier property against hydrogen. With this structure, the transistor 300 and the transistor 500 can be separated by the barrier layer, so that diffusion of hydrogen from the transistor 300 into the transistor 500 can be inhibited.

A wiring layer may be provided over the insulator 374 and the conductor 376. For example, in FIG. 28, an insulator 380, an insulator 382, and an insulator 384 are stacked in this order. Furthermore, a conductor 386 is formed in the insulator 380, the insulator 382, and the insulator 384. The conductor 386 has a function of a plug or a wiring. Note that the conductor 386 can be provided using a material similar to those for the conductor 328 and the conductor 330.

For example, like the insulator 324, the insulator 380 is preferably formed using an insulator having a barrier property against hydrogen. Furthermore, the conductor 386 preferably contains a conductor having a barrier property against hydrogen. In particular, the conductor having a barrier property against hydrogen is formed in an opening portion of the insulator 380 having a barrier property against hydrogen. With this structure, the transistor 300 and the transistor 500 can be separated by the barrier layer, so that diffusion of hydrogen from the transistor 300 into the transistor 500 can be inhibited.

Although the wiring layer including the conductor 356, the wiring layer including the conductor 366, the wiring layer including the conductor 376, and the wiring layer including the conductor 386 are described above, the semiconductor device of this embodiment is not limited thereto. Three or less wiring layers that are similar to the wiring layer including the conductor 356 may be provided, or five or more wiring layers that are similar to the wiring layer including the conductor 356 may be provided.

An insulator 510, an insulator 512, an insulator 514, and an insulator 516 are stacked sequentially and provided over the insulator 384. A substance having a barrier property against oxygen or hydrogen is preferably used for any of the insulator 510, the insulator 512, the insulator 514, and the insulator 516.

For example, as the insulator 510 and the insulator 514, it is preferable to use a film having a barrier property that prevents diffusion of hydrogen or impurities from the substrate 311, a region where the transistor 300 is provided, or the like into the region where the transistor 500 is provided. Thus, a material similar to that for the insulator 324 can be used.

For the film having a barrier property against hydrogen, silicon nitride formed using a CVD method can be used, for example. Here, diffusion of hydrogen into a semiconductor element including an oxide semiconductor, such as the transistor 500, degrades the characteristics of the semiconductor element in some cases. Therefore, a film that inhibits hydrogen diffusion is preferably used between the transistor 500 and the transistor 300. The film that inhibits hydrogen diffusion is specifically a film from which a small amount of hydrogen is released.

As the film having a barrier property against hydrogen, a metal oxide such as aluminum oxide, hafnium oxide, or tantalum oxide is preferably used for the insulator 510 and the insulator 514, for example.

In particular, aluminum oxide has an excellent blocking effect that prevents the passage of both oxygen and impurities such as hydrogen and moisture, which are factors of a change in electrical characteristics of the transistor. Accordingly, aluminum oxide can prevent mixing of impurities such as hydrogen and moisture into the transistor 500 in a manufacturing process and after manufacturing of the transistor. In addition, release of oxygen from the oxide included in the transistor 500 can be inhibited. Therefore, aluminum oxide is suitably used for the protective film of the transistor 500.

In addition, for the insulator 512 and the insulator 516, a material similar to that for the insulator 320 can be used, for example. Furthermore, when a material with a comparatively low permittivity is used for these insulators, parasitic capacitance generated between wirings can be reduced. A silicon oxide film, a silicon oxynitride film, or the like can be used for the insulator 512 and the insulator 516, for example.

Furthermore, a conductor 518, a conductor included in the transistor 500 (e.g., a conductor 503), and the like are embedded in the insulator 510, the insulator 512, the insulator 514, and the insulator 516. Note that the conductor 518 has a function of a plug or a wiring connected to the capacitor 600 or the transistor 300. The conductor 518 can be provided using a material similar to those for the conductor 328 and the conductor 330.

In particular, the conductor 518 in a region in contact with the insulator 510 and the insulator 514 is preferably a conductor having a barrier property against oxygen, hydrogen, and water. With this structure, the transistor 300 and the transistor 500 can be separated by the layer having a barrier property against oxygen, hydrogen, and water; hence, the diffusion of hydrogen from the transistor 300 into the transistor 500 can be inhibited.

The transistor 500 is provided above the insulator 516.

As illustrated in FIG. 30A and FIG. 30B, the transistor 500 includes the conductor 503 positioned to be embedded in the insulator 514 and the insulator 516, an insulator 520 positioned over the insulator 516 and the conductor 503, an insulator 522 positioned over the insulator 520, an insulator 524 positioned over the insulator 522, an oxide 530a positioned over the insulator 524, an oxide 530b positioned over the oxide 530a, a conductor 542a and a conductor 542b positioned apart from each other over the oxide 530b, an insulator 580 that is positioned over the conductor 542a and the conductor 542b and has an opening between the conductor 542a and the conductor 542b, an oxide 530c positioned on a bottom surface and a side surface of the opening, an insulator 550 positioned on the formation surface of the oxide 530c, and a conductor 560 positioned on the formation surface of the insulator 550.

As illustrated in FIG. 30A and FIG. 30B, an insulator 544 is preferably provided between the insulator 580 and the oxide 530a, the oxide 530b, the conductor 542a, and the conductor 542b. As illustrated in FIG. 30A and FIG. 30B, the conductor 560 preferably includes a conductor 560a provided on the inner side of the insulator 550 and a conductor 560b provided to be embedded on the inner side of the conductor 560a. As illustrated in FIG. 30A and FIG. 30B, an insulator 574 is preferably provided over the insulator 580, the conductor 560, and the insulator 550.

Note that in the following description, the oxide 530a, the oxide 530b, and the oxide 530c are sometimes collectively referred to as an oxide 530.

The transistor 500 is illustrated to have a structure in which the three layers of the oxide 530a, the oxide 530b, and the oxide 530c are stacked in the region where the channel is formed and in the vicinity thereof; however, one embodiment of the present invention is not limited thereto. For example, a single layer of the oxide 530b, a two-layer structure of the oxide 530b and the oxide 530a, a two-layer structure of the oxide 530b and the oxide 530c, or a stacked-layer structure of four or more layers may be employed. Furthermore, although the conductor 560 is illustrated to have a stacked-layer structure of two layers in the transistor 500, one embodiment of the present invention is not limited thereto. For example, the conductor 560 may have a single-layer structure or a stacked-layer structure of three or more layers. Moreover, the transistor 500 illustrated in FIG. 28, FIG. 30A, and FIG. 30B is an example and the structure is not limited thereto; an appropriate transistor is used in accordance with a circuit structure or a driving method.

Here, the conductor 560 functions as a gate electrode of the transistor, and the conductor 542a and the conductor 542b each function as a source electrode or a drain electrode. As described above, the conductor 560 is formed to be embedded in the opening of the insulator 580 and the region interposed between the conductor 542a and the conductor 542b. The positions of the conductor 560, the conductor 542a, and the conductor 542b with respect to the opening of the insulator 580 are selected in a self-aligned manner. That is, in the transistor 500, the gate electrode can be positioned between the source electrode and the drain electrode in a self-aligned manner. Thus, the conductor 560 can be formed without an alignment margin, resulting in a reduction in the area occupied by the transistor 500. Accordingly, miniaturization and high integration of the semiconductor device can be achieved.

In addition, since the conductor 560 is formed in the region between the conductor 542a and the conductor 542b in a self-aligned manner, the conductor 560 does not include a region overlapping with the conductor 542a or the conductor 542b. Thus, parasitic capacitance formed between the conductor 560 and each of the conductor 542a and the conductor 542b can be reduced. As a result, the switching speed of the transistor 500 can be improved, and the transistor 500 can have high frequency characteristics.

The conductor 560 sometimes functions as a first gate (also referred to as top gate) electrode. In addition, the conductor 503 sometimes functions as a second gate (also referred to as bottom gate) electrode. In that case, the threshold voltage of the transistor 500 can be controlled by changing a potential applied to the conductor 503 independently of a potential applied to the conductor 560. In particular, the threshold voltage of the transistor 500 can be higher than 0 V and the off-state current can be reduced by applying a negative potential to the conductor 503. Thus, a drain current at the time when a potential applied to the conductor 560 is 0 V can be lower in the case where a negative potential is applied to the conductor 503 than in the case where a negative potential is not applied to the conductor 503.

The conductor 503 is placed to overlap with the oxide 530 and the conductor 560. Thus, in the case where potentials are applied to the conductor 560 and the conductor 503, an electric field generated from the conductor 560 and an electric field generated from the conductor 503 are connected, so that a channel formation region formed in the oxide 530 can be covered. In this specification and the like, a transistor structure in which a channel formation region is electrically surrounded by electric fields of a first gate electrode and a second gate electrode is referred to as a surrounded channel (S-channel) structure.

In addition, the conductor 503 has a structure similar to that of the conductor 518; a conductor 503a is formed in contact with an inner wall of an opening of the insulator 514 and the insulator 516, and a conductor 503b is formed on the inner side. Although the transistor 500 is illustrated to have a structure in which the conductor 503a and the conductor 503b are stacked, one embodiment of the present invention is not limited thereto. For example, the conductor 503 may be provided as a single layer or to have a stacked-layer structure of three or more layers.

Here, for the conductor 503a, a conductive material that has a function of inhibiting diffusion of impurities such as a hydrogen atom, a hydrogen molecule, a water molecule, and a copper atom (through which the impurities are unlikely to pass) is preferably used. Alternatively, it is preferable to use a conductive material that has a function of inhibiting diffusion of oxygen (e.g., at least one of an oxygen atom, an oxygen molecule, and the like) (through which the oxygen is less likely to pass). Note that in this specification, a function of inhibiting diffusion of impurities or oxygen means a function of inhibiting diffusion of any one or all of the impurities and oxygen.

For example, when the conductor 503a has a function of inhibiting diffusion of oxygen, a reduction in conductivity of the conductor 503b due to oxidation can be inhibited.

In addition, in the case where the conductor 503 also functions as a wiring, a conductive material with high conductivity that contains tungsten, copper, or aluminum as its main component is preferably used for the conductor 503b. In that case, the conductor 503a is not necessarily provided. Note that the conductor 503b is illustrated as a single layer but may have a stacked-layer structure, for example, a stack of any of the above conductive materials and titanium or titanium nitride.

The insulator 520, the insulator 522, and the insulator 524 have a function of a second gate insulating film.

Here, as the insulator 524 that is in contact with the oxide 530, an insulator that contains oxygen more than oxygen in the stoichiometric composition is preferably used. That is, an excess-oxygen region is preferably formed in the insulator 524. When such an insulator containing excess oxygen is provided in contact with the oxide 530, oxygen vacancies in the oxide 530 can be reduced and the reliability of the transistor 500 can be improved. Note that in this specification and the like, an oxygen vacancy in a metal oxide is sometimes referred to as V_{O}. A transistor using a metal oxide is likely to change its electrical characteristics when impurities or oxygen vacancies (V_{O}) exist in a region of the metal oxide where a channel is formed, which might degrade the reliability. In particular, hydrogen in the vicinity of an oxygen vacancy (V_{O}) may form a defect that is an oxygen vacancy (V_{O}) into which hydrogen enters (hereinafter sometimes referred to as V_{O}H), which may generate an electron serving as a carrier. Accordingly, the transistor 500 is likely to have normally on characteristics.

As the insulator including an excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably in the range of 100° C. to 700° C. or 100° C. to 400° C.

One or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when a reaction in which a bond of V_{O}H is cut occurs, i.e., a reaction of “V_{O}H→V_{O}+H” occurs. Part of hydrogen generated at this time is bonded to oxygen to be H₂O, and removed from the oxide 530 or an insulator near the oxide 530 in some cases. Part of hydrogen is diffused into or gettered (also referred to as gettering) by the conductor 542a and the conductor 542b in some cases.

For the microwave treatment, for example, an apparatus including a power supply that generates high-density plasma or an apparatus including a power supply that applies RF to the substrate side is suitably used. For example, the use of an oxygen-containing gas and high-density plasma enables high-density oxygen radicals to be generated, and application of the RF to the substrate side allows the oxygen radicals generated by the high-density plasma to be efficiently introduced into the oxide 530 or an insulator in the vicinity of the oxide 530. The pressure in the microwave treatment is higher than or equal to 133 Pa, preferably higher than or equal to 200 Pa, further preferably higher than or equal to 400 Pa. As a gas introduced into an apparatus for performing the microwave treatment, for example, oxygen and argon are used and the oxygen flow rate ratio (O₂/(O₂+Ar)) is lower than or equal to 50%, preferably higher than or equal to 10% and lower than or equal to 30%.

In a manufacturing process of the transistor 500, heat treatment is preferably performed with the surface of the oxide 530 exposed. The heat treatment is performed at higher than or equal to 100° C. and lower than or equal to 450° C., preferably higher than or equal to 350° C. and lower than or equal to 400° C., for example. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 530 to reduce oxygen vacancies (V_{O}). The heat treatment may be performed under reduced pressure. Alternatively, the heat treatment may be performed in such a manner that heat treatment is performed in a nitrogen gas or inert gas atmosphere and then another heat treatment is performed in an atmosphere containing an oxidizing gas at 10 ppm or more, 1% or more, or 10% or more in order to compensate for released oxygen. Alternatively, the heat treatment may be performed in such a manner that heat treatment is performed in an atmosphere containing an oxidizing gas at 10 ppm or more, 1% or more, or 10% or more, and then another heat treatment is successively performed in a nitrogen gas or inert gas atmosphere.

Note that the oxygen adding treatment performed on the oxide 530 can promote a reaction in which oxygen vacancies in the oxide 530 are filled with supplied oxygen, in other words, a reaction of “V_{O}+O→null” is promoted. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of V_{O}H.

When the insulator 524 includes an excess-oxygen region, it is preferable that the insulator 522 have a function of inhibiting diffusion of oxygen (e.g., oxygen atoms and oxygen molecules) (or that the above oxygen be less likely to pass through the insulator 522).

When the insulator 522 has a function of inhibiting diffusion of oxygen or impurities, oxygen contained in the oxide 530 is not diffused into the insulator 520 side, which is preferable. Furthermore, the conductor 503 can be inhibited from reacting with oxygen contained in the insulator 524 or the oxide 530.

For the insulator 522, a single layer or stacked layers of an insulator containing what is called a high-k material such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba,Sr)TiO₃ (BST) are preferably used, for example. As miniaturization and high integration of transistors progress, a problem such as leakage current might arise because of a thinner gate insulating film. When a high-k material is used for an insulator functioning as the gate insulating film, a gate potential during transistor operation can be reduced while the physical thickness is maintained.

It is particularly preferable to use an insulator containing an oxide of one or both of aluminum and hafnium, which is an insulating material having a function of inhibiting diffusion of impurities, oxygen, and the like (through which the oxygen is less likely to pass). Aluminum oxide, hafnium oxide, an oxide containing aluminum and hafnium (hafnium aluminate), or the like is preferably used as the insulator containing an oxide of one or both of aluminum and hafnium. In the case where the insulator 522 is formed using such a material, the insulator 522 functions as a layer that inhibits release of oxygen from the oxide 530 and mixing of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. The insulator over which silicon oxide, silicon oxynitride, or silicon nitride is stacked may be used.

In addition, it is preferable that the insulator 520 be thermally stable. For example, silicon oxide and silicon oxynitride, which have thermal stability, are suitable. Furthermore, when an insulator that is a high-k material is combined with silicon oxide or silicon oxynitride, the insulator 520 having a stacked-layer structure that has thermal stability and a high dielectric constant can be obtained.

Note that in the transistor 500 in FIG. 30A and FIG. 30B, the insulator 520, the insulator 522, and the insulator 524 are shown as the second gate insulating film having a stacked-layer structure of three layers; however, the second gate insulating film may be a single layer or may have a stacked-layer structure of two layers or four or more layers. In such cases, without limitation to a stacked-layer structure formed of the same material, a stacked-layer structure formed of different materials may be employed.

In the transistor 500, a metal oxide functioning as an oxide semiconductor is preferably used as the oxide 530 including the channel-formation region. For example, as the oxide 530, a metal oxide such as an In-M-Zn oxide (the element M is one or more selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is preferably used. In particular, the In-M-Zn oxide that can be used as the oxide 530 is preferably a CAAC-OS (C-Axis Aligned Crystalline Oxide Semiconductor) or a CAC-OS (Cloud-Aligned Composite Oxide Semiconductor). Alternatively, an In—Ga oxide, an In—Zn oxide, an In oxide, or the like may be used as the oxide 530.

Furthermore, a metal oxide with a low carrier concentration is preferably used for the transistor 500. In order to reduce the carrier concentration of the metal oxide, the concentration of impurities in the metal oxide is reduced so that the density of defect states can be reduced. In this specification and the like, a state with a low impurity concentration and a low density of defect states is referred to as a highly purified intrinsic or substantially highly purified intrinsic state. Examples of impurities in a metal oxide include hydrogen, nitrogen, alkali metal, alkaline earth metal, iron, nickel, and silicon.

In particular, hydrogen contained in a metal oxide reacts with oxygen bonded to a metal atom to be water, and thus forms oxygen vacancies in the metal oxide in some cases. In the case where hydrogen enters an oxygen vacancy in the oxide 530, the oxygen vacancy and the hydrogen are bonded to each other to form V_{O}H in some cases. The V_{O}H serves as a donor and an electron that is a carrier is generated in some cases. In other cases, bonding of part of hydrogen to oxygen bonded to a metal atom generates electrons serving as carriers. Thus, a transistor using a metal oxide containing a large amount of hydrogen is likely to have normally-on characteristics. Moreover, hydrogen in a metal oxide easily moves by stress such as heat and an electric field; thus, the reliability of a transistor may be low when the metal oxide contains a large amount of hydrogen. In one embodiment of the present invention, V_{O}H in the oxide 530 is preferably reduced as much as possible so that the oxide 530 becomes a highly purified intrinsic or substantially highly purified intrinsic oxide. It is important to remove impurities such as moisture and hydrogen in a metal oxide (sometimes described as dehydration or dehydrogenation treatment) and to compensate for oxygen vacancies by supplying oxygen to the metal oxide (sometimes described as oxygen supplying treatment) to obtain a metal oxide whose V_{O}H is sufficiently reduced. When a metal oxide in which impurities such as V_{O}H are sufficiently reduced is used for a channel formation region of a transistor, stable electrical characteristics can be given.

A defect that is an oxygen vacancy into which hydrogen has entered can function as a donor of a metal oxide. However, it is difficult to evaluate the defects quantitatively. Thus, the metal oxide is sometimes evaluated in terms of not its donor concentration but its carrier concentration. Therefore, in this specification and the like, the carrier concentration assuming the state where an electric field is not applied is sometimes used, instead of the donor concentration, as the parameter of the metal oxide. That is, “carrier concentration” in this specification and the like can be replaced with “donor concentration” in some cases.

Consequently, when a metal oxide is used for the oxide 530, hydrogen in the metal oxide is preferably reduced as much as possible. Specifically, the hydrogen concentration of the metal oxide, which is measured by secondary ion mass spectrometry (SIMS), is lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³. When a metal oxide with a sufficiently low concentration of impurities such as hydrogen is used for a channel-formation region of a transistor, the transistor can have stable electrical characteristics.

In the case where a metal oxide is used as the oxide 530, the metal oxide is an intrinsic (also referred to as i-type) or substantially intrinsic semiconductor that has a large band gap, and the carrier concentration of the metal oxide in the channel formation region is preferably lower than 1×10¹⁸ cm⁻³, further preferably lower than 1×10¹⁷ cm³, still further preferably lower than 1×10¹⁶ cm⁻³, yet further preferably lower than 1×10¹³ cm⁻³, yet still further preferably lower than 1×10¹² cm³. Note that the lower limit of the carrier concentration of the metal oxide in the channel formation region is not particularly limited and can be, for example, 1×10⁻⁹ cm³.

In the case where a metal oxide is used as the oxide 530, contact between the oxide 530 and each of the conductor 542a and the conductor 542b may diffuse oxygen in the oxide 530 into the conductor 542a and the conductor 542b, resulting in oxidation of the conductor 542a and the conductor 542b in some cases. It is highly possible that oxidation of the conductor 542a and the conductor 542b lowers the conductivity of the conductor 542a and the conductor 542b. Note that diffusion of oxygen from the oxide 530 into the conductor 542a and the conductor 542b can be rephrased as absorption of oxygen in the oxide 530 by the conductor 542a and the conductor 542b.

When oxygen in the oxide 530 diffuses into the conductor 542a and the conductor 542b, a different layer is sometimes formed between the conductor 542a and the oxide 530b and between the conductor 542b and the oxide 530b. The different layer contains a larger amount of oxygen than the conductor 542a and the conductor 542b and thus presumably has an insulating property. In this case, a three-layer structure of the conductor 542a or the conductor 542b, the different layer, and the oxide 530b can be regarded as a three-layer structure of a metal, an insulator, and a semiconductor and is sometimes referred to as a MIS (Metal-Insulator-Semiconductor) structure or referred to as a diode-connected structure mainly formed of the MIS structure.

The above different layer is not necessarily formed between the oxide 530b and the conductor 542a and the conductor 542b; for example, the different layer may be formed between the oxide 530c and the conductor 542a and the conductor 542b, or between the oxide 530b and the conductor 542a and the conductor 542b, and between the oxide 530c and the conductor 542a and the conductor 542b.

The metal oxide functioning as the channel formation region in the oxide 530 has a band gap of more than or equal to 2 eV, preferably more than or equal to 2.5 eV. With the use of a metal oxide having such a wide band gap, the off-state current of the transistor can be reduced.

When the oxide 530 includes the oxide 530a under the oxide 530b, it is possible to inhibit diffusion of impurities into the oxide 530b from the components formed below the oxide 530a. Moreover, including the oxide 530c over the oxide 530b makes it possible to inhibit diffusion of impurities into the oxide 530b from the components formed above the oxide 530c.

Note that the oxide 530 preferably has a stacked-layer structure of a plurality of oxide layers that differ in the atomic ratio of metal atoms. Specifically, the atomic ratio of the element M to the constituent elements in the metal oxide used for the oxide 530a is preferably higher than the atomic ratio of the element M to the constituent elements in the metal oxide used for the oxide 530b. In addition, the atomic ratio of the element M to In in the metal oxide used for the oxide 530a is preferably higher than the atomic ratio of the element M to In in the metal oxide used for the oxide 530b. Furthermore, the atomic ratio of In to the element M in the metal oxide used for the oxide 530b is preferably higher than the atomic ratio of In to the element M in the metal oxide used for the oxide 530a. Moreover, a metal oxide that can be used as the oxide 530a or the oxide 530b can be used as the oxide 530c.

Specifically, as the oxide 530a, a metal oxide in which an atomic ratio of In to Ga and Zn is In:Ga:Zn=1:3:4 or 1:1:0.5 is used. In addition, as the oxide 530b, a metal oxide in which an atomic ratio of In to Ga and Zn is In:Ga:Zn=4:2:3 or 1:1:1 is used. In addition, as the oxide 530c, a metal oxide in which an atomic ratio of In to Ga and Zn is In:Ga:Zn=1:3:4 or an atomic ratio of Ga to Zn is Ga:Zn=2:1 or Ga:Zn=2:5 is used. Specific examples of the case where the oxide 530c has a stacked-layer structure include a stacked-layer structure of a layer in which an atomic ratio of In to Ga and Zn is In:Ga:Zn=4:2:3 and a layer with In:Ga:Zn=1:3:4; a stacked-layer structure of a layer in which an atomic ratio of Ga to Zn is Ga:Zn=2:1 and a layer in which an atomic ratio of In to Ga and Zn is In:Ga:Zn=4:2:3; a stacked-layer structure of a layer in which an atomic ratio of Ga to Zn is Ga:Zn=2:5 and a layer in which an atomic ratio of In to Ga and Zn is In:Ga:Zn=4:2:3; and a stacked-layer structure of gallium oxide and a layer in which an atomic ratio of In to Ga and Zn is In:Ga:Zn=4:2:3.

For example, in the case where the atomic ratio of In to the element M in the metal oxide used as the oxide 530a is lower than the atomic ratio of In to the element M in the metal oxide used as the oxide 530b, an In—Ga—Zn oxide having a composition with an atomic ratio of In:Ga:Zn=5:1:6 or a neighborhood thereof, In:Ga:Zn=5:1:3 or a neighborhood thereof, In:Ga:Zn=10:1:3 or a neighborhood thereof, or the like can be used as the oxide 530b.

As the oxide 530b, it is also possible to use a metal oxide having a composition of In:Zn=2:1, a composition of In:Zn=5:1, a composition of In:Zn=10:1, or a composition in the neighborhood of any one of these compositions, other than the above-described compositions.

These oxide 530a, the oxide 530b, and the oxide 530c are preferably combined to satisfy the above relationship of the atomic ratios. For example, it is preferable that the oxide 530a and the oxide 530c each be a metal oxide having a composition of In:Ga:Zn=1:3:4 or a composition in the neighborhood thereof and the oxide 530b be a metal oxide having a composition of In:Ga:Zn=4:2:3 to 4:2:4.1 or a composition in the neighborhood thereof. Note that the above composition represents the atomic ratio of an oxide formed over a base or the atomic ratio of a sputtering target. Moreover, it is suitable that the proportion of In is increased in the composition of the oxide 530b because the transistor can have a higher on-state current, higher field effect mobility, or the like.

In addition, the energy of the conduction band minimum of each of the oxide 530a and the oxide 530c is preferably higher than the energy of the conduction band minimum of the oxide 530b. In other words, the electron affinity of each of the oxide 530a and the oxide 530c is preferably smaller than the electron affinity of the oxide 530b.

Here, the energy level of the conduction band minimum gradually changes at junction portions of the oxide 530a, the oxide 530b, and the oxide 530c. In other words, the energy level of the conduction band minimum at the junction portions of the oxide 530a, the oxide 530b, and the oxide 530c continuously changes or is continuously connected. To change the energy level gradually, the densities of defect states in mixed layers formed at an interface between the oxide 530a and the oxide 530b and an interface between the oxide 530b and the oxide 530c is preferably made low.

Specifically, when the oxide 530a and the oxide 530b or the oxide 530b and the oxide 530c contain a common element (as a main component) in addition to oxygen, a mixed layer with a low density of defect states can be formed. For example, in the case where the oxide 530b is an In—Ga—Zn oxide, an In—Ga—Zn oxide, a Ga—Zn oxide, gallium oxide, or the like is preferably used as the oxide 530a and the oxide 530c.

At this time, the oxide 530b serves as a main carrier path. When the oxide 530a and the oxide 530c have the above structures, the densities of defect states at the interface between the oxide 530a and the oxide 530b and the interface between the oxide 530b and the oxide 530c can be made low. Thus, the influence of interface scattering on carrier conduction is small, and the transistor 500 can have a high on-state current.

The conductor 542a and the conductor 542b functioning as the source electrode and the drain electrode are provided over the oxide 530b. For the conductor 542a and conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing the above metal element as its component; an alloy containing any of the above metal elements in combination; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. Furthermore, a metal nitride film of tantalum nitride or the like is preferable because it has a barrier property against hydrogen or oxygen.

In addition, although the conductor 542a and the conductor 542b each having a single-layer structure are illustrated in FIG. 30A and FIG. 30B, a stacked-layer structure of two or more layers may be employed. For example, it is preferable to stack a tantalum nitride film and a tungsten film. Alternatively, a titanium film and an aluminum film may be stacked. Alternatively, a two-layer structure where an aluminum film is stacked over a tungsten film, a two-layer structure where a copper film is stacked over a copper-magnesium-aluminum alloy film, a two-layer structure where a copper film is stacked over a titanium film, or a two-layer structure where a copper film is stacked over a tungsten film may be employed.

Other examples include a three-layer structure where a titanium film or a titanium nitride film is formed, an aluminum film or a copper film is stacked over the titanium film or the titanium nitride film, and a titanium film or a titanium nitride film is formed over the aluminum film or the copper film; and a three-layer structure where a molybdenum film or a molybdenum nitride film is formed, an aluminum film or a copper film is stacked over the molybdenum film or the molybdenum nitride film, and a molybdenum film or a molybdenum nitride film is formed over the aluminum film or the copper film. Note that a transparent conductive material containing indium oxide, tin oxide, or zinc oxide may be used.

As illustrated in FIG. 30A, a region 543a and a region 543b are sometimes formed as low-resistance regions in the oxide 530 at and around the interface with the conductor 542a (the conductor 542b). In this case, the region 543a functions as one of a source region and a drain region, and the region 543b functions as the other of the source region and the drain region. Furthermore, the channel formation region is formed in a region between the region 543a and the region 543b.

When the conductor 542a (the conductor 542b) is provided to be in contact with the oxide 530, the oxygen concentration in the region 543a (the region 543b) sometimes decreases. In addition, a metal compound layer that contains the metal contained in the conductor 542a (the conductor 542b) and the component of the oxide 530 is sometimes formed in the region 543a (the region 543b). In such a case, the carrier density of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. At this time, the insulator 544 may be provided to cover a side surface of the oxide 530 and to be in contact with the insulator 524.

A metal oxide containing one kind or two or more kinds selected from hafnium, aluminum, gallium, yttrium, zirconium, tungsten, titanium, tantalum, nickel, germanium, neodymium, lanthanum, magnesium, and the like can be used as the insulator 544. Alternatively, silicon nitride oxide, silicon nitride, or the like can be used as the insulator 544.

It is particularly preferable to use an insulator containing an oxide of one or both of aluminum and hafnium, such as aluminum oxide, hafnium oxide, or an oxide containing aluminum and hafnium (hafnium aluminate), as the insulator 544. In particular, hafnium aluminate has higher heat resistance than a hafnium oxide film. Therefore, hafnium aluminate is preferable because it is less likely to be crystallized by heat treatment in a later step. Note that the insulator 544 is not an essential component when the conductor 542a and the conductor 542b are oxidation-resistant materials or do not significantly lose their conductivity even after absorbing oxygen. Design is appropriately set in consideration of required transistor characteristics.

When the insulator 544 is included, impurities such as water and hydrogen contained in the insulator 580 can be inhibited from diffusing into the oxide 530b through the oxide 530c and the insulator 550. Furthermore, oxidation of the conductor 560 due to excess oxygen contained in the insulator 580 can be inhibited.

The insulator 550 functions as a first gate insulating film. The insulator 550 is preferably placed in contact with the inner side (the top surface and the side surface) of the oxide 530c. Like the insulator 524, the insulator 550 is preferably formed using an insulator that contains excess oxygen and releases oxygen by heating.

Specifically, silicon oxide containing excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable.

When an insulator from which oxygen is released by heating is provided as the insulator 550 in contact with the top surface of the oxide 530c, oxygen can be effectively supplied from the insulator 550 to the channel-formation region of the oxide 530b through the oxide 530c. Furthermore, as in the insulator 524, the concentration of impurities such as water or hydrogen in the insulator 550 is preferably lowered. The thickness of the insulator 550 is preferably greater than or equal to 1 nm and less than or equal to 20 nm.

To efficiently supply excess oxygen contained in the insulator 550 to the oxide 530, a metal oxide may be provided between the insulator 550 and the conductor 560. The metal oxide preferably inhibits diffusion of oxygen from the insulator 550 into the conductor 560. Providing the metal oxide that inhibits diffusion of oxygen inhibits diffusion of excess oxygen from the insulator 550 into the conductor 560. That is, reduction in the amount of excess oxygen supplied to the oxide 530 can be inhibited. Moreover, oxidation of the conductor 560 due to excess oxygen can be inhibited. For the metal oxide, a material that can be used for the insulator 544 is used.

Note that the insulator 550 may have a stacked-layer structure like the second gate insulating film. As miniaturization and high integration of a transistor progress, a problem such as leakage current might arise because of a thinner gate insulating film; for that reason, when the insulator functioning as the gate insulating film has a stacked-layer structure of a high-k material and a thermally stable material, a gate potential during transistor operation can be reduced while the physical thickness is kept. Furthermore, the stacked-layer structure can be thermally stable and have a high dielectric constant.

Although the conductor 560 functioning as the first gate electrode has a two-layer structure in FIG. 30A and FIG. 30B, the conductor 560 may have a single-layer structure or a stacked-layer structure of three or more layers.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, it is preferable to use a conductive material having a function of inhibiting diffusion of oxygen (e.g., at least one of an oxygen atom and an oxygen molecule). When the conductor 560a has a function of inhibiting diffusion of oxygen, it is possible to inhibit a reduction in conductivity of the conductor 560b due to oxidation caused by oxygen contained in the insulator 550. As a conductive material having a function of inhibiting diffusion of oxygen, for example, tantalum, tantalum nitride, ruthenium, ruthenium oxide, or the like is preferably used. For the conductor 560a, the oxide semiconductor that can be used for the oxide 530 can be used. In that case, when the conductor 560b is deposited using a sputtering method, the conductor 560a can have a reduced value of electrical resistance to be a conductor. Such a conductor can be referred to as an OC (Oxide Conductor) electrode.

In addition, a conductive material containing tungsten, copper, or aluminum as its main component is preferably used for the conductor 560b. Furthermore, the conductor 560b also functions as a wiring and thus a conductor having high conductivity is preferably used for the conductor 560b. For example, a conductive material containing tungsten, copper, or aluminum as its main component can be used. Moreover, the conductor 560b may have a stacked-layer structure, for example, a stacked-layer structure of the above conductive material and titanium or titanium nitride.

The insulator 580 is provided over the conductor 542a and the conductor 542b with the insulator 544 therebetween. The insulator 580 preferably includes an excess-oxygen region. For example, the insulator 580 preferably contains silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, resin, or the like. In particular, silicon oxide and silicon oxynitride are preferable because they are thermally stable. In particular, silicon oxide and porous silicon oxide are preferable because an excess-oxygen region can be easily formed in a later step.

The insulator 580 preferably includes an excess-oxygen region. When the insulator 580 from which oxygen is released by heating is provided in contact with the oxide 530c, oxygen in the insulator 580 can be efficiently supplied to the oxide 530 through the oxide 530c. Note that the concentration of impurities such as water or hydrogen in the insulator 580 is preferably reduced.

The opening of the insulator 580 is formed to overlap with the region between the conductor 542a and the conductor 542b. Accordingly, the conductor 560 is formed to be embedded in the opening of the insulator 580 and the region between the conductor 542a and the conductor 542b.

The gate length needs to be short for miniaturization of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening of the insulator 580; thus, even when the conductor 560 has a shape with a high aspect ratio, the conductor 560 can be formed without collapsing during the process.

The insulator 574 is preferably provided in contact with a top surface of the insulator 580, atop surface of the conductor 560, and a top surface of the insulator 550. When the insulator 574 is formed by a sputtering method, excess-oxygen regions can be provided in the insulator 550 and the insulator 580. Accordingly, oxygen can be supplied from the excess-oxygen regions to the oxide 530.

For example, a metal oxide containing one kind or two or more kinds selected from hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness of greater than or equal to 0.5 nm and less than or equal to 3.0 nm can inhibit diffusion of hydrogen and nitrogen. Accordingly, aluminum oxide deposited by a sputtering method serves as an oxygen supply source and can also have a function of a barrier film against impurities such as hydrogen.

In addition, an insulator 581 functioning as an interlayer film is preferably provided over the insulator 574. As in the insulator 524 or the like, the concentration of impurities such as water or hydrogen in the insulator 581 is preferably reduced.

Furthermore, a conductor 540a and a conductor 540b are placed in openings formed in the insulator 581, the insulator 574, the insulator 580, and the insulator 544. The conductor 540a and the conductor 540b are provided to face each other with the conductor 560 interposed therebetween. The structures of the conductor 540a and the conductor 540b are similar to a structure of a conductor 546 and a conductor 548 that are described later.

An insulator 582 is provided over the insulator 581. A substance having a barrier property against oxygen or hydrogen is preferably used for the insulator 582. Therefore, a material similar to that for the insulator 514 can be used for the insulator 582. For the insulator 582, a metal oxide such as aluminum oxide, hafnium oxide, or tantalum oxide is preferably used, for example.

In particular, aluminum oxide has an excellent blocking effect that prevents the passage of both oxygen and impurities such as hydrogen and moisture, which are factors of a change in electrical characteristics of the transistor. Accordingly, aluminum oxide can prevent mixing of impurities such as hydrogen and moisture into the transistor 500 in a manufacturing process and after manufacturing of the transistor. In addition, release of oxygen from the oxide included in the transistor 500 can be inhibited. Therefore, aluminum oxide is suitably used for the protective film of the transistor 500.

In addition, an insulator 586 is provided over the insulator 582. For the insulator 586, a material similar to that for the insulator 320 can be used. Furthermore, when a material with a comparatively low permittivity is used for these insulators, parasitic capacitance generated between wirings can be reduced. A silicon oxide film, a silicon oxynitride film, or the like can be used for the insulator 586, for example.

Furthermore, the conductor 546, the conductor 548, and the like are embedded in the insulator 520, the insulator 522, the insulator 524, the insulator 544, the insulator 580, the insulator 574, the insulator 581, the insulator 582, and the insulator 586.

The conductor 546 and the conductor 548 have functions of plugs or wirings that are connected to the capacitor 600, the transistor 500, or the transistor 300. The conductor 546 and the conductor 548 can be provided using materials similar to those for the conductor 328 and the conductor 330.

Note that after the transistor 500 is formed, an opening may be formed to surround the transistor 500 and an insulator having a high barrier property against hydrogen or water may be formed to cover the opening. Surrounding the transistor 500 with the insulator having a high barrier property can prevent entry of moisture and hydrogen from the outside. Alternatively, a plurality of transistors 500 may be collectively surrounded by the insulator having a high barrier property against hydrogen or water. In the case where an opening is formed to surround the transistor 500, for example, formation of an opening reaching the insulator 514 or the insulator 522 and the formation of the insulator having a high barrier property in contact with the insulator 514 or the insulator 522 are suitable because these formation steps can also serve as some of the manufacturing steps of the transistor 500. For the insulator having a high barrier property against hydrogen or water, a material similar to that for the insulator 522 can be used, for example.

Next, the capacitor 600 is provided above the transistor 500. The capacitor 600 includes a conductor 610, a conductor 620, and an insulator 630.

In addition, a conductor 612 may be provided over the conductor 546 and the conductor 548. The conductor 612 has a function of a plug or a wiring that is connected to the transistor 500. The conductor 610 has a function of an electrode of the capacitor 600. Note that the conductor 612 and the conductor 610 can be formed at the same time.

For the conductor 612 and the conductor 610, a metal film containing an element selected from molybdenum, titanium, tantalum, tungsten, aluminum, copper, chromium, neodymium, and scandium; a metal nitride film containing the above element as its component (a tantalum nitride film, a titanium nitride film, a molybdenum nitride film, or a tungsten nitride film); or the like can be used. Alternatively, it is possible to use a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

The conductor 612 and the conductor 610 each have a single-layer structure in FIG. 28; however, the structure is not limited thereto, and a stacked-layer structure of two or more layers may be employed. For example, between a conductor having a barrier property and a conductor having high conductivity, a conductor that is highly adhesive to the conductor having a barrier property and the conductor having high conductivity may be formed.

The conductor 620 is provided to overlap with the conductor 610 with the insulator 630 therebetween. For the conductor 620, a conductive material such as a metal material, an alloy material, or a metal oxide material can be used. It is preferable to use a high-melting-point material that has both heat resistance and conductivity, such as tungsten or molybdenum, and it is particularly preferable to use tungsten. In addition, in the case where the conductor 620 is formed concurrently with another component such as a conductor, Cu (copper), Al (aluminum), or the like, which is a low-resistance metal material, is used.

An insulator 650 is provided over the conductor 620 and the insulator 630. The insulator 650 can be provided using a material similar to that for the insulator 320. The insulator 650 may function as a planarization film that covers an uneven shape thereunder.

With the use of this structure, a change in electrical characteristics can be inhibited and reliability can be improved in a semiconductor device using a transistor including an oxide semiconductor. Alternatively, a semiconductor device using a transistor including an oxide semiconductor can be miniaturized or highly integrated.

Next, other structure examples of the OS transistor illustrated in FIG. 28 and FIG. 29 are described.

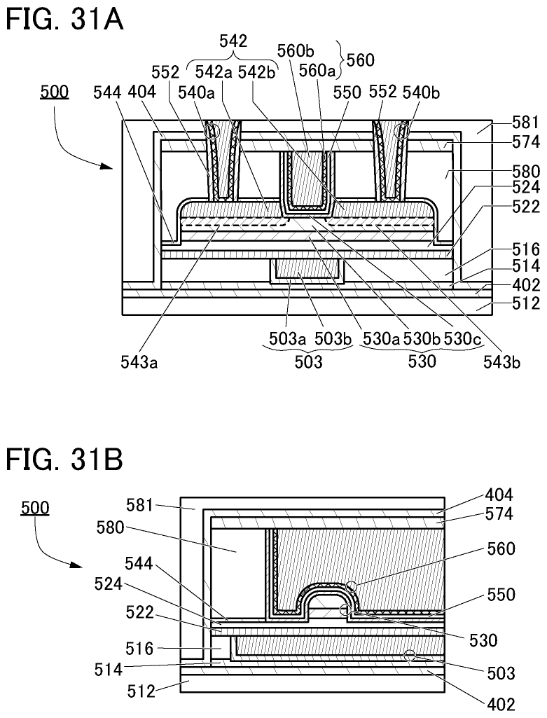

FIG. 31A and FIG. 31B illustrate a modification example of the transistor 500 illustrated in FIG. 30A and FIG. 30B. FIG. 31A is a cross-sectional diagram of the transistor 500 in the channel length direction and FIG. 31B is a cross-sectional diagram of the transistor 500 in the channel width direction. Note that the structure illustrated in FIG. 31A and FIG. 31B can also be employed for other transistors, such as the transistor 300, included in the semiconductor device of one embodiment of the present invention.

The transistor 500 illustrated in FIG. 31A and FIG. 31B is different from the transistor 500 illustrated in FIG. 30A and FIG. 30B in including an insulator 402 and an insulator 404. Furthermore, the transistor 500 illustrated in FIG. 31A and FIG. 31B is different from the transistor 500 having the structure illustrated in FIG. 30A and FIG. 30B in that an insulator 552 is provided in contact with a side surface of the conductor 540a and a side surface of the conductor 540b. Moreover, the transistor 500 illustrated in FIG. 31A and FIG. 31B is different from the transistor 500 having the structure illustrated in FIG. 30A and FIG. 30B in not including the insulator 520.

In the transistor 500 having the structure illustrated in FIG. 31A and FIG. 31B, the insulator 402 is provided over the insulator 512. In addition, the insulator 404 is provided over the insulator 574 and the insulator 402.

In the transistor 500 having the structure illustrated in FIG. 31A and FIG. 31B, the insulator 514, the insulator 516, the insulator 522, the insulator 524, the insulator 544, the insulator 580, and the insulator 574 are provided and covered with the insulator 404. That is, the insulator 404 is in contact with the top surface of the insulator 574, a side surface of the insulator 574, a side surface of the insulator 580, a side surface of the insulator 544, a side surface of the insulator 524, a side surface of the insulator 522, a side surface of the insulator 516, a side surface of the insulator 514, and the top surface of the insulator 402. Thus, the oxide 530 and the like are isolated from the outside by the insulator 404 and the insulator 402.

It is preferable that the insulator 402 and the insulator 404 have higher capability of inhibiting diffusion of hydrogen (e.g., at least one of a hydrogen atom, a hydrogen molecule, and the like) or a water molecule. For example, the insulator 402 and the insulator 404 are preferably formed using silicon nitride or silicon nitride oxide with a high hydrogen barrier property. This can inhibit diffusion of hydrogen or the like into the oxide 530, whereby degradation of the characteristics of the transistor 500 can be inhibited. Consequently, the reliability of the semiconductor device of one embodiment of the present invention can be increased.

The insulator 552 is provided in contact with the insulator 581, the insulator 404, the insulator 574, the insulator 580, and the insulator 544. The insulator 552 preferably has a function of inhibiting diffusion of hydrogen or water molecules. For example, for the insulator 552, an insulator such as silicon nitride, aluminum oxide, or silicon nitride oxide that is a material having a high hydrogen barrier property is preferably used. In particular, it is preferable to use silicon nitride for the insulator 552 because of its high hydrogen barrier property. By using a material having a high hydrogen barrier property for the insulator 552, diffusion of impurities such as water or hydrogen from the insulator 580 and the like into the oxide 530 through the conductor 540a and the conductor 540b can be inhibited. Furthermore, oxygen contained in the insulator 580 can be inhibited from being absorbed by the conductor 540a and the conductor 540b. As described above, the reliability of the semiconductor device of one embodiment of the present invention can be increased.

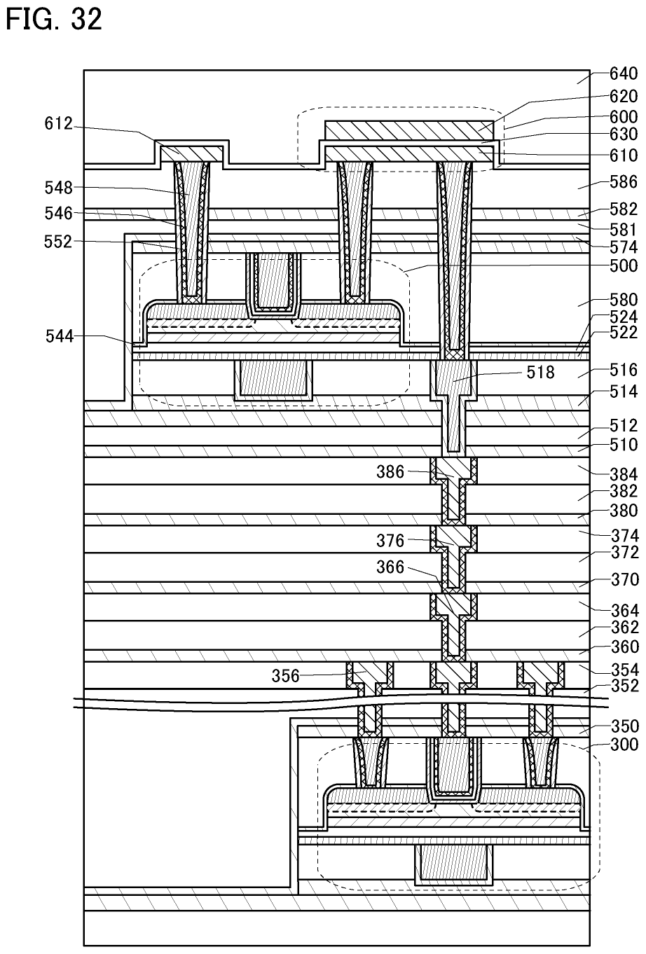

FIG. 32 is a cross-sectional view showing a structure example of the semiconductor device in the case where the transistor 500 and the transistor 300 have the structure illustrated in FIG. 31A and FIG. 31B. The insulator 552 is provided on a side surface of the conductor 546.

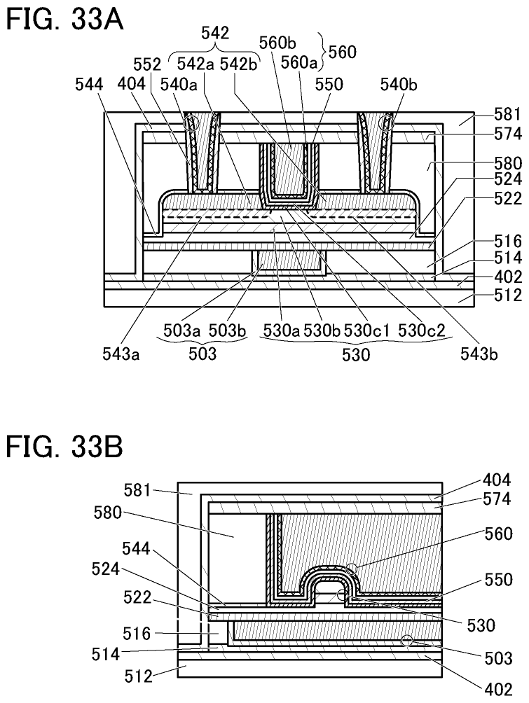

The transistor structure of the transistor 500 illustrated in FIG. 31A and FIG. 31B may be changed according to circumstances. As the modification example of the transistor 500 illustrated in FIG. 31A and FIG. 31B, a transistor illustrated in FIG. 33A and FIG. 33B can be employed, for example. FIG. 33A is a cross-sectional view of the transistor in the channel length direction, and FIG. 33B is a cross-sectional view of the transistor in the channel width direction. The transistor illustrated in FIG. 33A and FIG. 33B is different from the transistor illustrated in FIG. 31A and FIG. 31B in that the oxide 530c has a two-layer structure of an oxide 530c and an oxide 530c2.

The oxide 530cl is in contact with the top surface of the insulator 524, a side surface of the oxide 530a, the top surface and a side surface of the oxide 530b, side surfaces of the conductor 542a and the conductor 542b, a side surface of the insulator 544, and a side surface of the insulator 580. The oxide 530c2 is in contact with the insulator 550.

An In—Zn oxide can be used as the oxide 530c, for example. For the oxide 530c2, it is possible to use a material similar to the material that can be used for the oxide 530c when the oxide 530c has a single-layer structure. For example, as the oxide 530c2, a metal oxide with In:Ga:Zn=1:3:4 [atomic ratio], Ga:Zn=2:1 [atomic ratio], or Ga:Zn=2:5 [atomic ratio] can be used.

When the oxide 530c has a two-layer structure of the oxide 530c1 and the oxide 530c2, the on-state current of the transistor can be increased as compared with the case where the oxide 530c has a single-layer structure. Thus, the transistor can be used as a power MOS transistor, for example. Note that the oxide 530c included in the transistor illustrated in FIG. 30A and FIG. 30B can also have a two-layer structure of the oxide 530c1 and the oxide 530c2.

The transistor illustrated in FIG. 33A and FIG. 33B can be used as the transistor 300 illustrated in FIG. 28 or FIG. 29, for example. In addition, the transistor 300 can be used as a transistor or the like included in the semiconductor device described in the above embodiments, for example, the operation apparatus 100, the operation apparatus 100A, and the like described in the above embodiments, as described above. Note that the transistor illustrated in FIG. 33A and FIG. 33B can be used as a transistor, other than the transistor 300 and the transistor 500, included in the semiconductor device of one embodiment of the present invention.

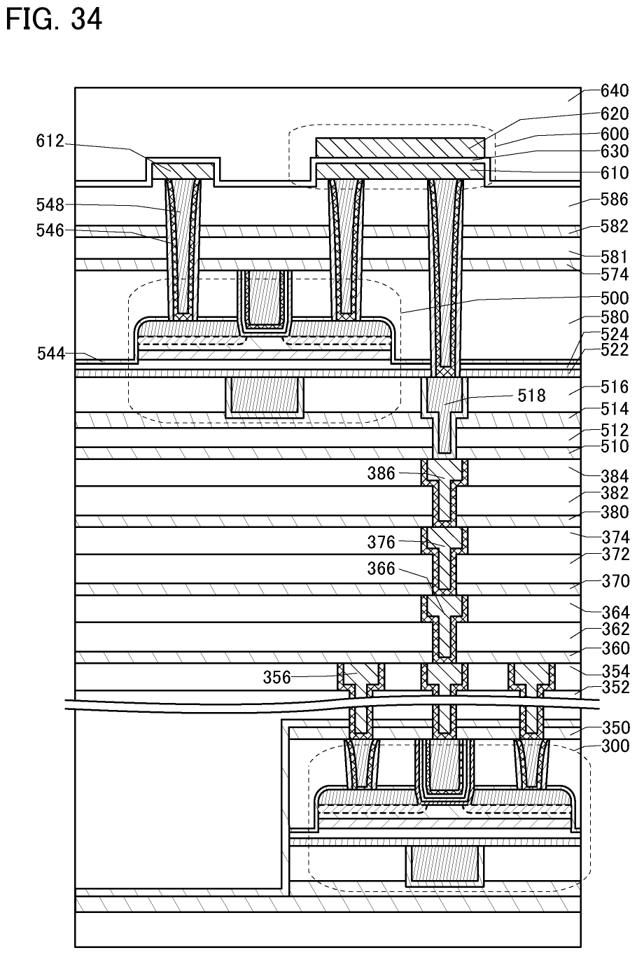

FIG. 34 is a cross-sectional view illustrating a structure example of a semiconductor device in which the transistor 500 has the structure of the transistor illustrated in FIG. 30A and the transistor 300 has the structure of the transistor illustrated in FIG. 33A. Note that a structure is employed in which the insulator 552 is provided on the side surface of the conductor 546 as in FIG. 32. As illustrated in FIG. 34, in the semiconductor device of one embodiment of the present invention, the transistor 300 and the transistor 500 can have different structures while both the transistor 300 and the transistor 500 can be OS transistors.

Next, a capacitor that can be used in the semiconductor devices in FIG. 28, FIG. 29, FIG. 32, and FIG. 34 is described.

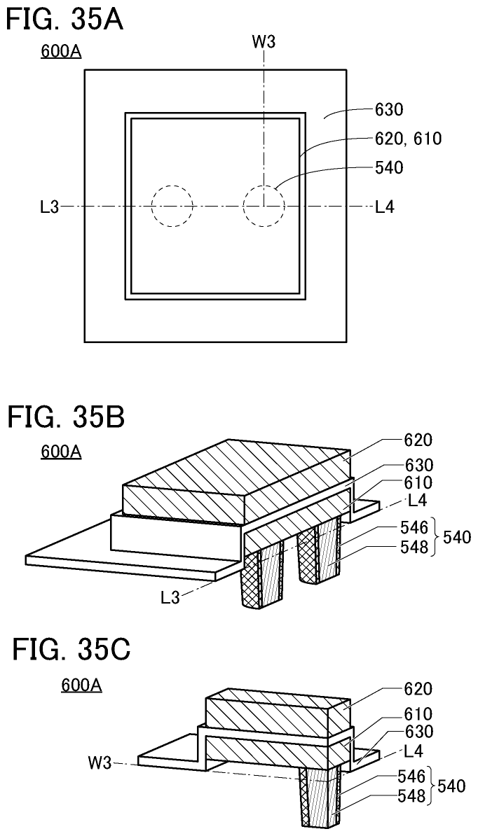

FIG. 35 illustrates a capacitor 600A as an example of the capacitor 600 that can be used in the semiconductor devices illustrated in FIG. 28, FIG. 29, FIG. 32, and FIG. 34. FIG. 35A is a top view of the capacitor 600A, FIG. 35B is a perspective view illustrating a cross section of the capacitor 600A along the dashed-dotted line L3-L4, and FIG. 35C is a perspective view illustrating a cross section of the capacitor 600A along the dashed-dotted line W3-L4.

The conductor 610 functions as one of a pair of electrodes of the capacitor 600A, and the conductor 620 functions as the other of the pair of electrodes of the capacitor 600A. The insulator 630 functions as a dielectric interposed between the pair of electrodes.

The insulator 630 can be provided to have a single-layer structure or a stacked-layer structure using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or zirconium oxide.

Furthermore, in this specification, hafnium oxynitride refers to a material that contains oxygen at a higher proportion than nitrogen, and hafnium nitride oxide refers to a material that contains nitrogen at a higher proportion than oxygen.

Alternatively, for the insulator 630, a stacked-layer structure using a material with high dielectric strength such as silicon oxynitride and a high permittivity (high-k) material may be used, for example. In the capacitor 600A having such a structure, a sufficient capacitance can be ensured owing to the high permittivity (high-k) insulator, and the dielectric strength can be increased owing to the insulator with high dielectric strength, so that the electrostatic breakdown of the capacitor 600A can be inhibited.

As the insulator of a high permittivity (high-k) material (a material having a high relative permittivity), gallium oxide, hafnium oxide, zirconium oxide, an oxide containing aluminum and hafnium, an oxynitride containing aluminum and hafnium, an oxide containing silicon and hafnium, an oxynitride containing silicon and hafnium, a nitride containing silicon and hafnium, or the like can be given.

Alternatively, for example, a single layer or stacked layers of an insulator containing a high-k material, such as aluminum oxide, hafnium oxide, tantalum oxide, zirconium oxide, lead zirconate titanate (PZT), strontium titanate (SrTiO₃), or (Ba,Sr)TiO₃ (BST), may be used as the insulator 630. In the case where the insulator 630 has stacked layers, a three-layer structure in which zirconium oxide, aluminum oxide, and zirconium oxide are formed in this order, or a four-layer structure in which zirconium oxide, aluminum oxide, zirconium oxide, and aluminum oxide are formed in this order can be employed, for example. For the insulator 630, a compound containing hafnium and zirconium may be employed, for example. As miniaturization and high integration of a semiconductor device progress, a problem such as leakage current from a transistor or a capacitor might arise because of a thinner dielectric used for a gate insulator and the capacitor. When a high-k material is used as an insulator functioning as the dielectric used for the gate insulator and the capacitor, a gate potential during the transistor operation can be reduced and the capacitance of the capacitor can be ensured while the physical thickness is kept.

A bottom portion of the conductor 610 in the capacitor 600 is electrically connected to the conductor 546 and the conductor 548. The conductor 546 and the conductor 548 function as plugs or wirings for connection to another circuit element. In FIG. 35A to FIG. 35C, the conductor 546 and the conductor 548 are collectively denoted as a conductor 540.

For clarification of the drawing, the insulator 586 in which the conductor 546 and the conductor 548 are embedded and the insulator 650 that covers the conductor 620 and the insulator 630 are omitted in FIG. 35.

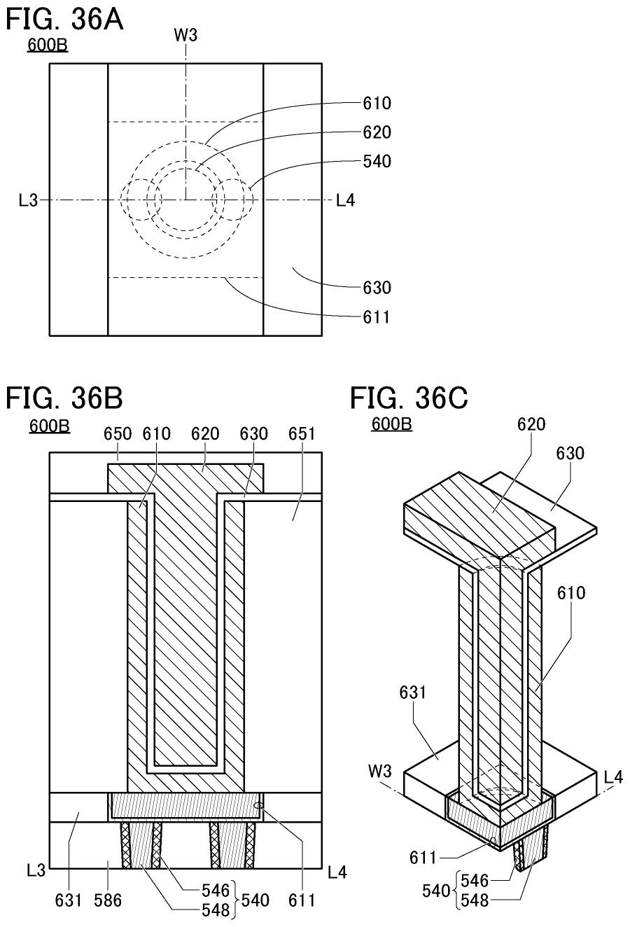

Although the capacitor 600 illustrated in FIG. 28, FIG. 29, FIG. 32, FIG. 34, FIG. 35A, FIG. 35B, and FIG. 35C is a planar capacitor, the shape of the capacitor is not limited thereto. For example, the capacitor 600 may be a cylindrical capacitor 600B illustrated in FIG. 36A to FIG. 36C.

FIG. 36A is a top view of the capacitor 600B, FIG. 36B is a cross-sectional view of the capacitor 600B along the dashed-dotted line L3-L4, and FIG. 36C is a perspective view illustrating a cross section of the capacitor 600B along the dashed-dotted line W3-L4.

In FIG. 36B, the capacitor 600B includes an insulator 631 over the insulator 586 in which the conductor 540 is embedded, an insulator 651 having an opening, the conductor 610 functioning as one of a pair of electrodes, and the conductor 620 functioning as the other of the pair of electrodes.

For clarification of the drawing, the insulator 586, the insulator 650, and the insulator 651 are omitted in FIG. 36C.

For the insulator 631, a material similar to that for the insulator 586 can be used, for example.

A conductor 611 is embedded in the insulator 631 to be electrically connected to the conductor 540. For the conductor 611, a material similar to those for the conductor 330 and the conductor 518 can be used, for example.

For the insulator 651, a material similar to that for the insulator 586 can be used, for example.

The insulator 651 has an opening portion as described above, and the opening portion overlaps with the conductor 611.

The conductor 610 is formed on the bottom portion and the side surface of the opening portion. In other words, a conductor 621 overlaps with the conductor 611 and is electrically connected to the conductor 611.

The conductor 610 is formed in such a manner that an opening portion is formed in the insulator 651 by an etching method or the like, and then the conductor 610 is formed by a sputtering method, an ALD method, or the like. After that, the conductor 610 formed over the insulator 651 can be removed by a CMP (Chemical Mechanical Polishing) method or the like while the conductor 610 formed in the opening portion is left.

The insulator 630 is positioned over the insulator 651 and the formation surface of the conductor 610. Note that the insulator 630 functions as a dielectric interposed between the pair of electrodes in the capacitor.

The conductor 620 is formed over the insulator 630 so as to fill the opening portion of the insulator 651.

The insulator 650 is formed to cover the insulator 630 and the conductor 620.

The capacitance value of the cylindrical capacitor 600B illustrated in FIG. 36 can be higher than that of the planar capacitor 600A.

Note that this embodiment can be combined with any of the other embodiments in this specification as appropriate.

### Embodiment 4

In this embodiment, a metal oxide (hereinafter also referred to as an oxide semiconductor) that can be used in an OS transistor described in the above embodiment will be described.

The metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

### <Classification of Crystal Structure>

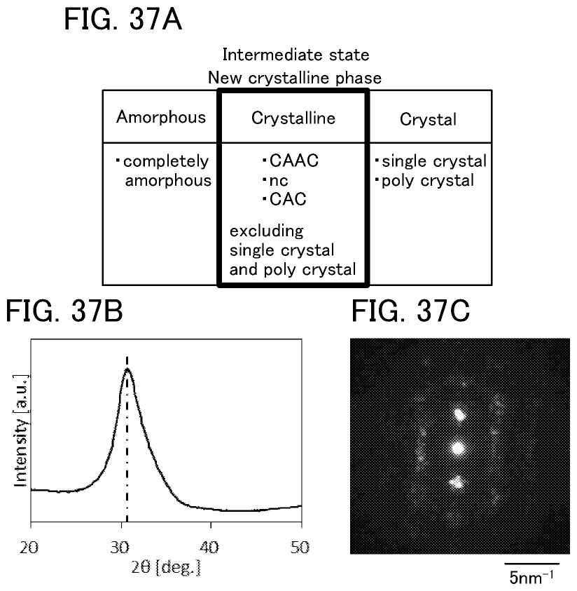

First, the classification of crystal structures of an oxide semiconductor will be described with reference to FIG. 37A. FIG. 37A is a diagram showing the classification of crystal structures of an oxide semiconductor, typically IGZO (a metal oxide containing In, Ga, and Zn).

As shown in FIG. 37A, an oxide semiconductor is roughly classified into “Amorphous”, “Crystalline”, and “Crystal”. The term “Amorphous” includes completely amorphous. “Crystalline” includes CAAC (c-axis-aligned crystalline), nc (nanocrystalline), and CAC (cloud-aligned composite) (excluding single crystal and poly crystal). Note that “Crystalline” excludes single crystal, poly crystal, and completely amorphous. “Crystal” includes single crystal and poly crystal.

Note that the structures in the thick frame in FIG. 37A are in an intermediate state between “Amorphous” and “Crystal”, and belong to a new crystalline phase. That is, these structures are completely different from “Amorphous,” which is energetically unstable, and “Crystal.”

Note that a crystal structure of a film or a substrate can be evaluated with an X-ray diffraction (XRD) spectrum. FIG. 37B shows an XRD spectrum, which is obtained by GIXD (Grazing-Incidence XRD) measurement, of a CAAC-IGZO film classified into “Crystalline”. Note that a GIXD method is also referred to as a thin film method or a Seemann-Bohlin method. The XRD spectrum that is shown in FIG. 37B and obtained by GIXD measurement is hereinafter simply referred to as an XRD spectrum. The CAAC-IGZO film in FIG. 37B has a composition in the vicinity of In:Ga:Zn=4:2:3 [atomic ratio]. The CAAC-IGZO film in FIG. 37B has a thickness of 500 nm.

As shown in FIG. 37B, a clear peak indicating crystallinity is detected in the XRD spectrum of the CAAC-IGZO film. Specifically, a peak indicating c-axis alignment is detected at 20 of around 31° in the XRD spectrum of the CAAC-IGZO film. As shown in FIG. 37B, the peak at 20 of around 31° is asymmetric with respect to the axis of the angle at which the peak intensity is detected.

A crystal structure of a film or a substrate can also be evaluated with a diffraction pattern obtained by a nanobeam electron diffraction (NBED) method (such a pattern is also referred to as a nanobeam electron diffraction pattern). FIG. 37C shows a diffraction pattern of the CAAC-IGZO film. FIG. 37C shows a diffraction pattern obtained by the NBED method in which an electron beam is incident in the direction parallel to the substrate. The CAAC-IGZO film in FIG. 37C has a composition in the vicinity of In:Ga:Zn=4:2:3 [atomic ratio]. In the nanobeam electron diffraction method, electron diffraction is performed with a probe diameter of 1 nm.

As shown in FIG. 37C, a plurality of spots indicating c-axis alignment are observed in the diffraction pattern of the CAAC-IGZO film.

### <<Structure of Oxide Semiconductor>>

Oxide semiconductors might be classified in a manner different from that in FIG. 37A when classified in terms of the crystal structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a stacked-layer structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure in which a clear grain boundary is observed is what is called polycrystal. It is highly probable that the grain boundary becomes a recombination center and captures carriers and thus decreases the on-state current and field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a grain boundary as compared with an In oxide.

The CAAC-OS is an oxide semiconductor with high crystallinity in which no clear grain boundary is observed. Thus, in the CAAC-OS, a reduction in electron mobility due to the grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., 1 nm or larger and 30 nm or smaller).

[a-Like OS]

The a-like OS is an oxide semiconductor having a structure between those of the nc-OS and the amorphous oxide semiconductor. The a-like OS includes a void or a low-density region. That is, the a-like OS has low crystallinity as compared with the nc-OS and the CAAC-OS. Moreover, the a-like OS has higher hydrogen concentration in the film than the nc-OS and the CAAC-OS.

### <<Composition of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Note that the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than that in the composition of the CAC-OS film. Moreover, the second region has [Ga] higher than that in the composition of the CAC-OS film. For example, the first region has higher [In] and lower [Ga] than the second region. Moreover, the second region has higher [Ga] and lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

For example, energy dispersive X-ray spectroscopy (EDX) is used to obtain EDX mapping, and according to the EDX mapping, the CAC-OS in the In—Ga—Zn oxide has a composition in which the region containing In as its main component (the first region) and the region containing Ga as its main component (the second region) are unevenly distributed and mixed.

In the case where the CAC-OS is used for a transistor, a switching function (on/off switching function) can be given to the CAC-OS owing to the complementary action of the conductivity derived from the first region and the insulating property derived from the second region. A CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor having a low carrier concentration is preferably used in a transistor. For example, the carrier concentration of an oxide semiconductor is lower than or equal to 1×10¹⁷ cm⁻³, preferably lower than or equal to 1×10¹⁵ cm³, further preferably lower than or equal to 1×10¹³ cm⁻³, still further preferably lower than or equal to 1×10¹¹ cm³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal is likely to have normally-on characteristics. Thus, the concentration of an alkali metal or an alkaline earth metal in the oxide semiconductor, which is obtained using SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

Note that this embodiment can be combined with any of the other embodiments in this specification as appropriate.

### Embodiment 5

In this embodiment, examples of a semiconductor wafer where the semiconductor device or the like described in the above embodiment is formed and electronic components incorporating the semiconductor device are described.

### <Semiconductor Wafer>

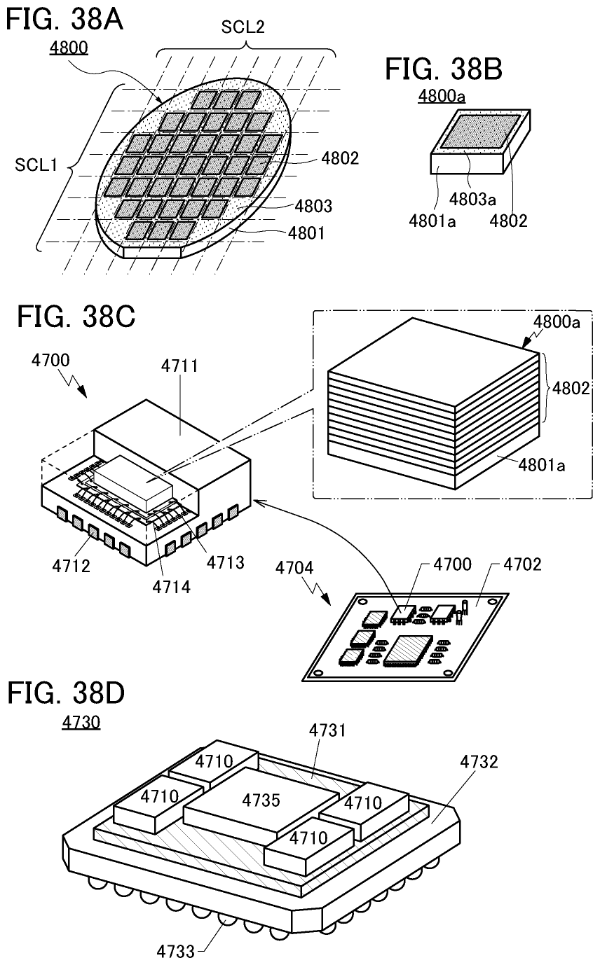

First, an example of a semiconductor wafer where a semiconductor device or the like is formed is described with reference to FIG. 38A.

A semiconductor wafer 4800 illustrated in FIG. 38A includes a wafer 4801 and a plurality of circuit portions 4802 provided on the top surface of the wafer 4801. A portion without the circuit portion 4802 on the top surface of the wafer 4801 is a spacing 4803 that is a region for dicing.

The semiconductor wafer 4800 can be fabricated by forming the plurality of circuit portions 4802 on the surface of the wafer 4801 by a pre-process. After that, a surface of the wafer 4801 opposite to the surface provided with the plurality of circuit portions 4802 may be ground to thin the wafer 4801. Through this step, warpage or the like of the wafer 4801 is reduced and the size of the component can be reduced.

A dicing step is performed as the next step. The dicing is performed along scribe lines SCL1 and scribe lines SCL2 (referred to as dicing lines or cutting lines in some cases) indicated with dashed-dotted lines. Note that to perform the dicing step easily, it is preferable that the spacing 4803 be provided so that the plurality of scribe lines SCL1 are parallel to each other, the plurality of scribe lines SCL2 are parallel to each other, and the scribe lines SCL1 are perpendicular to the scribe lines SCL2.

With the dicing step, a chip 4800a as illustrated in FIG. 38B can be cut out from the semiconductor wafer 4800. The chip 4800a includes a wafer 4801a, the circuit portion 4802, and a spacing 4803a. Note that it is preferable to make the spacing 4803a as small as possible. In this case, the width of the spacing 4803 between adjacent circuit portions 4802 is substantially the same as a cutting allowance of the scribe line SCL1 or a cutting allowance of the scribe line SCL2.

Note that the shape of the element substrate of one embodiment of the present invention is not limited to the shape of the semiconductor wafer 4800 illustrated in FIG. 38A. The element substrate may be a rectangular semiconductor wafer, for example. The shape of the element substrate can be changed as appropriate, depending on a manufacturing process of an element and an apparatus for manufacturing the element.

### <Electronic Component>

FIG. 38C is a perspective view of an electronic component 4700 and a substrate (a mounting board 4704) on which the electronic component 4700 is mounted. The electronic component 4700 illustrated in FIG. 38C includes the chip 4800a in a mold 4711. Note that the chip 4800a illustrated in FIG. 38C may have a structure in which the circuit portions 4802 are stacked. To illustrate the inside of the electronic component 4700, some portions are omitted in FIG. 38C. The electronic component 4700 includes a land 4712 outside the mold 4711. The land 4712 is electrically connected to an electrode pad 4713, and the electrode pad 4713 is electrically connected to the chip 4800a through a wire 4714. The electronic component 4700 is mounted on a printed circuit board 4702, for example. A plurality of such electronic components are combined and electrically connected to each other on the printed circuit board 4702, whereby the mounting board 4704 is completed.

FIG. 38D is a perspective view of an electronic component 4730. The electronic component 4730 is an example of a SiP (System in package) or an MCM (Multi Chip Module). In the electronic component 4730, an interposer 4731 is provided on a package substrate 4732 (a printed circuit board), and a semiconductor device 4735 and a plurality of semiconductor devices 4710 are provided on the interposer 4731.

The electronic component 4730 includes the semiconductor devices 4710. Examples of the semiconductor device 4710 include the semiconductor device described in the above embodiment and a high bandwidth memory (HBM). An integrated circuit (a semiconductor device) such as a CPU, a GPU, an FPGA, or a memory device can be used as the semiconductor device 4735.

As the package substrate 4732, a ceramic substrate, a plastic substrate, a glass epoxy substrate, or the like can be used. As the interposer 4731, a silicon interposer, a resin interposer, or the like can be used.

The interposer 4731 includes a plurality of wirings and has a function of electrically connecting a plurality of integrated circuits with different terminal pitches. The plurality of wirings have a single-layer structure or a layered structure. Moreover, the interposer 4731 has a function of electrically connecting an integrated circuit provided on the interposer 4731 to an electrode provided on the package substrate 4732. Accordingly, the interposer is sometimes referred to as a redistribution substrate or an intermediate substrate. A through electrode is provided in the interposer 4731 and the through electrode is used to electrically connect an integrated circuit and the package substrate 4732 in some cases. In the case of using a silicon interposer, a TSV (Through Silicon Via) can also be used as the through electrode.

A silicon interposer is preferably used as the interposer 4731. The silicon interposer can be manufactured at lower cost than an integrated circuit because it is not necessary to provide an active element. Moreover, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; hence, a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (a radiator plate) may be provided to overlap with the electronic component 4730. In the case of providing a heat sink, the heights of integrated circuits provided on the interposer 4731 are preferably equal to each other. For example, in the electronic component 4730 described in this embodiment, the heights of the semiconductor devices 4710 and the semiconductor device 4735 are preferably equal to each other.

To mount the electronic component 4730 on another substrate, an electrode 4733 may be provided on the bottom portion of the package substrate 4732. FIG. 38D illustrates an example in which the electrode 4733 is formed of a solder ball. Solder balls are provided in a matrix on the bottom portion of the package substrate 4732, whereby BGA (Ball Grid Array) mounting can be achieved. Alternatively, the electrode 4733 may be formed of a conductive pin. When conductive pins are provided in a matrix on the bottom portion of the package substrate 4732, PGA (Pin Grid Array) mounting can be achieved.

The electronic component 4730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

Note that this embodiment can be combined with any of the other embodiments in this specification as appropriate.

### Embodiment 6

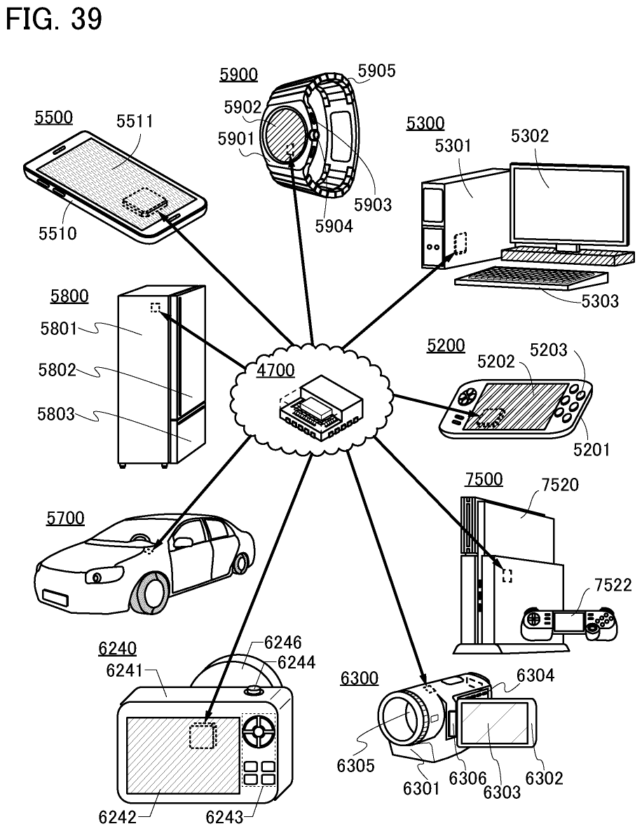

In this embodiment, examples of electronic devices each including the semiconductor device described in the above embodiment are described. FIG. 39 illustrates electronic devices each including the electronic component 4700 including the semiconductor device.

### [Mobile Phone]

An information terminal 5500 illustrated in FIG. 39 is a mobile phone (smartphone), which is a type of information terminal. The information terminal 5500 includes a housing 5510 and a display portion 5511, and as input interfaces, a touch panel is provided in the display portion 5511 and a button is provided in the housing 5510.

The information terminal 5500 can execute an application utilizing artificial intelligence with the use of the semiconductor device described in the above embodiment. Examples of the application utilizing artificial intelligence include an application for interpreting a conversation and displaying its content on the display portion 5511; an application for recognizing letters, diagrams, and the like input to the touch panel of the display portion 5511 by a user and displaying them on the display portion 5511; and an application for biometric authentication using fingerprints, voice prints, or the like.

### [Wearable Terminal]

FIG. 39 illustrates an information terminal 5900 as an example of a wearable terminal. The information terminal 5900 includes a housing 5901, a display portion 5902, an operation button 5903, an operator 5904, a band 5905, and the like.

The wearable terminal can execute an application utilizing artificial intelligence with the use of the semiconductor device described in the above embodiment, like the information terminal 5500. Examples of the application utilizing artificial intelligence include an application for managing the health condition of the user of the wearable terminal and a navigation system that selects the optimal route and navigates the user on the basis of the input of the destination.

### [Information Terminal]

FIG. 39 illustrates a desktop information terminal 5300. The desktop information terminal 5300 includes a main body 5301 of the information terminal, a display 5302, and a keyboard 5303.

The desktop information terminal 5300 can execute an application utilizing artificial intelligence with the use of the semiconductor device described in the above embodiment, like the information terminal 5500 described above. Examples of the application utilizing artificial intelligence include design-support software, text correction software, and software for automatic menu generation. Furthermore, with the use of the desktop information terminal 5300, novel artificial intelligence can be developed.

Note that although FIG. 39 illustrates the smartphone and the desktop information terminal as examples of the electronic device, one embodiment of the present invention can also be applied to information terminals other than a smartphone and a desktop information terminal. Examples of an information terminal other than a smartphone and a desktop information terminal include a PDA (Personal Digital Assistant), a laptop information terminal, and a workstation.

### [Household Appliance]

FIG. 39 illustrates an electric refrigerator-freezer 5800 as an example of a household appliance. The electric refrigerator-freezer 5800 includes a housing 5801, a refrigerator door 5802, a freezer door 5803, and the like.

When the semiconductor device described in the above embodiment is used for the electric refrigerator-freezer 5800, the electric refrigerator-freezer 5800 including artificial intelligence can be achieved. Utilizing the artificial intelligence enables the electric refrigerator-freezer 5800 to have a function of automatically making a menu based on foods stored in the electric refrigerator-freezer 5800, expiration dates of the foods, or the like, a function of automatically adjusting temperature to be appropriate for the foods stored in the electric refrigerator-freezer 5800, and the like.

Although the electric refrigerator-freezer is described as an electronic device in the example, other examples of the electronic device include a vacuum cleaner, a microwave oven, an electric oven, a rice cooker, a water heater, an IH (Induction Heating) cooker, a water server, a heating-cooling combination appliance such as an air conditioner, a washing machine, a drying machine, and an audio visual appliance.

### [Game Machines]

FIG. 39 illustrates a portable game machine 5200 as an example of a game machine. The portable game machine 5200 includes a housing 5201, a display portion 5202, a button 5203, and the like.

FIG. 39 illustrates a stationary game machine 7500 as another example of a game machine. The stationary game machine 7500 includes a main body 7520 and a controller 7522. The controller 7522 can be connected to the main body 7520 with or without a wire. Although not illustrated in FIG. 39, the controller 7522 can include a display portion that displays a game image, and an input interface besides a button, such as a touch panel, a stick, a rotating knob, and a sliding knob, for example. The shape of the controller 7522 is not limited to that in FIG. 39, and the shape of the controller 7522 may be changed variously in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include a camera, a depth sensor, a microphone, and the like so that the game player can play a game using a gesture and/or a voice instead of a controller.

Videos displayed on the game machine can be output with a display device such as a television device, a personal computer display, a game display, or a head-mounted display.

When the semiconductor device described in the above embodiment is used in the portable game machine 5200, the portable game machine 5200 with low power consumption can be achieved. Furthermore, heat generation from a circuit can be reduced owing to low power consumption; thus, the influence of heat generation on the circuit itself, the peripheral circuit, and the module can be reduced.

Furthermore, when the semiconductor device described in the above embodiment is used for the portable game machine 5200, the portable game machine 5200 including artificial intelligence can be achieved.

In general, the progress of a game, the actions and words of game characters, and expressions of a phenomenon and the like in the game are programed in the game; however, the use of artificial intelligence in the portable game machine 5200 enables expressions not limited by the game program. For example, it becomes possible to change expressions such as questions posed by the player, the progress of the game, time, and actions and words of game characters.

When a game requiring a plurality of players is played on the portable game machine 5200, the artificial intelligence can create a virtual game player; thus, the game can be played alone with the game player created by the artificial intelligence as an opponent.

Although FIG. 39 illustrates the portable game machine as an example of a game machine, the electronic device of one embodiment of the present invention is not limited thereto. Examples of the electronic device of one embodiment of the present invention include a home stationary game machine, an arcade game machine installed in entertainment facilities (e.g., a game center and an amusement park), and a throwing machine for batting practice installed in sports facilities.

### [Moving Vehicle]

The semiconductor device described in the above embodiment can be used for an automobile, which is a moving vehicle, and around the driver's seat in an automobile.

FIG. 39 illustrates an automobile 5700 as an example of a moving vehicle.

An instrument panel that can display a speedometer, a tachometer, a mileage, a fuel meter, a gearshift state, air-conditioning setting, and the like is provided around the driver's seat in the automobile 5700. In addition, a display device showing the above information may be provided around the driver's seat.

In particular, the display device can compensate for the view obstructed by the pillar or the like, the blind areas for the driver's seat, and the like by displaying a video taken by an imaging device (not illustrated) provided for the automobile 5700, which improves safety. That is, display of an image taken by an imaging device provided on the outside of the automobile 5700 can fill in blind areas and improve safety.

Since the semiconductor device described in the above embodiment can be used as the components of artificial intelligence, the computer can be used for an automatic driving system of the automobile 5700, for example. The computer can also be used for a system for navigation, risk prediction, or the like. The display device may display navigation information, risk prediction information, or the like.

Note that although an automobile is described above as an example of a moving vehicle, the moving vehicle is not limited to an automobile. Examples of moving objects include a train, a monorail train, a ship, and a flying object (a helicopter, an unmanned aircraft (a drone), an airplane, and a rocket), and these moving objects can include a system utilizing artificial intelligence when equipped with the computer of one embodiment of the present invention.

### [Camera]

The semiconductor device described in the above embodiment can be used in a camera.

FIG. 39 illustrates a digital camera 6240 as an example of an imaging device. The digital camera 6240 includes a housing 6241, a display portion 6242, operation buttons 6243, a shutter button 6244, and the like, and an attachable lens 6246 is attached to the digital camera 6240. Here, the lens 6246 of the digital camera 6240 is detachable from the housing 6241 for replacement; alternatively, the lens 6246 may be incorporated into the housing 6241. A stroboscope, a viewfinder, or the like may be additionally attached to the digital camera 6240.

When the semiconductor device described in the above embodiment is used for the digital camera 6240, the digital camera 6240 with low power consumption can be achieved. Furthermore, heat generation from a circuit can be reduced owing to low power consumption; thus, the influence of heat generation on the circuit itself, the peripheral circuit, and the module can be reduced.

Furthermore, when the semiconductor device described in the above embodiment is used for the digital camera 6240, the digital camera 6240 including artificial intelligence can be achieved. Utilizing the artificial intelligence enables the digital camera 6240 to have a function of automatically recognizing a subject such as a face or an object, a function of adjusting a focus on the subject, a function of automatically using a flash in accordance with environments, a function of toning a taken image, and the like.

### [Video Camera]

The semiconductor device described in the above embodiment can be used in a video camera.

FIG. 39 illustrates a video camera 6300 as an example of an imaging device. The video camera 6300 includes a first housing 6301, a second housing 6302, a display portion 6303, operation keys 6304, a lens 6305, a joint 6306, and the like. The operation keys 6304 and the lens 6305 are provided in the first housing 6301, and the display portion 6303 is provided in the second housing 6302. The first housing 6301 and the second housing 6302 are connected to each other with the joint 6306, and the angle between the first housing 6301 and the second housing 6302 can be changed with the joint 6306. Images displayed on the display portion 6303 may be changed in accordance with the angle at the joint 6306 between the first housing 6301 and the second housing 6302.

When images taken by the video camera 6300 are recorded, the images need to be encoded in accordance with a data recording format. With the use of artificial intelligence, the video camera 6300 can perform the pattern recognition by artificial intelligence in encoding of the images. The pattern recognition is used to calculate a difference in the human, the animal, the object, and the like between continuously taken image data, so that the data can be compressed.

### [Expansion Device for Personal Computer]

The semiconductor device described in the above embodiment can be used in a calculator such as a PC (Personal Computer) and an extension device for an information terminal.

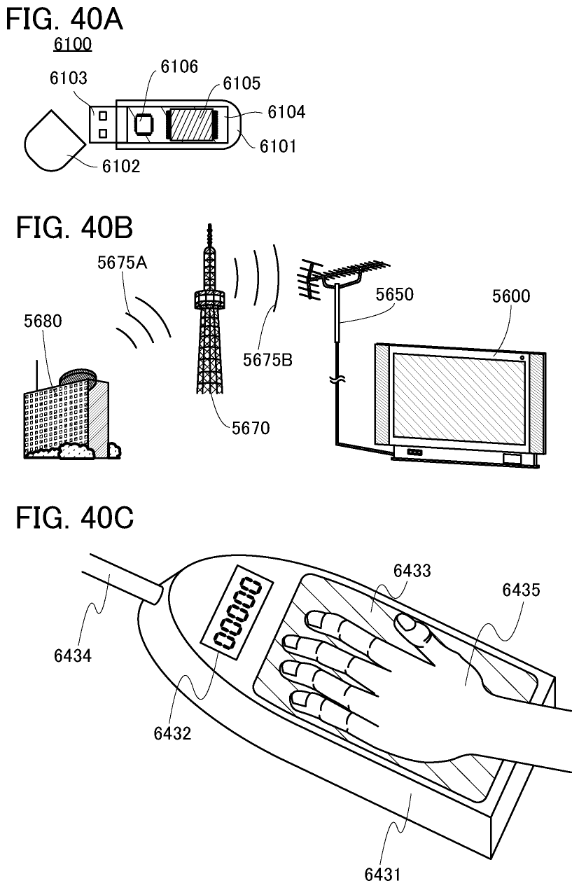

FIG. 40A illustrates, as an example of the external device, a portable external device 6100 that includes a chip capable of arithmetic processing and is externally attached to a PC. The external device 6100 can perform arithmetic processing using the chip when connected to a PC with a USB (Universal Serial Bus), for example. FIG. 40A illustrates the portable external device 6100; however, the external device of one embodiment of the present invention is not limited thereto and may be a relatively large external device including a cooling fan or the like, for example.

The expansion device 6100 includes a housing 6101, a cap 6102, a USB connector 6103, and a substrate 6104. The substrate 6104 is held in the housing 6101. The substrate 6104 is provided with a circuit for driving the semiconductor device or the like described in the above embodiment. For example, a chip 6105 (e.g., the semiconductor device described in the above embodiment, the electronic component 4700, or a memory chip) and a controller chip 6106 are attached to the substrate 6104. The USB connector 6103 functions as an interface for connection to an external device.

The use of the external device 6100 for the PC and the like can increase the arithmetic processing properties of the PC. Thus, a PC with insufficient processing capability can perform arithmetic operation of artificial intelligence, moving image processing, and the like.

### [Broadcasting System]

The semiconductor device described in the above embodiment can be used for a broadcasting system. FIG. 40B schematically illustrates data transmission in a broadcasting system. Specifically, FIG. 40B illustrates a path in which a radio wave (a broadcasting signal) transmitted from a broadcast station 5680 reaches a television receiver (TV) 5600 of each household. The TV 5600 includes a receiving device (not illustrated), and the broadcast signal received by an antenna 5650 is transmitted to the TV 5600 through the receiving device.

Although a UHF (Ultra High Frequency) antenna is illustrated as the antenna 5650 in FIG. 40B, a BS/110° C. S antenna, a CS antenna, or the like can also be used as the antenna 5650.

A radio wave 5675A and a radio wave 5675B are broadcast signals for terrestrial broadcasting; a radio wave tower 5670 amplifies the received radio wave 5675A and transmits the radio wave 5675B. Each household can view terrestrial TV broadcasting on the TV 5600 by receiving the radio wave 5675B with the antenna 5650. Note that the broadcasting system is not limited to the terrestrial broadcasting illustrated in FIG. 40B and may be satellite broadcasting using an artificial satellite, data broadcasting using an optical line, or the like.

The above-described broadcasting system may be a broadcasting system that utilizes artificial intelligence by including the semiconductor device described in the above embodiment. When the broadcast data is transmitted from the broadcast station 5680 to the TV 5600 of each household, the broadcast data is compressed with an encoder. When the antenna 5650 receives the compressed broadcast data, the compressed broadcast data is decompressed with a decoder of the receiving device in the TV 5600. Utilizing the artificial intelligence enables, for example, recognition of a display pattern included in a displayed image in motion compensation prediction, which is one of the compressing methods for the encoder. In-frame prediction utilizing artificial intelligence, for example, can also be performed. As another example, when the broadcast data with low resolution is received and the broadcast data is displayed on the TV 5600 with high resolution, image interpolation such as upconversion can be performed in the broadcast data decompression by the decoder.

The above-described broadcasting system utilizing artificial intelligence is suitable for ultra-high definition television (UHIDTV: 4K and 8K) broadcasting, which needs a large amount of broadcast data.

As the application of artificial intelligence in the TV 5600, a recording device with artificial intelligence may be provided in the TV 5600, for example. With such a structure, the artificial intelligence can learn the user's preference, so that TV programs that suit the user's preference can be recorded automatically in the recording device.

### [Authentication System]

The semiconductor device described in the above embodiment can be used for an authentication system.

FIG. 40C illustrates a palm print authentication device including a housing 6431, a display portion 6432, a palm print reading portion 6433, and a wiring 6434.

In FIG. 40C, a palm print of a hand 6435 is obtained using the palm print authentication device. The obtained palm print is subjected to the pattern recognition utilizing artificial intelligence, so that personal authentication of the palm print can be performed. Thus, a system that performs highly secure authentication can be constructed. Without limitation to the palm print authentication device, the authentication system of one embodiment of the present invention may be a device that performs biometric authentication by obtaining biological information of fingerprints, veins, faces, iris, voice prints, genes, physiques, or the like.

Note that this embodiment can be combined with any of the other embodiments in this specification as appropriate.

### REFERENCE NUMERALS

MAR: MAC array, MEMD: memory unit, CTLR: control circuit, MA: operation circuit, MA[1,1]: operation circuit, MA[2,1]: operation circuit, MA[u,1]: operation circuit, MA[1,2]: operation circuit, MA[2,2]: operation circuit, MA[u,2]: operation circuit, MA[1,v]: operation circuit, MA[2,v]: operation circuit, MA[u,v]: operation circuit, PR[1,1]: programmable switch, PR[2,1]: programmable switch, PR[u,1]: programmable switch, PR[1,2]: programmable switch, PR[2,2]: programmable switch, PR[u,2]: programmable switch, PR[1,v]: programmable switch, PR[2,v]: programmable switch, PR[u,v]: programmable switch, PC[1,1]: programmable switch, PC[2,1]: programmable switch, PC[u,1]: programmable switch, PC[1,2]: programmable switch, PC[2,2]: programmable switch, PC[u,2]: programmable switch, PC[1,v]: programmable switch, PC[2,v]: programmable switch, PC[u,v]: programmable switch, RG[1,1]: register, RG[1,p]: register, RG[2,1]: register, RG[2,p]: register, RG[u,1]: register, RG[u,p]: register, AF[1]: circuit, AF[2]: circuit, AF[v]: circuit, CKL: wiring, XL[1]: wiring, XL[2]: wiring, XL[u]: wiring, YL[1]: wiring, YL[2]: wiring, YL[v]: wiring, RG1: register, RG2: register, RG3: register, RG4: register, OSM: memory unit, MP: multiplier, AD: adder, SLC: selector, SI: terminal, SO: terminal, AI: terminal, AO: terminal, MI: terminal, MO: terminal, IT: terminal, OT1: terminal, IT2: terminal, OT2: terminal, CT2: terminal, IT3: terminal, OT3: terminal, CT3: terminal, IT4: terminal, OT4: terminal, XI: terminal, WI: terminal, ZO: terminal, FT: terminal, ST: terminal, TT: terminal, CF: wiring, WDT: wiring, URST: wiring, SLT: wiring, SEL: wiring, CTX: wiring, MA[s,g]: operation circuit, MA[s,h]: operation circuit, PR[s,g]: programmable switch, PR[s,h]: programmable switch, SW_SI[s,g]: switch, SW_SI[s,h]: switch, SW_SO[s,g]: switch, SW_SO[s,h]: switch, SW_AIX[s,g]: switch, SW_AIX[s,h]: switch, SW_AOX[s,g]: switch, SW_AOX[s,h]: switch, SL: wiring, ALX: wiring, XL[s]: wiring, MA[e,t]: operation circuit, MA[f,t]: operation circuit, PC[e,t]: programmable switch, PC[f,t]: programmable switch, SW_MI[e,t]: switch, SW_MI[f,t]: switch, SW_MO[e,t]: switch, SW_MO[f,t]: switch, SW_AIY[e,t]: switch, SW_AIY[f,t]: switch, SW_AOY[e,t]: switch, SW_AOY[f,t]: switch, ML: wiring, ALY: wiring, YL[s]: wiring, IPD: image data, IPD-Fₜ: image data, OPD: image data, CL: convolution layer, PL: pooling layer, FCL: fully connected layer, fil₁: filter, fil₂: filter, fil₃: filter, L₁: layer, L₂: layer, L_{z}: layer, D₁: image data, D₂: image data, D₃: image data, M1: transistor, M2: transistor, M3: transistor, CA: capacitor, CB: capacitor, BIL: wiring, RBL: wiring, WBL: wiring, WOL: wiring, SOL: wiring, CAL: wiring, BGL: wiring, CVL: wiring, SCL1: scribe line, SCL2: scribe line, 100: operation apparatus, 100A: operation apparatus, 221: memory cell, 231: memory cell, 232: memory cell, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 360: insulator, 362: insulator, 364: insulator, 366: conductor, 370: insulator, 372: insulator, 374: insulator, 376: conductor, 380: insulator, 382: insulator, 384: insulator, 386: conductor, 402: insulator, 404: insulator, 500: transistor, 503: conductor, 503a: conductor, 503b: conductor, 510: insulator, 512: insulator, 514: insulator, 516: insulator, 518: conductor, 520: insulator, 522: insulator, 524: insulator, 530: oxide, 530a: oxide, 530b: oxide, 530c: oxide, 530c1: oxide, 530c2: oxide, 540: conductor, 540a: conductor, 540b: conductor, 542a: conductor, 542b: conductor, 543a: region, 543b: region, 544: insulator, 546: conductor, 548: conductor, 550: insulator, 552: insulator, 560: conductor, 560a: conductor, 560b: conductor, 574: insulator, 580: insulator, 581: insulator, 582: insulator, 586: insulator, 600: capacitor, 600A: capacitor, 600B: capacitor, 610: conductor, 611: conductor, 612: conductor, 620: conductor, 621: conductor, 630: insulator, 631: insulator, 650: insulator, 651: insulator, 4700: electronic component, 4702: printed circuit board, 4704: mounting board, 4710: semiconductor device, 4711: mold, 4712: land, 4713: electrode pad, 4714: wire, 4730: electronic component, 4731: interposer, 4732: package substrate, 4733: electrode, 4735: semiconductor device, 4800: semiconductor wafer, 4800a: chip, 4801: wafer, 4801a: wafer, 4802: circuit portion, 4803: spacing, 4803a: spacing, 5200: portable game machine, 5201: housing, 5202: display portion, 5203: button, 5300: desktop information terminal, 5301: main body, 5302: display, 5303: keyboard, 5500: information terminal, 5510: housing, 5511: display portion, 5600: TV, 5650: antenna, 5670: radio wave tower, 5675A: radio wave, 5675B: radio wave, 5680: broadcast station, 5700: automobile, 5800: electric refrigerator-freezer, 5801: housing, 5802: refrigerator door, 5803: freezer door, 5900: information terminal, 5901: housing, 5902: display portion, 5903: operation button, 5904: operator, 5905: band, 6100: external device, 6101: housing, 6102: cap, 6103: USB connector, 6104: substrate, 6105: chip, 6106: controller chip, 6240: digital camera, 6241: housing, 6242: display portion, 6243: operation button, 6244: shutter button, 6246: lens, 6300: video camera, 6301: housing, 6302: housing, 6303: display portion, 6304: operation key, 6305: lens, 6306: joint, 6431: housing, 6432: display portion, 6433: palm print reading portion, 6434: wiring, 6435: hand, 7500: stationary game machine, 7520: main body, 7522: controller

1. A semiconductor device comprising:
a first operation circuit, a second operation circuit, a third operation circuit, an input register, and a second memory unit,
wherein the second operation circuit comprises a same circuit structure as the first operation circuit,
wherein the third operation circuit comprises a same circuit structure as the first operation circuit,
wherein the first operation circuit comprises a first memory unit, a first register, a second register, a third register, a first terminal, a second terminal, a third terminal, and a fourth terminal,
wherein, in the first operation circuit:
an input terminal of the first register is electrically connected to the first terminal;
an output terminal of the first register is electrically connected to an input terminal of the second register and the second terminal; and
an output terminal of the third register is electrically connected to the fourth terminal,
wherein the first operation circuit is configured to:
read out first data corresponding to a context signal from the first memory unit when the context signal is input to the first memory unit;
retain second data input to the first terminal, in the first register or the second register;
generate third data by multiplying the first data and the second data retained in the second register;
generate addition data by adding the third data to fourth data input from the third terminal; and
retain the addition data in the third register, and
wherein the first operation circuit is configured to:
output the second data retained in the first register to the second terminal and input the second data to the first terminal of the second operation circuit; and
output the addition data retained in the third register to the fourth terminal and input the addition data as the fourth data to the third terminal of the third operation circuit,
wherein the second memory unit is electrically connected to an input terminal of the input register, and
wherein the second memory unit is configured to read out the second data and input the second data from an output terminal of the input register to the first terminal of the first operation circuit through the input register,
wherein each of the first operation circuit and the third operation circuit comprises a selector, a fourth register, a fifth terminal, and a sixth terminal,
wherein, in each of the first operation circuit and the third operation circuit:
a first input terminal of the selector is electrically connected to the output terminal of the third register,
a second input terminal of the selector is electrically connected to the fifth terminal;
an output terminal of the selector is electrically connected to an input terminal of the fourth register; and
an output terminal of the fourth register is electrically connected to the sixth terminal, and
wherein the fifth terminal of the first operation circuit is electrically connected to the sixth terminal of the third operation circuit.

2. The semiconductor device according to claim 1, further comprising a circuit, wherein the circuit is configured to perform an operation with an active function on data output from the sixth terminal of the first operation circuit or the third operation circuit, and to retain a result of the operation in the second memory unit.

3. The semiconductor device according to claim 1, further comprising a plurality of first switches and a plurality of second switches,
wherein the second terminal of the first operation circuit is electrically connected to the first terminal of the second operation circuit through the plurality of first switches, and
wherein the fourth terminal of the first operation circuit is electrically connected to the third terminal of the third operation circuit through the plurality of second switches.

4. An electronic device comprising:
the semiconductor device according to claim 1, and a housing,
wherein a product-sum operation is performed by the semiconductor device.
